(19) United States
(12) Patent Application Publication
(10) Pub. No.: US 2026/0191111 A1
(43) Pub. Date: Jul. 2, 2026

(54) SEMICONDUCTOR APPARATUS INCLUDING A PLURALITY OF CELL DIES SHARING A LOGIC DIE

(71) Applicant: SK hynix Inc., Icheon-si (KR)

(72) Inventor: Seong Ju LEE, San Jose, CA (US)

(21) Appl. No.: 19/544,742

(22) Filed: Feb. 19, 2026

Related U.S. Application Data
(63) Continuation-in-part of application No. 19/322,182, filed on Sep. 8, 2025.
(60) Provisional application No. 63/711,065, filed on Oct. 23, 2024.

(30) Foreign Application Priority Data
Jun. 27, 2025 (KR) 10-2025-0085954

(51) Int. Cl. H10W 90/24; H10B 80/00; H10D 80/30; H10W 70/60; H10W 90/00; H10W 90/10

(52) U.S. Cl. CPC H10W 90/24; H10W 70/614; H10W 90/10; H10W 90/754; H10B 80/00; H10D 80/30

(57) ABSTRACT

A semiconductor apparatus includes a package substrate, a logic die, and a plurality of cell dies. The logic die and the plurality of cell dies are disposed on the package substrate. The logic die is coupled to pads of the package substrate through signal transmission lines of the package substrate. The plurality of cell dies is coupled to the pads of the package substrate through bonding wires, thereby being coupled to the logic die.

### CROSS-REFERENCES TO RELATED APPLICATIONS

The present application is a continuation-in-part application of pending U.S. patent application Ser. No. 19/322,182, filed on Sep. 8, 2025, which claims priority under 35 U.S.C. § 119 (a) to U.S. provisional application No. 63/711,065, filed on Oct. 23, 2024, and Korean application number 10-2025-0085954, filed on Jun. 27, 2025, in the Korean Intellectual Property Office, which applications are incorporated herein by reference in their entirety.

### BACKGROUND

### 1. Technical Field

Various embodiments generally relate to integrated circuit technology, and, more particularly, to a semiconductor apparatus including a plurality of cell dies that share a logic die.

### 2. Related Art

In recent years, with the explosive growth of artificial intelligence (AI) and big data technologies, a memory apparatus with higher performance has become necessary, while an extremely low-power memory apparatus is also being demanded due to eco-friendly policies. The memory industry has evolved in a direction of reducing power consumption, improving performance, and lowering manufacturing costs while pursuing miniaturization and integration. However, semiconductor miniaturization requires increasingly higher research and development costs, and the level of miniaturization is reaching its limit. Therefore, there is a growing need to develop a memory apparatus having a new structure in order to meet the demands of the times. To increase memory capacity and bandwidth, a stacked memory apparatus having a structure in which a plurality of memory dies are stacked and electrically connected through through-silicon vias (TSVs) has been developed. However, a stacked memory apparatus is expensive to manufacture and cannot be widely applied to different systems.

### SUMMARY

In an embodiment, a semiconductor apparatus may include a package substrate, a logic die, and first to fourth cell dies. The logic die may be disposed on the package substrate. The first to fourth cell dies may be disposed on the logic die and may each have data pads on a first side. The second cell die may be offset from the first cell die in a second direction opposite to a first direction to expose the first side of the first cell die in the first direction. The third and fourth cell dies may be disposed on the second cell die and rotated by 180 degrees with respect to the first and second cell dies. The third cell die may be offset from the second cell die in the second direction to expose the first side of the second cell die in the first direction. The fourth cell die may be offset from the third cell die in the first direction to expose the first side of the third cell die in the second direction. The data pads of the first and second cell dies may be coupled to first pads of the package substrate through first bonding wires, and the data pads of the third and fourth cell dies may be coupled to second pads of the package substrate through second bonding wires. The logic die may be coupled to the first pads through first signal transmission lines provided in the package substrate, may be coupled to the second pads through second signal transmission lines provided in the package substrate, and may be coupled to an external apparatus through third signal transmission lines provided in the package substrate.

In an embodiment, a semiconductor apparatus may include a package substrate, a logic die, a first cell die, a second cell die, a third cell die, and a fourth cell die. The logic die may be disposed on the package substrate. The first cell die may be disposed on the logic die. The second cell die may be disposed on the first cell die and may be rotated by 90 degrees with respect to the first cell die. The third cell die may be disposed on the second cell die to be aligned with the first cell die. The fourth cell die may be disposed on the third cell die to be aligned with the second cell die. The first to fourth cell dies may each include first data pads on a first side and second data pads on a second side opposite to the first side. The first data pads of the first cell die may be coupled to first pads of the package substrate through first bonding wires, and the second data pads of the first cell die may be coupled to second pads of the package substrate through second bonding wires. The first data pads of the second cell die may be coupled to third pads of the package substrate through third bonding wires, and the second data pads of the second cell die may be coupled to fourth pads of the package substrate through fourth bonding wires. The first data pads of the third cell die may be coupled to the first pads of the package substrate through fifth bonding wires, and the second data pads of the third cell die may be coupled to the second pads of the package substrate through sixth bonding wires. The first data pads of the fourth cell die may be coupled to the third pads of the package substrate through seventh bonding wires, and the second data pads of the fourth cell die may be coupled to the fourth pads of the package substrate through eighth bonding wires. The logic die may be coupled to the first pads through first signal transmission lines provided in the package substrate, may be coupled to the second pads through second signal transmission lines provided in the package substrate, may be coupled to the third pads through third signal transmission lines provided in the package substrate, may be coupled to the fourth pads through fourth signal transmission lines provided in the package substrate, and may be coupled to an external apparatus through fifth signal transmission lines provided in the package substrate.

In an embodiment, a semiconductor apparatus may include a package substrate, a logic die, and first to fourth cell dies. The logic die may be disposed on the package substrate. The first to fourth cell dies may be disposed on the logic die and may each have data pads on a first side. The second cell die may be disposed on the first cell die by being shifted in a second direction opposite to a first direction to expose the first side of the first cell die in the first direction. The third and fourth cell dies may be disposed on the second cell die and rotated by 180 degrees with respect to the first and second cell dies. The third cell die may be disposed on the second cell die by being shifted in the second direction to expose the first side of the second cell die in the first direction. The fourth cell die may be disposed on the third cell die by being shifted in the first direction to expose the first side of the third cell die in the second direction. The first cell die may include down memory banks of a bank group accessed based on a first address group, the second cell die may include down memory banks of a bank group accessed based on a second address group, the third cell die may include up memory banks of a bank group accessed based on the first address group, and the fourth cell die may include up memory banks of a bank group accessed based on the second address group. The logic die may be configured to access the first and third cell dies in conjunction or to access the second and fourth cell dies in conjunction, in a plurality of data input/output modes.

In an embodiment, a semiconductor apparatus may include a package substrate, a logic die, a first cell die, a second cell die, a third cell die, and a fourth cell die. The logic die may be disposed on the package substrate. The first cell die may be disposed on the logic die. The second cell die may be disposed on the first cell die and may be rotated by 90 degrees with respect to the first cell die. The third cell die may be disposed on the second cell die to be aligned with the first cell die. The fourth cell die may be disposed on the third cell die to be aligned with the second cell die. The first to fourth cell dies may each have first data pads on a first side and second data pads on a second side opposite to the first side. Down memory banks of the first cell die may be coupled to the first data pads of the first cell die, and up memory banks of the first cell die may be coupled to the second data pads of the first cell die. Down memory banks of the second cell die may be coupled to the first data pads of the second cell die, and up memory banks of the second cell die may be coupled to the second data pads of the second cell die. Down memory banks of the third cell die may be coupled to the first data pads of the third cell die, and up memory banks of the third cell die may be coupled to the second data pads of the third cell die. Down memory banks of the fourth cell die may be coupled to the first data pads of the fourth cell die, and up memory banks of the fourth cell die may be coupled to the second data pads of the fourth cell die. The logic die may be configured to access the first and second cell dies in conjunction or to access the third and fourth cell dies in conjunction, in a plurality of data input/output modes.

### BRIEF DESCRIPTION OF THE DRAWINGS

FIG. 1 is a diagram illustrating configurations of a semiconductor apparatus according to a prior art and a semiconductor apparatus according to an embodiment of the present disclosure.

FIG. 2 is a diagram illustrating a configuration and connection relationship of a semiconductor apparatus according to an embodiment of the present disclosure.

FIG. 3 is a plan view of a portion of the semiconductor apparatus illustrated in FIG. 2 according to an embodiment of the present disclosure.

FIG. 4A is a diagram illustrating a configuration and connection relationship of a semiconductor apparatus according to an embodiment of the present disclosure.

FIG. 4B is a diagram illustrating configurations of a logic die, a first cell die, and a second cell die illustrated in FIG. 4A according to an embodiment of the present disclosure.

FIG. 5 is a diagram illustrating a configuration of a logic die according to an embodiment of the present disclosure.

FIG. 6 is a diagram illustrating a configuration of a bank group control circuit illustrated in FIG. 5.

FIG. 7 is a diagram illustrating a configuration and connection relationship of a semiconductor apparatus according to an embodiment of the present disclosure.

FIG. 8 is a diagram illustrating a configuration of a cell die according to an embodiment of the present disclosure.

FIG. 9 is a diagram illustrating a configuration and connection relationship of a semiconductor apparatus according to an embodiment of the present disclosure.

FIG. 10 is a diagram illustrating a configuration of a logic die illustrated in FIG. 9.

FIG. 11 is a diagram illustrating a configuration and connection relationship of a semiconductor apparatus according to an embodiment of the present disclosure.

FIG. 12 is a diagram illustrating a configuration of a logic die illustrated in FIG. 11.

FIG. 13 is a diagram illustrating a configuration of a semiconductor apparatus according to an embodiment of the present disclosure.

FIG. 14 is a diagram illustrating a configuration of a logic die illustrated in FIG. 13.

FIG. 15 is a diagram illustrating a configuration of a semiconductor system according to an embodiment of the present disclosure.

FIG. 16A is a diagram illustrating a configuration and connection relationship of a semiconductor apparatus according to an embodiment of the present disclosure.

FIG. 16B is a diagram illustrating configurations of a first cell die and a fifth cell die illustrated in FIG. 16A.

FIGS. 17A and 17B are diagrams illustrating a configuration and connection relationship of a semiconductor apparatus according to an embodiment of the present disclosure.

FIG. 18 is a diagram illustrating a configuration of a cell die according to an embodiment of the present disclosure.

### DETAILED DESCRIPTION

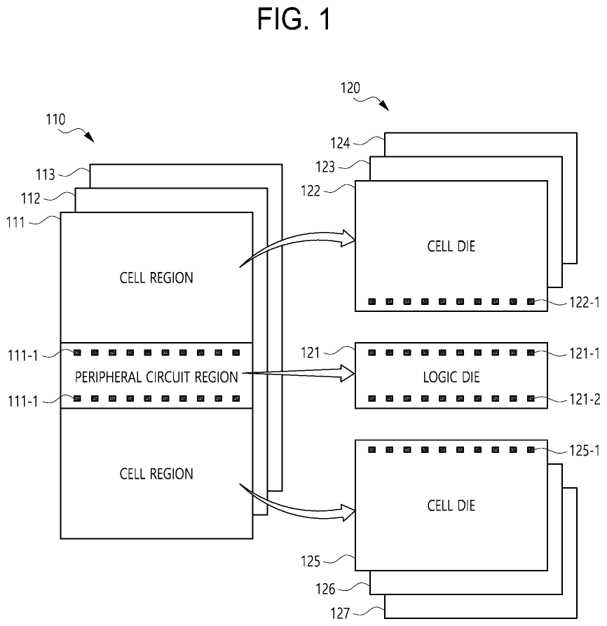

FIG. 1 is a diagram illustrating a configuration of a semiconductor apparatus 110 according to a prior art and a configuration of a semiconductor apparatus 120 according to an embodiment of the present disclosure. Referring to FIG. 1, the semiconductor apparatus 110 according to the prior art may include a plurality of dies 111, 112, and 113. The plurality of dies 111, 112, and 113 may be packaged as a single package to constitute a single semiconductor apparatus. The plurality of dies 111, 112, and 113 may have the same structure. Each of the plurality of dies 111, 112, and 113 may include a cell region and a peripheral circuit region. The peripheral circuit region may be disposed between two cell regions. Components, which may be referred to as memory banks, may be disposed in the cell region. For example, the cell region may include circuits such as a memory cell array, a row decoding circuit, a column decoding circuit, and write and read drivers. Additionally, the cell region may include a fuse array and an error correction circuit. The peripheral circuit region may include remaining components of the semiconductor apparatus that are not included in the memory bank. For example, the peripheral circuit region may include various interface circuits for enabling the semiconductor apparatus to communicate with an external apparatus. The peripheral circuit region may include a serializer/deserializer (SerDes) configured to serialize data signals output from the cell region and deserialize data signals received from the external apparatus. In addition, the peripheral circuit region may include a clock generation circuit, a voltage generation circuit, and a command and address control circuit. The plurality of dies 111, 112, and 113 may include a pad or through-via region 111-1 in the peripheral circuit region and may be electrically connected to each other through through-vias. When the plurality of dies 111, 112, and 113 constitute a single semiconductor apparatus, circuits in the peripheral circuit region may be activated only in one die, while the same circuits may be deactivated in the remaining dies. These deactivated circuits in the remaining dies may occupy unnecessary area. In addition, the package manufacturing method using through-vias may incur a high cost and may reduce the margin between manufacturing cost and selling price.

The semiconductor apparatus 120 according to an embodiment of the present disclosure may include a logic die 121 and a plurality of cell dies 122, 123, 124, 125, 126, and 127. The logic die 121 may include circuits disposed in the peripheral circuit region of the dies 111, 112, and 113 of the semiconductor apparatus 110. The plurality of cell dies 122, 123, 124, 125, 126, and 127 may include memory cells and circuits disposed in the cell region of the dies 111, 112, and 113 of the semiconductor apparatus 110. By separating the logic die 121 and the plurality of cell dies 122, 123, 124, 125, 126, and 127, the semiconductor apparatus 120 may remove the peripheral circuit region provided in each of the dies 111, 112, and 113 and allow more cell dies to be manufactured from a single wafer. While the plurality of cell dies 122, 123, 124, 125, 126, and 127 may be manufactured using a process technology having a first characteristic, the logic die 121 may be manufactured using a process technology having a second characteristic. The process technology having the second characteristic may be finer than the process technology having the first characteristic. For example, the process technology having the first characteristic may be a memory process technology, and the process technology having the second characteristic may be a logic process technology. The semiconductor apparatus 120 may couple the logic die 121 and the plurality of cell dies 122, 123, 124, 125, 126, and 127 using bonding wires. By using the bonding wires, the manufacturing cost of the semiconductor apparatus 120 may be significantly lower than that of the semiconductor apparatus 110 using through-vias. Because the logic die 121 may be manufactured using a finer process technology than the plurality of cell dies 122, 123, 124, 125, 126, and 127, it may enable high-speed operation and reduce power consumption. Additionally, because additional features and/or functions may be provided in the logic die 121, the functionality of the logic die 121 may be improved, and the types of semiconductor systems to which the semiconductor apparatus 120 may be applied may be diversified. For example, the error correction circuit previously provided in the cell region of the comparative device may be implemented in the logic die 121, and by forming additional memory cells in the region where the error correction circuit would have been disposed, the memory capacity of the cell dies 122, 123, 124, 125, 126, and 127 may be increased. Because an enhanced error correction circuit may be integrated into the logic die 121, error bit recovery capability may be improved, and the reliability of the semiconductor apparatus 120 may be enhanced. Additionally, an SRAM performing the function of a Last Level Cache (LLC) may be integrated into the logic die 121, and the semiconductor apparatus 120 may supplement the performance of a host. Furthermore, a computing circuit may be integrated into the logic die 121 such that the semiconductor apparatus 120 may perform a function of Processing Near Memory (PNM) or Processing In Memory (PIM).

The plurality of cell dies 122, 123, 124, 125, 126, and 127 may share the logic die 121 and may be coupled to the logic die 121 at opposite sides of the logic die 121. In the plan view of FIG. 1, a side refers to an edge defining the die, or a region of the die. In embodiments, a side may refer to the edge, an area or region adjacent to the edge, or both. An area or region adjacent to an edge may refer to a surface of a die near the edge. The plurality of cell dies 122, 123, 124, 125, 126, and 127 may include data pads 122-1 and 125-1 at first sides of the plurality of cell dies. The logic die 121 may include data pads 121-1 and 121-2 on a first side and a second side of the logic die 121, the second side being opposite to or facing the first side. The first sides of the plurality of cell dies 122, 123, and 124 may be adjacent to the first side of the logic die 121. The data pads 121-1 provided on the first side of the logic die 121 may be coupled to the data pads 122-1 of the plurality of cell dies 122, 123, and 124 disposed adjacent to the first side of the logic die 121. The first sides of the plurality of cell dies 125, 126, and 127 may be adjacent to the second side of the logic die 121. The data pads 121-2 provided on the second side of the logic die 121 may be coupled to the data pads 125-1 of the plurality of cell dies 125, 126, and 127 disposed adjacent to the second side of the logic die 121.

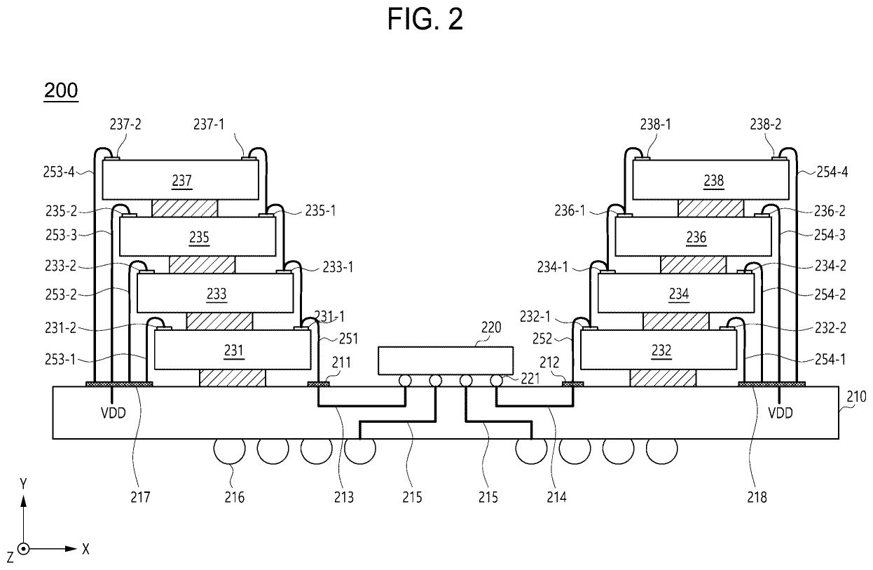

FIG. 2 is a diagram illustrating a configuration and a connection relationship of a semiconductor apparatus 200 according to an embodiment of the present disclosure. Referring to FIG. 2, the semiconductor apparatus 200 may include a package substrate 210, a logic die 220, and a plurality of cell dies 231, 232, 233, 234, 235, 236, 237, and 238. The logic die 220 may correspond to the logic die 121 illustrated in FIG. 1. Each of the plurality of cell dies 231 to 238 may correspond to one of the cell dies 122, 123, 124, 125, 126, and 127 illustrated in FIG. 1. The logic die 220 and the plurality of cell dies 231 to 238 may be disposed on the package substrate 210 and may be packaged in a single package. The logic die 220 may be disposed on the package substrate 210. For example, the logic die 220 may be disposed at a central region of the package substrate 210 in an x-axis direction and a z-axis direction such that the plurality of cell dies 231 to 238 are disposed at both sides of the logic die 220 in an x-axis direction. The logic die 220 may include a first side, and a second side opposite to or facing the first side in an x-axis direction.

The plurality of cell dies may include first to eighth cell dies 231, 232, 233, 234, 235, 236, 237, and 238. Although eight cell dies are illustrated in FIG. 2 as an example, the number of cell dies included in the semiconductor apparatus 200 may be any multiple of two. The first cell die 231 may be disposed adjacent to the first side of the logic die 220 in an x-axis direction and disposed on the package substrate 210 in a y-axis direction. The second cell die 232 may be disposed adjacent to the second side of the logic die 220 in an x-axis direction and disposed on the package substrate 210 in a y-axis direction. The first and second cell dies 231 and 232 may be bonded to the package substrate 210 using an adhesive or a die attach film (DAF). The third cell die 233 may be disposed adjacent to the first side of the logic die 220 in an x-axis direction and disposed on the first cell die 231 in a y-axis direction. The fourth cell die 234 may be disposed adjacent to the second side of the logic die 220 in an x-axis direction and disposed on the second cell die 232 in a y-axis direction. The third and fourth cell dies 233 and 234 may be bonded onto the first and second cell dies 231 and 232, respectively, using the die attach film. The fifth cell die 235 may be disposed adjacent to the first side of the logic die 220 in an x-axis direction and disposed on the third cell die 233 in a y-axis direction. The sixth cell die 236 may be disposed adjacent to the second side of the logic die 220 in an x-axis direction and disposed on the fourth cell die 234 in a y-axis direction. The fifth and sixth cell dies 235 and 236 may be bonded onto the third and fourth cell dies 233 and 234, respectively, using the die attach film. The seventh cell die 237 may be disposed adjacent to the first side of the logic die 220 in an x-axis direction and disposed on the fifth cell die 235 in a y-axis direction. The eighth cell die 238 may be disposed adjacent to the second side of the logic die 220 in an x-axis direction and disposed on the sixth cell die 236 in a y-axis direction. The seventh and eighth cell dies 237 and 238 may be bonded onto the fifth and sixth cell dies 235 and 236, respectively, using the die attach film. The first, third, fifth, and seventh cell dies 231, 233, 235, and 237 may include data pads 231-1, 233-1, 235-1, and 237-1 on a first side thereof. The first, third, fifth, and seventh cell dies 231, 233, 235, and 237 may be stacked in a stepwise structure such that the data pads 231-1, 233-1, 235-1, and 237-1 are exposed. The second, fourth, sixth, and eighth cell dies 232, 234, 236, and 238 may include data pads 232-1, 234-1, 236-1, and 238-1 on a first side of thereof. The second, fourth, sixth, and eighth cell dies 232, 234, 236, and 238 may be stacked in a stepwise structure such that the data pads 232-1, 234-1, 236-1, and 238-1 are exposed.

The package substrate 210 may include first pads 211, second pads 212, first signal transmission lines 213, second signal transmission lines 214, and third signal transmission lines 215. The first pads 211 and the second pads 212 may be provided on the package substrate 210, and the first to third signal transmission lines 213, 214, and 215 may be provided in the package substrate 210. For example, the first pads 211 may be provided on the package substrate 210 in a region in an x-axis direction between the first cell die 231 and the logic die 220, and the second pads 212 may be provided in a region between the second cell die 232 and the logic die 220. The first cell die 231 may be coupled to the first pads 211 through first bonding wires 251. The data pads 231-1 of the first cell die 231 may be coupled to the first pads 211 through the first bonding wires 251. The third, fifth, and seventh cell dies 233, 235, and 237 may be coupled to the first pads 211 through the first bonding wires 251. The data pads 233-1, 235-1, and 237-1 of the third, fifth, and seventh cell dies 233, 235, and 237 may be coupled to the first pads 211 through the first bonding wires 251. The data pads 231-1, 233-1, 235-1, and 237-1 of the first, third, fifth, and seventh cell dies 231, 233, 235, and 237 may be coupled in common through the first bonding wires 251. The second cell die 232 may be coupled to the second pads 212 through second bonding wires 252. The data pads 232-1 of the second cell die 232 may be coupled to the second pads 212 through the second bonding wires 252. The fourth, sixth, and eighth cell dies 234, 236, and 238 may be coupled to the second pads 212 through the second bonding wires 252. The data pads 234-1, 236-1, and 238-1 of the fourth, sixth, and eighth cell dies 234, 236, and 238 may be coupled to the second pads 212 through the second bonding wires 252. The data pads 232-1, 234-1, 236-1, and 238-1 of the second, fourth, sixth, and eighth cell dies 232, 234, 236, and 238 may be coupled in common through the second bonding wires 252. The logic die 220 may be coupled to the first pads 211 through the first signal transmission lines 213. The logic die 220 may be coupled to the first, third, fifth, and seventh cell dies 231, 233, 235, and 237 through the first signal transmission lines 213, the first pads 211, and the first bonding wires 251. The logic die 220 may be coupled to the second pads 212 through the second signal transmission lines 214. The logic die 220 may be coupled to the second, fourth, sixth, and eighth cell dies 232, 234, 236, and 238 through the second signal transmission lines 214, the second pads 212, and the second bonding wires 252. The logic die 220 may be coupled to an external apparatus of the semiconductor apparatus 200 through the third signal transmission lines 215. The logic die 220 may include a plurality of bumps 221 and may be coupled to a plurality of pads provided on the package substrate 210 through the plurality of bumps 221. The logic die 220 may be coupled to the first to third signal transmission lines 213, 214, and 215 through the bumps. The package substrate 210 may include package balls 216, and the third signal transmission lines 215 may be coupled to the external apparatus through the package balls 216. The logic die 220 may deserialize signals from the third signal transmission lines 215 into signals transmitted to the first and second signal transmission lines 213 and 214, and serialize signals from the first and second signal transmission lines 213 and 214 into signals transmitted to the third signal transmission lines 215. The logic die 220 may perform an error correction operation on the signals received from the first and second signal transmission lines 213 and 214.

The first to eighth cell dies 231, 232, 233, 234, 235, 236, 237, and 238 may include power pads 231-2, 232-2, 233-2, 234-2, 235-2, 236-2, 237-2, and 238-2, respectively, each on a second side opposite to or facing the first side of the first to eighth cell dies 231, 232, 233, 234, 235, 236, 237, and 238 respectively in an x-axis direction. The package substrate 210 may further include a third pad 217 and a fourth pad 218. For example, the third pad 217 may be provided at a location spaced apart from the second side of the first cell die 231 in an x-axis direction. The fourth pad 218 may be provided at a location spaced apart from the second side of the second cell die 232 in an x-axis direction. The first cell die 231 may be coupled to the third pad 217 through a bonding wire 253-1. The third, fifth, and seventh cell dies 233, 235, and 237 may also be coupled to the third pad 217 through bonding wires 253-2, 253-3, and 253-4, respectively. A power voltage VDD may be supplied through the third pad 217. The power voltage VDD may be supplied to the power pads 231-2, 233-2, 235-2, and 237-2 of the first, third, fifth, and seventh cell dies 231, 233, 235, and 237 through the third pad 217 and the bonding wires 253-1, 253-2, 253-3, and 253-4, respectively. The second cell die 232 may be coupled to the fourth pad 218 through a bonding wire 254-1. The fourth, sixth, and eighth cell dies 234, 236, and 238 may also be coupled to the fourth pad 218 through bonding wires 254-2, 254-3, and 254-4, respectively. The power voltage VDD may be supplied through the fourth pad 218. The power voltage VDD may be supplied to the power pads 232-2, 234-2, 236-2, and 238-2 of the second, fourth, sixth, and eighth cell dies 232, 234, 236, and 238 through the fourth pad 218 and the bonding wires 254-1, 254-2, 254-3, and 254-4, respectively.

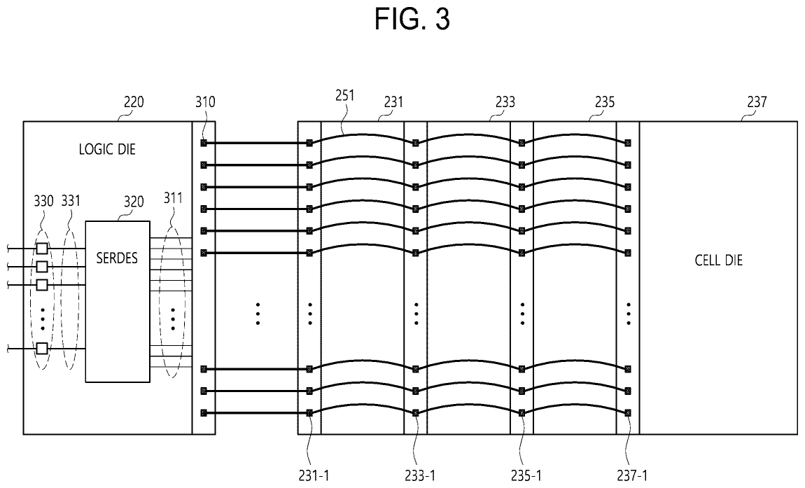

FIG. 3 is a plan view of a portion of the semiconductor apparatus 200 illustrated in FIG. 2 according to an embodiment of the present disclosure, illustrated in FIG. 2. FIG. 3 illustrates a connection relationship between the logic die 220 and the first, third, fifth, and seventh cell dies 231, 233, 235, and 237 shown in FIG. 2. Referring to both FIGS. 2 and 3, the first, third, fifth, and seventh cell dies 231, 233, 235, and 237 may be coupled to the logic die 220 through the first bonding wires 251. The first bonding wires 251 may be coupled to the first pads 211 of the package substrate 210 and may be coupled to the logic die 220 through the first signal transmission lines 213. The logic die 220 may include internal data pads 310, and the internal data pads 310 may be coupled to the data pads 231-1, 233-1, 235-1, and 237-1 of the first, third, fifth, and seventh cell dies 231, 233, 235, and 237 through the bumps 221, the first signal transmission lines 213, and the first pads 211. The logic die 220 may include a serializer/deserializer (SERDES) 320. The serializer/deserializer 320 may be coupled between external data pads 330 and the internal data pads 310. The external data pads 330 may be coupled to an external apparatus of the semiconductor apparatus 200. The logic die 220 may be coupled to the external apparatus through the external data pads 330, the bumps 221, the third signal transmission lines 215, and the package balls 216. The logic die 220 may receive data transmitted from the external apparatus or transmit data to the external apparatus through the external data pads 330.

The logic die 220 may perform serial data communication with the external apparatus. For example, the logic die 220 may be coupled to the external apparatus through N data transmission lines 331 and may include N external data pads 330. Here, N may be a multiple of 4 or 6. Through the N external data pads 330, N data signals may be transmitted from the external apparatus to the logic die 220 at the same time, and N data signals may be transmitted from the logic die 220 to the external apparatus at the same time. The N data signals on the N data transmission lines 331 may be serial data and the N data signals may be transmitted as a bit stream in which multiple bits are continuously transferred through one data transmission line. The number of bits of a data signal transmitted through one data transmission line in a single data transmission operation may be defined as a burst length, and the burst length may be a multiple of 8. For example, when the burst length is k, a k-bit data signal may be transmitted as a continuous bit stream through one data transmission line in a single data transmission operation. The logic die 220 may perform parallel data communication with the first, third, fifth, and seventh cell dies 231, 233, 235, and 237. The logic die 220 may be coupled to the first, third, fifth, and seventh cell dies 231, 233, 235, and 237 through a plurality of data input/output lines 311. For example, the ratio of the number of the data transmission lines 331 to the number of the data input/output lines 311 may be 1 to k. The logic die 220 may be coupled to the first, third, fifth, and seventh cell dies 231, 233, 235, and 237 through N*k data input/output lines and may include N*k internal data pads 310. Through the N*k internal data pads 310, N*k data signals may be transmitted from the logic die 220 to the first, third, fifth, and seventh cell dies 231, 233, 235, and 237 at the same time, and N*k data signals may be transmitted from the first, third, fifth, and seventh cell dies 231, 233, 235, and 237 to the logic die 220 at the same time. The serializer/deserializer (SerDes) 320 may deserialize the data signals received through the external data pads 330 and output the deserialized data signals through the data input/output lines 311 and the internal data pads 310. The serializer/deserializer 320 may serialize the data signals received through the internal data pads 310 and the data input/output lines 311 and output the serialized data signals through the external data pads 330 and the data transmission lines. The semiconductor apparatus 200 may couple the plurality of cell dies 231, 232, 233, 234, 235, 236, 237, and 238 to the logic die 220 using bonding wires, thereby significantly reducing the manufacturing cost compared to a conventional semiconductor apparatus using through vias. However, in this example, because the logic die 220 includes the serializer/deserializer 320, the number of bonding wires for connecting the plurality of cell dies may become excessive. For example, when the number of data transmission lines 331 is 16 and the burst length is 16, the number of bonding wires may be equal to the number of data input/output lines 311, and in order to support the maximum bandwidth of the semiconductor apparatus, the number of bonding wires may increase to 256 or 512. In addition, it is difficult to form 256 or 512 pads on one side of the plurality of cell dies having a limited area. Therefore, there is a need for a method for reducing the number of bonding wires connecting the plurality of cell dies and the logic die.

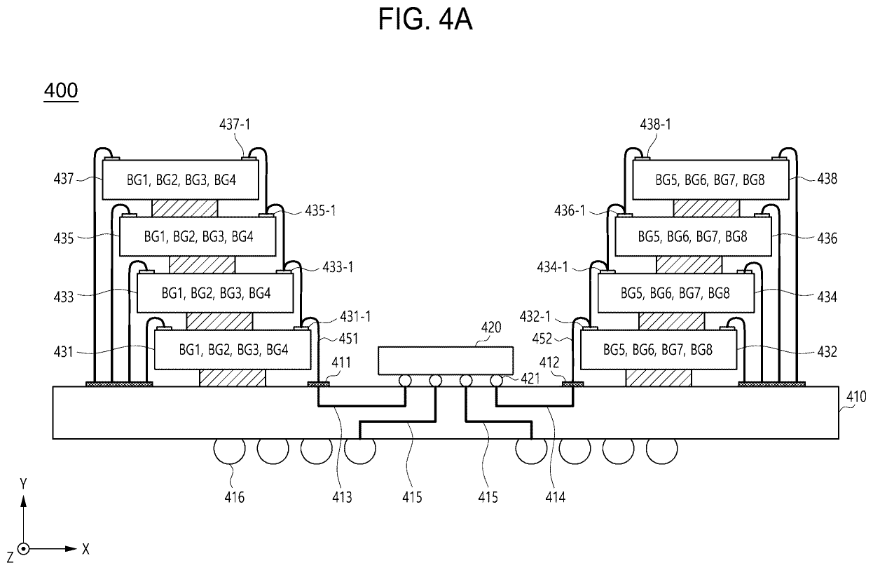

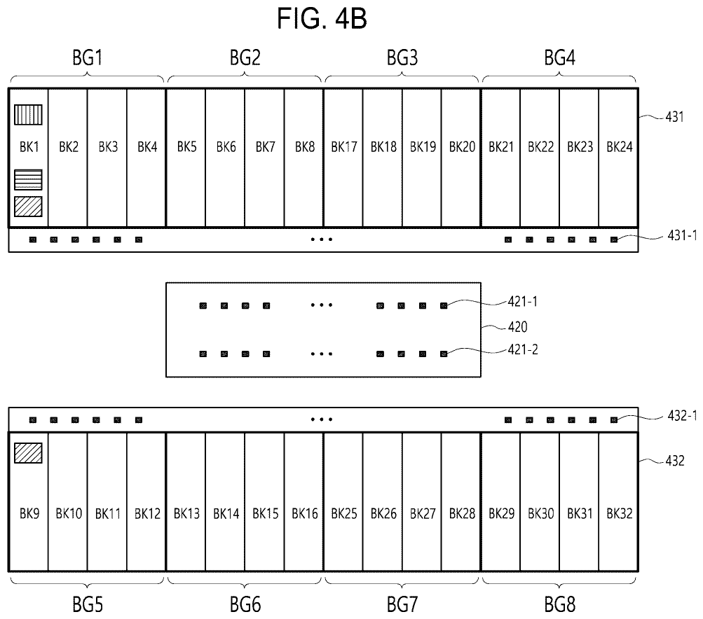

FIG. 4A is a diagram illustrating a configuration and a connection relationship of a semiconductor apparatus 400 according to an embodiment of the present disclosure. Referring to FIG. 4A, the semiconductor apparatus 400 may include a package substrate 410, a logic die 420, and a plurality of cell dies. For example, the semiconductor apparatus 400 may include first to eighth cell dies 431, 432, 433, 434, 435, 436, 437, and 438. The semiconductor apparatus 400 may have substantially the same connection relationship as the semiconductor apparatus 200 illustrated in FIG. 2. Similar reference numerals are given to components of the semiconductor apparatus 400 corresponding to components of the semiconductor apparatus 200, and redundant descriptions regarding some connection relationships will be omitted. Each of the first, third, fifth, and seventh cell dies 431, 433, 435, and 437 include four bank groups, and each of the second, fourth, sixth, and eighth cell dies 432, 434, 436, and 438 include four bank groups. Each of the bank groups may include a plurality of memory banks. The first cell die 431 and the second cell die 432 may include bank groups accessed based on a first address group. The third cell die 433 and the fourth cell die 434 may include bank groups accessed based on a second address group. The fifth cell die 435 and the sixth cell die 436 may include bank groups accessed based on a third address group. The seventh cell die 437 and the eighth cell die 438 may include bank groups accessed based on a fourth address group. For example, the first cell die 431 may include a first bank group BG1, a second bank group BG2, a third bank group BG3, and a fourth bank group BG4 accessed by the first address group. The third cell die 433 may include a first bank group BG1, a second bank group BG2, a third bank group BG3, and a fourth bank group BG4 accessed by the second address group. The fifth cell die 435 may include a first bank group BG1, a second bank group BG2, a third bank group BG3, and a fourth bank group BG4 accessed by the third address group. The seventh cell die 437 may include a first bank group BG1, a second bank group BG2, a third bank group BG3, and a fourth bank group BG4 accessed by the fourth address group. The second cell die 432 may include a fifth bank group BG5, a sixth bank group BG6, a seventh bank group BG7, and an eighth bank group BG8 accessed by the first address group. The fourth cell die 434 may include a fifth bank group BG5, a sixth bank group BG6, a seventh bank group BG7, and an eighth bank group BG8 accessed by the second address group. The sixth cell die 436 may include a fifth bank group BG5, a sixth bank group BG6, a seventh bank group BG7, and an eighth bank group BG8 accessed by the third address group. The eighth cell die 438 may include a fifth bank group BG5, a sixth bank group BG6, a seventh bank group BG7, and an eighth bank group BG8 accessed by the fourth address group. Accordingly, the first and second cell dies 431 and 432 may operate as one independent rank, die, or slice, and the third and fourth cell dies 433 and 434 may also operate as one independent rank, die, or slice. The fifth and sixth cell dies 435 and 436 may operate as one independent rank, die, or slice, and the seventh and eighth cell dies 437 and 438 may also operate as one independent rank, die, or slice.

FIG. 4B is a diagram illustrating a configuration of the logic die 420, the first cell die 431, and the second cell die 432 illustrated in FIG. 4A according to an embodiment of the present disclosure. Referring to FIG. 4B, the first cell die 431 may include the first bank group BG1, the second bank group BG2, the third bank group BG3, and the fourth bank group BG4. The first bank group BG1 may include a first memory bank BK1, a second memory bank BK2, a third memory bank BK3, and a fourth memory bank BK4. The second bank group BG2 may include a fifth memory bank BK5, a sixth memory bank BK6, a seventh memory bank BK7, and an eighth memory bank BK8. The third bank group BG3 may include a seventeenth memory bank BK17, an eighteenth memory bank BK18, a nineteenth memory bank BK19, and a twentieth memory bank BK20. The fourth bank group BG4 may include a twenty-first memory bank BK21, a twenty-second memory bank BK22, a twenty-third memory bank BK23, and a twenty-fourth memory bank BK24. The second cell die 432 may include the fifth bank group BG5, the sixth bank group BG6, the seventh bank group BG7, and the eighth bank group BG8. The fifth bank group BG5 may include a ninth memory bank BK9, a tenth memory bank BK10, an eleventh memory bank BK11, and a twelfth memory bank BK12. The sixth bank group BG6 may include a thirteenth memory bank BK13, a fourteenth memory bank BK14, a fifteenth memory bank BK15, and a sixteenth memory bank BK16. The seventh bank group BG7 may include a twenty-fifth memory bank BK25, a twenty-sixth memory bank BK26, a twenty-seventh memory bank BK27, and a twenty-eighth memory bank BK28. The eighth bank group BG8 may include a twenty-ninth memory bank BK29, a thirtieth memory bank BK30, a thirty-first memory bank BK31, and a thirty-second memory bank BK32. In FIG. 4B, the numbers of the memory banks included in each of the bank groups are illustrated as examples, but the numbering is not intended to be limiting and may vary.

The first and second cell dies 431 and 432 may include data pads 431-1 and 432-1 at first sides of the first and second cell dies 431 and 432, respectively. The first side may correspond to an edge portion adjacent to one of the two longer sides among the four sides of each of the first and second cell dies 431 and 432. The logic die may include internal data pads 421-1 on a first side and internal data pads 421-2 on a second side opposite to or facing the first side. The first side of the first cell die 431 may be adjacent to the first side of the logic die 420, and the first side of the second cell die 432 may be adjacent to the second side of the logic die 420. The data pads 431-1 of the first cell die 431 may be coupled to the internal data pads 421-1 provided on the first side of the logic die 420 through the first bonding wires 451. The data pads 432-1 of the second cell die 432 may be coupled to the internal data pads 421-2 provided on the second side of the logic die 420 through the second bonding wires 452. Because the first cell die 431 includes half of the bank groups accessed by an address group and the second cell die 432 includes the remaining half of the bank groups, the first and second cell dies 431 and 432 may be accessed simultaneously through data pads coupled to the logic die 420 distributed across the first and second cell dies 431 and 432. Therefore, compared to FIG. 3, the number of data pads provided in the first and second cell dies 431 and 432 may be reduced by half. For example, the number of the data pads 431-1 and 432-1 provided on the first sides of the first and second cell dies 431 and 432 may each be N*k/2. The number of the internal data pads 421-1 and 421-2 provided at the first and second sides of the logic die 420 may also each be N*k/2. The logic die 420 may be coupled to the data pads 431-1 of the first cell die 431 through the N*k/2 internal data pads 421-1 provided on the first side of the logic die 420. The logic die 420 may be coupled to the data pads 432-1 of the second cell die 432 through the N*k/2 internal data pads 421-2 provided on the second side of the logic die.

Referring also to FIG. 4A, data pads 431-1, 433-1, 435-1, and 437-1 of the first, third, fifth, and seventh cell dies 431, 433, 435, and 437 may be coupled to first pads 411 of the package substrate 410 through the first bonding wires 451, and the first pads 411 may be coupled to the logic die 420 through the first signal transmission lines 413. The number of the first bonding wires 451 may be N*k/2, and the number of the first signal transmission lines 413 may also be N*k/2. Data pads 432-1, 434-1, 436-1, and 438-1 of the second, fourth, sixth, and eighth cell dies 432, 434, 436, and 438 may be coupled to second pads 412 of the package substrate 410 through the second bonding wires 452, and the second pads 412 may be coupled to the logic die 420 through the second signal transmission lines 414. The number of the second bonding wires 452 may be N*k/2, and the number of the second signal transmission lines 414 may also be N*k/2. The logic die 420 may be coupled to the external apparatus through the third signal transmission lines 415. The number of the third signal transmission lines 415 may be N, 2N, or 4N.

The semiconductor apparatus 400 may support a plurality of data input/output modes. The plurality of data input/output modes may include a first data input/output mode, a second data input/output mode, and a third data input/output mode. For example, the first data input/output mode may be ×16, and may be an operation mode in which sixteen serial data signals are transmitted to perform a data input/output operation. The second data input/output mode may be ×4, and may be an operation mode in which four serial data signals are transmitted to perform a data input/output operation. The third data input/output mode may be ×8, and may be an operation mode in which eight serial data signals are transmitted to perform a data input/output operation. When the semiconductor apparatus 400 supports all of the first to third data input/output modes, the number of third signal transmission lines may be sixteen, and a burst length may be sixteen. For example, a data transmission operation from the external apparatus to the semiconductor apparatus 400 is described as follows. In the second data input/output mode, four serial data signals transmitted from the external apparatus may be converted into sixty-four parallel data signals by the logic die 420. Because the first bonding wires 451 and the second bonding wires 452 are each 128 in number, the sixty-four parallel data signals may be transmitted through either the first bonding wires 451 or the second bonding wires 452. Accordingly, in the second data input/output mode, the logic die 420 may access one of the first to eighth cell dies 431, 432, 433, 434, 435, 436, 437, and 438, and may perform a data input/output operation with the accessed cell die. For example, as schematically indicated by the area with vertical lines in FIG. 4B, the sixty-four parallel data signals may be stored in one of memory banks in the first bank group BG1 of the first cell die 431, that is, in the first memory bank BK1. In the third data input/output mode, eight serial data signals transmitted from the external apparatus may be converted into 128 parallel data signals by the logic die 420. Because the first bonding wires 451 and the second bonding wires 452 are each 128 in number, the 128 parallel data signals may be transmitted through either the first bonding wires 451 or the second bonding wires 452. Accordingly, in the third data input/output mode, the logic die 420 may access one of the first to eighth cell dies 431, 432, 433, 434, 435, 436, 437, and 438, and may perform a data input/output operation with the accessed cell die. For example, as schematically indicated by the area with horizontal lines in FIG. 4B, the 128 parallel data signals may be stored in one of the memory banks in the first bank region BG1 of the first cell die 431. In the first data input/output mode, 16 serial data signals transmitted from the external apparatus may be converted into 256 parallel data signals by the logic die 420. Because each of the first bonding wires 451 and the second bonding wires 452 is 128 in number, the 256 parallel data signals cannot be transmitted through only one of the first and second bonding wires 451 and 452. Therefore, in the first data input/output mode, the logic die 420 may access the first and second cell dies 431 and 432 simultaneously and perform a data input/output operation with the first and second cell dies 431 and 432 simultaneously. The logic die 420 may transmit half of the 256 parallel data signals to the first cell die 431 through the first bonding wires 451, and transmit the remaining half of the parallel data signals to the second cell die 432 through the second bonding wires 452. Likewise, in the first data input/output mode, the logic die 420 may access the third and fourth cell dies 433 and 434, the fifth and sixth cell dies 435 and 436, or the seventh and eighth cell dies 437 and 438 simultaneously and perform a data input/output operation. For example, as schematically indicated by the area with diagonal lines in FIG. 4B, half of the 256 parallel data signals may be stored in one of the memory banks in the first bank group BG1 of the first cell die 431, that is, the first memory bank BK1, and the remaining half of the parallel data signals may be stored in one of the memory banks in the fifth bank group BG5 of the second cell die 432, that is, the ninth memory bank BK9. A data transmission operation from the semiconductor apparatus 400 to the external apparatus may also be performed in a similar manner.

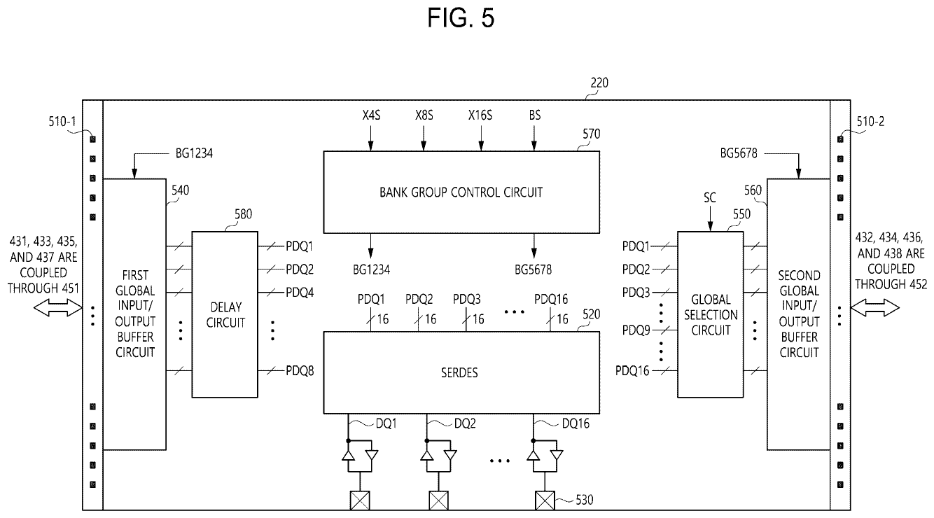

FIG. 5 is a diagram illustrating a configuration of the logic die 220 according to an embodiment of the present disclosure. Referring to FIGS. 4A, 4B, and 5 together, the logic die 220 may include a serializer/deserializer 520, a first global input/output buffer circuit 540, a global selection circuit 550, a second global input/output buffer circuit 560, and a bank group control circuit 570. When the number N of data transmission lines is 16 and a burst length k is 16, the serializer/deserializer 520 may be coupled between N data transmission lines and N*k data input/output lines. The N data transmission lines may be signal transmission lines through which the logic die 220 is coupled to the external apparatus by the third signal transmission lines 415. The N*k data input/output lines may be signal transmission lines through which the logic die 220 is coupled to a plurality of cell dies by the first and second signal transmission lines 413 and 414. For example, when N is 16 and k is 16, the serializer/deserializer 520 may be coupled between 16 data transmission lines DQ1 to DQ16 and 256 data input/output lines. The 16 data transmission lines DQ1 to DQ16 may be coupled to external data pads 530 of the logic die 220. For signal transmission between the serializer/deserializer 520 and the external data pads 530, each of the external data pads 530 may be provided with a receiver and a transmitter. The serializer/deserializer 520 may serialize data signals on the 256 data input/output lines into data signals on the 16 data transmission lines DQ1 to DQ16. The serializer/deserializer may also deserialize data signals on the 16 data transmission lines DQ1 to DQ16 into data signals on the 256 data input/output lines. In FIG. 5, the serializer/deserializer 520 is shown coupled to 16 data input/output line groups PDQ1 to PDQ16, each of which may include 16 data input/output lines.

The first global input/output buffer circuit 540 may be coupled to half of the 256 data input/output lines. For example, the first global input/output buffer circuit 540 may be coupled to the first to eighth data input/output line groups PDQ1-PDQ8, and thereby coupled to first to 128th data input/output lines. The first global input/output buffer circuit 540 may be coupled to the first bonding wires 451, and may be coupled to the first, third, fifth, and seventh cell dies 431, 433, 435, and 437 through the first bonding wires 451. The logic die 220 includes a first internal data pad 510-1, and the first global input/output buffer circuit 540 may be coupled to the first bonding wires 451 through the first internal data pad 510-1, the bumps 421, and the first signal transmission lines 413. The first global input/output buffer circuit 540 may couple the first to eighth data input/output line groups PDQ1-PDQ8 or the 128 data input/output lines to the first, third, fifth, and seventh cell dies 431, 433, 435, and 437 through the first bonding wires 451 based on a first bank group selection signal BG1234. When the first bank group selection signal BG1234 is disabled, the first global input/output buffer circuit 540 may be disabled. When the first bank group selection signal BG1234 is enabled, the first global input/output buffer circuit 540 may buffer data signals on the first to eighth data input/output line groups PDQ1-PDQ8 and transmit the buffered data signals to the first, third, fifth, and seventh cell dies 431, 433, 435, and 437 through the first bonding wires 451. In addition, the first global input/output buffer circuit 540 may buffer data signals transmitted from the first, third, fifth, and seventh cell dies 431, 433, 435, and 437 through the first bonding wires 451 and output the buffered data signals to the first to eighth data input/output line groups PDQ1-PDQ8. The first global input/output buffer circuit 540 may be disposed on a first side of the logic die 220, which is adjacent to the first side of the first, third, fifth, and seventh cell dies 431, 433, 435, and 437.

The global selection circuit 550 may be coupled to the first to sixteenth data input/output line groups PDQ1-PDQ16. The global selection circuit 550 may select either the first to eighth data input/output line groups PDQ1-PDQ8 or the ninth to sixteenth data input/output line groups PDQ9-PDQ16 based on a data input/output mode. In the first data input/output mode, the global selection circuit 550 may select the ninth to sixteenth data input/output line groups PDQ9-PDQ16, and in the second and third data input/output modes, the global selection circuit 550 may select the first to eighth data input/output line groups PDQ1-PDQ8. The global selection circuit 550 may receive a selection control signal SC. The selection control signal SC may be generated based on the data input/output mode. For example, in the first data input/output mode, the selection control signal SC may have a first logic level, and in the second and third data input/output modes, the selection control signal SC may have a second logic level. When the selection control signal SC has the first logic level, the global selection circuit 550 may select the ninth to sixteenth data input/output line groups PDQ9-PDQ16, and when the selection control signal SC has the second logic level, the global selection circuit 550 may select the first to eighth data input/output line groups PDQ1-PDQ8.

The second global input/output buffer circuit 560 may be coupled to the global selection circuit 550. The second global input/output buffer circuit 560 may be coupled to either the half of the 256 data input/output lines or the remaining half of the data input/output lines as selected by the global selection circuit 550. For example, the second global input/output buffer circuit 560 may be coupled to the first to eighth data input/output line groups PDQ1-PDQ8 and may be coupled to the first to 128th data input/output lines. Alternatively, the second global input/output buffer circuit 560 may be coupled to the ninth to sixteenth data input/output line groups PDQ9-PDQ16 and may be coupled to the 129th to 256th data input/output lines. The second global input/output buffer circuit 560 may be coupled to the second bonding wires 452 and may be coupled to the second, fourth, sixth, and eighth cell dies 432, 434, 436, and 438 through the second bonding wires 452. The logic die 220 includes a second internal data pad 510-2, and the second global input/output buffer circuit 560 may be coupled to the second bonding wires 452 through the second internal data pad 510-2, the bumps 421, and the second signal transmission lines 414. The second global input/output buffer circuit 560 may couple the data input/output line groups selected by the global selection circuit 550 to the second, fourth, sixth, and eighth cell dies 432, 434, 436, and 438 through the second bonding wires 452, based on a second bank group selection signal BG5678. When the second bank group selection signal BG5678 is disabled, the second global input/output buffer circuit 560 may be deactivated. When the second bank group selection signal BG5678 is enabled, the second global input/output buffer circuit 560 may buffer the data signals on the data input/output line groups selected by the global selection circuit 550 and transmit the buffered data signals to the second, fourth, sixth, and eighth cell dies 432, 434, 436, and 438 through the second bonding wires 452. In addition, the second global input/output buffer circuit 560 may buffer data signals transmitted from the second, fourth, sixth, and eighth cell dies 432, 434, 436, and 438 through the second bonding wires 452, and may output the buffered data signals to the data input/output line groups selected by the global selection circuit 550. The second global input/output buffer circuit 560 may be disposed on a second side of the logic die 220, which is adjacent to the first side of the second, fourth, sixth, and eighth cell dies 432, 434, 436, and 438.

The bank group control circuit 570 may generate the first bank group selection signal BG1234 and the second bank group selection signal BG5678 based on a data input/output mode and a bank group address signal BS. The bank group control circuit 570 may receive the data input/output mode signal and the bank group address signal BS. The data input/output mode signal may include a first data input/output mode signal x16S, a second data input/output mode signal x4S, and a third data input/output mode signal x8S. The first data input/output mode signal x16S may be enabled in the first data input/output mode. The second data input/output mode signal x4S may be enabled in the second data input/output mode. The third data input/output mode signal x8S may be enabled in the third data input/output mode. The bank group control circuit 570 may generate the first and second bank group selection signals BG1234 and BG5678 according to the first to third data input/output mode signals x16S, x4S, and x8S and the bank group address signal BS. The bank group address signal BS may be at least one bit among a plurality of bits of a bank group address signal. For example, the bank group address signal BS may include information identifying either the first to fourth bank groups BG1, BG2, BG3, and BG4 or the fifth to eighth bank groups BG5, BG6, BG7, and BG8. When the bank group address signal BS is at a first logic level, one of the first to fourth bank groups BG1, BG2, BG3, and BG4 may be accessed. When the bank group address signal BS is at a second logic level, one of the fifth to eighth bank groups BG5, BG6, BG7, and BG8 may be accessed. The bank group control circuit 570 may enable the first bank group selection signal BG1234 and disable the second bank group selection signal BG5678 when the bank group address signal BS is at a logic low level and one of the second and third data input/output mode signals x4S and x8S is enabled. The bank group control circuit 570 may enable the second bank group selection signal BG5678 and disable the first bank group selection signal BG1234 when the bank group address signal BS is at a logic high level and one of the second and third data input/output mode signals x4S and x8S is enabled. The bank group control circuit 570 may enable both the first and second bank group selection signals BG1234 and BG5678 regardless of the bank group address signal BS when the first data input/output mode signal x16S is enabled.

The logic die 220 may further include a delay circuit 580. The delay circuit 580 may be coupled between the first to eighth data input/output line groups PDQ1-PDQ8 and the first global input/output buffer circuit 540. The delay circuit 580 may delay data signals on the first to eighth data input/output line groups PDQ1-PDQ8 and provide the delayed data signals to the first global input/output buffer circuit 540. The delay circuit 580 may delay data signals output from the first global input/output buffer circuit 540 and output the delayed data signals to the first to eighth data input/output line groups PDQ1-PDQ8. In order to reduce a timing skew between the first global input/output buffer circuit 540 and the second global input/output buffer circuit 560, a delay time of the delay circuit 580 may be set to be substantially the same as a propagation delay time occurring in the global selection circuit 550. Although not shown, the logic die 220 may further include an error correction circuit that performs an error correction operation on data signals transmitted through the first to sixteenth data input/output line groups PDQ1-PDQ16.

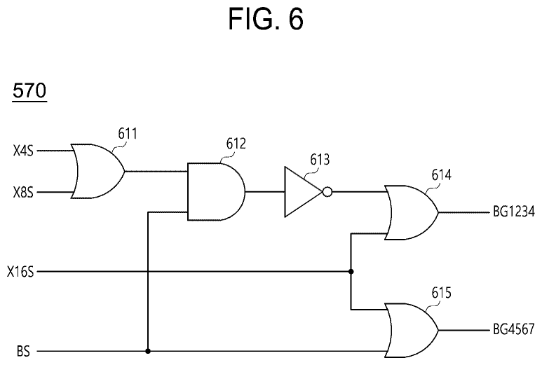

FIG. 6 is a diagram illustrating a configuration of the bank group control circuit 570 illustrated in FIG. 5. The bank group control circuit 570 may include a first OR gate 611, an AND gate 612, an inverter 613, a second OR gate 614, and a third OR gate 615. The first OR gate 611 may receive the second data input/output mode signal x4S and the third data input/output mode signal x8S. The AND gate 612 may receive an output signal of the first OR gate 611 and the bank group address signal BS. The inverter 613 may invert an output signal of the AND gate 612. The second OR gate 614 may receive an output signal of the inverter 613 and the first data input/output mode signal x16S and may output the first bank group selection signal BG1234. The third OR gate 615 may receive the first data input/output mode signal x16S and the bank group address signal BS and may output the second bank group selection signal BG5678.

TABLE 1

| x4S | x8S | x16S | BS | BG1234 | BG5678 |
|---|---|---|---|---|---|
| H | L | L | L | Enable | Disable |
| H | L | L | H | Disable | Enable |
| L | H | L | L | Enable | Disable |
| L | H | L | H | Disable | Enable |
| L | L | H | L or H | Enable | Enable |

Referring to Table 1, the bank group control circuit 570 may enable the first bank group selection signal BG1234 and disable the second bank group selection signal BG5678 when the second data input/output mode signal x4S is enabled to a high logic level in the second data input/output mode and the bank group address signal BS is at a low logic level. The bank group control circuit 570 may enable the second bank group selection signal BG5678 and disable the first bank group selection signal BG1234 when the second data input/output mode signal x4S is enabled to a high logic level in the second data input/output mode and the bank group address signal BS is at a high logic level. The bank group control circuit 570 may enable the first bank group selection signal BG1234 and disable the second bank group selection signal BG5678 when the third data input/output mode signal x8S is enabled to a high logic level in the third data input/output mode and the bank group address signal BS is at a low logic level. The bank group control circuit 570 may enable the second bank group selection signal BG5678 and disable the first bank group selection signal BG1234 when the third data input/output mode signal x8S is enabled to a high logic level in the third data input/output mode and the bank group address signal BS is at a high logic level. The bank group control circuit 570 may enable both the first and second bank group selection signals BG1234 and BG5678 regardless of the logic level (L or H) of the bank group address signal BS when the first data input/output mode signal x16S is enabled to a high logic level in the first data input/output mode.

Referring to FIGS. 4A to 6, an operation of a semiconductor apparatus according to an embodiment of the present disclosure will be described as follows. For example, an operation in which the semiconductor apparatus 400 receives data transmitted from the external apparatus will be described. In the second data input/output mode, when the bank group address signal BS is at a low logic level, the logic die 220 may deserialize data signals transmitted through four data transmission lines into 64 parallel data signals and output the parallel data signals to four data input/output line groups (e.g., the first to fourth data input/output line groups PDQ1 to PDQ4) among the first to eighth data input/output line groups PDQ1 to PDQ8. The bank group control circuit 570 may enable the first bank group signal BG1234 and disable the second bank group signal BG5678. The first global input/output buffer circuit 540 may buffer the data signals on the first to fourth data input/output line groups PDQ1 to PDQ4 and transmit the buffered data signals to one of the first, third, fifth, and seventh cell dies 431, 433, 435, and 437. Conversely, when the bank group address signal BS is at a high logic level, the global selection circuit 550 may select the first to eighth data input/output line groups PDQ1 to PDQ8, and the bank group control circuit 570 may disable the first bank group selection signal BG1234 and enable the second bank group selection signal BG5678. The second global input/output buffer circuit 560 may buffer the data signals on the first to fourth data input/output line groups PDQ1 to PDQ4 and transmit the buffered data signals to one of the second, fourth, sixth, and eighth cell dies 432, 434, 436, and 438.

In the third data input/output mode, when the bank group address signal BS is at a logic low level, the logic die 220 may deserialize data signals transmitted through eight data transmission lines and output 128 deserialized data signals to the first to eighth data input/output line groups PDQ1 to PDQ8. The bank group control circuit 570 may enable the first bank group signal BG1234 and disable the second bank group signal BG5678. The first global input/output buffer circuit 540 may buffer the data signals on the first to eighth data input/output line groups PDQ1 to PDQ8 and transmit the buffered data signals to one of the first, third, fifth, and seventh cell dies 431, 433, 435, and 437. Conversely, when the bank group address signal BS is at a logic high level, the global selection circuit 550 may select the first to eighth data input/output line groups PDQ1 to PDQ8, and the bank group control circuit 570 may disable the first bank group selection signal BG1234 and enable the second bank group selection signal BG5678. The second global input/output buffer circuit 560 may buffer the data signals on the first to eighth data input/output line groups PDQ1 to PDQ8 and transmit the buffered data signals to one of the second, fourth, sixth, and eighth cell dies 432, 434, 436, and 438.

In the first data input/output mode, the logic die 220 may deserialize data signals transmitted through sixteen data transmission lines and output 256 deserialized data signals to the first to sixteenth data input/output line groups PDQ1 to PDQ16. The global selection circuit 550 may select the ninth to sixteenth data input/output line groups PDQ9 to PDQ16, and the bank group control circuit 570 may enable both the first and second bank group selection signals BG1234 and BG5678. The first global input/output buffer circuit 540 may buffer the data signals on the first to eighth data input/output line groups PDQ1 to PDQ8 and transmit the buffered data signals to one of the first, third, fifth, and seventh cell dies 431, 433, 435, and 437. The second global input/output buffer circuit 560 may buffer the data signals on the ninth to sixteenth data input/output line groups PDQ9 to PDQ16 and transmit the buffered data signals to one of the second, fourth, sixth, and eighth cell dies 432, 434, 436, and 438. Accordingly, 128 of the 256 data signals may be transmitted to and stored in one of the first, third, fifth, and seventh cell dies 431, 433, 435, and 437, and the remaining 128 data signals may be transmitted to and stored in one of the second, fourth, sixth, and eighth cell dies 432, 434, 436, and 438.

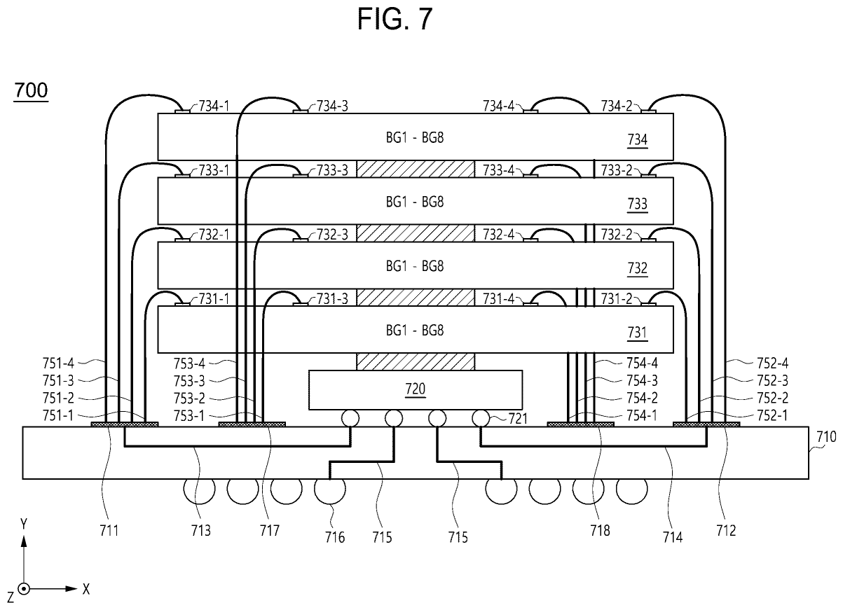

FIG. 7 is a diagram illustrating a configuration and connection relationship of a semiconductor apparatus 700 according to an embodiment of the present disclosure. Referring to FIG. 7, the semiconductor apparatus 700 may include a package substrate 710, a logic die 720, and a plurality of cell dies 731, 732, 733, and 734. The logic die 720 and the plurality of cell dies 731, 732, 733, and 734 may be disposed on the package substrate 710 and may be packaged in a single package. Without intending to be limiting, for example, the plurality of cell dies may include a first cell die 731, a second cell die 732, a third cell die 733, and a fourth cell die 734. The number of cell dies included in the semiconductor apparatus 700 may be any number equal to or greater than two. The logic die 720 may be disposed in a y-axis direction on the package substrate 710. The logic die 720 may be disposed at a central portion of the package substrate 710 with respect to the x-axis and z-axis directions. The logic die 720 may include bumps 721 and may be coupled to the package substrate 710 through the bumps 721. The first cell die 731 may be disposed in a y-axis direction on the logic die 720. The first cell die 731 may be disposed to cover a part or all of the logic die 720 in the y-axis direction. The first cell die 731 may be bonded onto the logic die 720 using an adhesive or a die attach film. The second cell die 732 may be disposed in a y-axis direction on the first cell die 731. The second cell die 732 may be aligned with the first cell die 731 in the x-axis and z-axis directions. The third cell die 733 may be disposed in a y-axis direction on the second cell die 732. The third cell die 733 may be aligned with the first and second cell dies 731 and 732 in the x-axis and z-axis directions. The fourth cell die 734 may be disposed in a y-axis direction on the third cell die 733. The fourth cell die 734 may be aligned with the first to third cell dies 731, 732, and 733 in the x-axis and z-axis directions. The second to fourth cell dies 732, 733, and 734 may be respectively bonded onto the first to third cell dies 731, 732, and 733 using a die attach film. The first to fourth cell dies 731, 732, 733, and 734 may respectively include first data pads 731-1, 732-1, 733-1, and 734-1 disposed in an area on a first side of the cell die. The first to fourth cell dies 731, 732, 733, and 734 may respectively include second data pads 731-2, 732-2, 733-2, and 734-2 disposed in an area on a second side of the cell die facing the first side in an x-axis direction.

The package substrate 710 may include first pads 711, second pads 712, first signal transmission lines 713, second signal transmission lines 714, and third signal transmission lines 715. The first and second pads 711 and 712 may be provided on the package substrate 710, and the first to third signal transmission lines 713, 714, and 715 may be provided in the package substrate 710. For example, the first pads 711 may be provided on a first side of the package substrate 710 in an x-axis direction (i.e., a left portion of the package substrate 710 in FIG. 7), and the second pads 712 may be provided on a second side of the package substrate 710 in an x-axis direction (i.e., a right portion of the package substrate 710 in FIG. 7). The first pads 711 may be provided at a distance spaced apart from the first side of the first cell die 731 in an x-axis direction. The second pads 712 may be provided at a distance spaced apart from the second side of the first cell die 731 in an x-axis direction. The first cell die 731 may be coupled to the first pads 711 through first bonding wires 751-1 and to the second pads 712 through second bonding wires 752-1. The first data pads 731-1 provided on the first side of the first cell die 731 may be coupled to the first pads 711 through the first bonding wires 751-1. The second data pads 731-2 provided on the second side of the first cell die 731 may be coupled to the second pads 712 through the second bonding wires 752-1. The second cell die 732 may be coupled to the first pads 711 through third bonding wires 751-2 and to the second pads 712 through fourth bonding wires 752-2. The first data pads 732-1 provided on the first side of the second cell die 732 may be coupled to the first pads 711 through the third bonding wires 751-2. The second data pads 732-2 provided on the second side of the second cell die 732 may be coupled to the second pads 712 through the fourth bonding wires 752-2. The third cell die 733 may be coupled to the first pads 711 through fifth bonding wires 751-3 and to the second pads 712 through sixth bonding wires 752-3. The first data pads 733-1 provided on the first side of the third cell die 733 may be coupled to the first pads 711 through the fifth bonding wires 751-3. The second data pads 733-2 provided on the second side of the third cell die 733 may be coupled to the second pads 712 through the sixth bonding wires 752-3. The fourth cell die 734 may be coupled to the first pads 711 through seventh bonding wires 751-4 and to the second pads 712 through eighth bonding wires 752-4. The first data pads 734-1 provided on the first side of the fourth cell die 734 may be coupled to the first pads 711 through the seventh bonding wires 751-4. The second data pads 734-2 provided on the second side of the fourth cell die 734 may be coupled to the second pads 712 through the eighth bonding wires 752-4. The logic die 720 may be coupled to the first pads 711 through the first signal transmission lines 713 and may be coupled to the second pads 712 through the second signal transmission lines 714. The logic die 720 may be coupled to the first data pads 731-1, 732-1, 733-1, and 734-1 of the first to fourth cell dies 731, 732, 733, and 734 through the first signal transmission lines 713, the first pads 711, and the first, third, fifth, and seventh bonding wires 751-1, 751-2, 751-3, and 751-4. The logic die 720 may be coupled to the second data pads 731-2, 732-2, 733-2, and 734-2 of the first to fourth cell dies 731, 732, 733, and 734 through the second signal transmission lines 714, the second pads 712, and the second, fourth, sixth, and eighth bonding wires 752-1, 752-2, 752-3, and 752-4. The logic die 720 may be coupled to an external apparatus of the semiconductor apparatus 700 through the third signal transmission lines 715. The package substrate 710 may include package balls 716, and the third signal transmission lines 715 may be coupled to the external apparatus through the package balls 716. The logic die 720 may deserialize signals on the third signal transmission lines 715 into signals on the first and second signal transmission lines 713 and 714, and may serialize signals on the first and second signal transmission lines 713 and 714 into signals on the third signal transmission lines 715. The logic die 720 may perform an error correction operation on the signals on the first and second signal transmission lines 713 and 714.

The first to fourth cell dies 731, 732, 733, and 734 may respectively include power pads 731-3, 731-4, 732-3, 732-4, 733-3, 733-4, 734-3, and 734-4 on a third side located between and perpendicular to the first side and the second side, and on a fourth side facing the third side in a z-axis direction. The package substrate 710 may further include a third pad 717 and a fourth pad 718. The third pad 717 may be provided on a third side of the package substrate 710 located between the first side and the second side (i.e., a front portion of the package substrate 710 in FIG. 7). The fourth pad 718 may be provided on a fourth side of the package substrate 710 facing the third side in a z-axis direction (i.e., a rear portion of the package substrate 710 in FIG. 7). The third pad 717 may be provided at a distance from the third side of the first cell die 731 in a z-axis direction. The fourth pad 718 may be provided at a distance from the fourth side of the first cell die 731 in a z-axis direction. The power pads 731-3, 732-3, 733-3, and 734-3 provided on the third side of the first to fourth cell dies 731, 732, 733, and 734 may respectively be coupled to the third pad 717 through bonding wires 753-1, 753-2, 753-3, and 753-4. The power pads 731-4, 732-4, 733-4, and 734-4 provided on the fourth side of the first to fourth cell dies 731, 732, 733, and 734 may respectively be coupled to the fourth pad 718 through bonding wires 754-1, 754-2, 754-3, and 754-4. A power supply voltage may be supplied through the third pad 717 and the fourth pad 718. The power supply voltage may be supplied to the power pads 731-3, 732-3, 733-3, 734-3, 731-4, 732-4, 733-4, and 734-4 of the first to fourth cell dies 731, 732, 733, and 734 through the third pad 717, the fourth pad 718, and the bonding wires 753-1, 753-2, 753-3, 753-4, 754-1, 754-2, 754-3, and 754-4.

The first to fourth cell dies 731, 732, 733, and 734 may be coupled to the first pads 711 of the package substrate 710 at the first side, as well as the second pads 712 of the package substrate 710 at the second side. Compared to the semiconductor apparatus 400 shown in FIG. 4A, the first to fourth cell dies 731, 732, 733, and 734 may each include all bank groups that are accessed based on a single address group. For example, the first to fourth cell dies 731, 732, 733, and 734 may each include first to eighth bank groups BG1 to BG8. The first cell die 731 may include first to eighth bank groups BG1 to BG8 that are accessed based on a first address group, and the second cell die 732 may include first to eighth bank groups BG1 to BG8 that are accessed based on a second address group. The third cell die 733 may include first to eighth bank groups BG1 to BG8 that are accessed based on a third address group. The fourth cell die 734 may include first to eighth bank groups BG1 to BG8 that are accessed based on a fourth address group. Among the plurality of bank groups, half of the bank groups may be respectively coupled to the logic die 720 through the first data pads 731-1, 732-1, 733-1, and 734-1 provided on the first side of the first to fourth cell dies 731, 732, 733, and 734. The remaining half of the bank groups may be respectively coupled to the logic die 720 through the second data pads 731-2, 732-2, 733-2, and 734-2 provided on the second side of the first to fourth cell dies 731, 732, 733, and 734. While the first to fourth cell dies 731, 732, 733, and 734 have a larger area than the first to eighth cell dies 431, 432, 433, 434, 435, 436, 437, and 438, the semiconductor apparatus 700 may implement the same capacity as the semiconductor apparatus 400 with fewer cell dies. In addition, because the first to fourth cell dies 731, 732, 733, and 734 may be disposed on the logic die 720 instead of being adjacent to the logic die 720, a package size of the semiconductor apparatus 700 may be reduced.

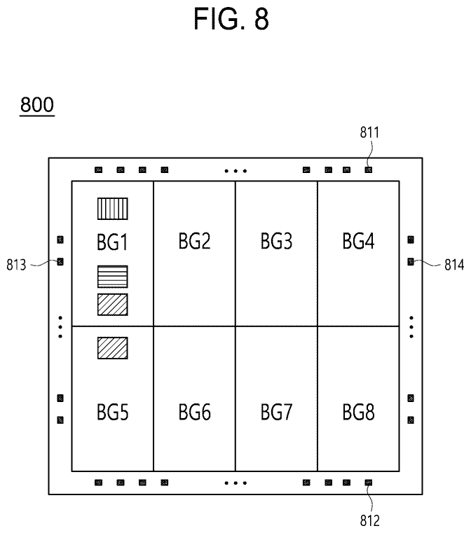

FIG. 8 is a diagram illustrating a configuration of a cell die 800 according to an embodiment of the present disclosure. The first to fourth cell dies 731, 732, 733, and 734 illustrated in FIG. 7 may each have substantially the same structure as the cell die 800. Referring to FIG. 8, in a plan view, the cell die 800 may include first data pads 811 on a first side. The cell die 800 may include second data pads 812 on a second side facing the first side. The first and second sides may correspond to portions adjacent to two longer sides among four sides of the cell die 800. A plurality of bank groups accessed based on a single address group may be disposed at a central portion of the cell die 800. For example, the cell die 800 may include first to eighth bank groups BG1 to BG8. As illustrated in FIG. 4B, the first to eighth bank groups BG1 to BG8 may each include four memory banks. The first to fourth bank groups BG1 to BG4 may be disposed adjacent to the first side and may be coupled to the first data pads 811 provided on the first side. The fifth to eighth bank groups BG5 to BG8 may be disposed adjacent to the second side and may be coupled to the second data pads 812 provided on the second side. The cell die 800 may include power pads 813 at a third side between the first side and the second side. The third side may correspond to a portion adjacent to one of two shorter sides among the four sides of the cell die 800. The cell die 800 may include power pads 814 at a fourth side facing the third side. The fourth side may correspond to a portion adjacent to the other one of the two shorter sides. The cell die 800 may receive a power supply voltage through the power pads 813 and 814.

Referring also to FIG. 7, the first data pads 731-1, 732-1, 733-1, and 734-1 provided on the first sides of the first to fourth cell dies 731, 732, 733, and 734 may be coupled to the first pads 711 of the package substrate 710 through the first, third, fifth, and seventh bonding wires 751-1, 751-2, 751-3, and 751-4, respectively, and the first pads 711 may be coupled to the logic die 720 through the first signal transmission lines 713. The number of the first, third, fifth, and seventh bonding wires 751-1, 751-2, 751-3, and 751-4 may each be N*K/2, and the number of the first signal transmission lines 713 may also be N*K/2. The second data pads 731-2, 732-2, 733-2, and 734-2 provided on the second sides of the first to fourth cell dies 731, 732, 733, and 734 may be coupled to the second pads 712 of the package substrate 710 through the second, fourth, sixth, and eighth bonding wires 752-1, 752-2, 752-3, and 752-4, and the second pads 712 may be coupled to the logic die 720 through the second signal transmission lines 714. The number of the second, fourth, sixth, and eighth bonding wires 752-1, 752-2, 752-3, and 752-4 may each be N*K/2, and the number of the second signal transmission lines 714 may also be N*K/2. The number of the third signal transmission lines 715 may be N, 2N, or 4N. The semiconductor apparatus 700 may support a plurality of data input/output modes. The plurality of data input/output modes may include a first data input/output mode, a second data input/output mode, and a third data input/output mode. When the semiconductor apparatus 700 supports all of the first to third data input/output modes, for example, the number of the third signal transmission lines 715 may be 16 (e.g., N is 16) and a burst length may be 16 (e.g., K is 16). A data transmission operation from the external apparatus to the semiconductor apparatus 700 is described as follows. In the second data input/output mode, four serial data signals transmitted from the external apparatus may be converted into 64 parallel data signals by the logic die 720. Because the first to eighth bonding wires 751-1, 752-1, 751-2, 752-2, 751-3, 752-3, 751-4, and 752-4 are each 128 in number, the 64 parallel data signals may be transmitted through any one of the first to eighth bonding wires 751-1, 752-1, 751-2, 752-2, 751-3, 752-3, 751-4, and 752-4. Accordingly, in the second data input/output mode, the logic die 720 may access one of the first to fourth cell dies 731, 732, 733, and 734 and may perform a data input/output operation with the accessed cell die. The logic die 720 may transmit the 64 parallel data signals through either the first data pads provided on the first side of the accessed cell die or the second data pads provided on the second side of the accessed cell die. For example, as schematically indicated by the area with vertical lines in FIG. 8, the 64 parallel data signals may be stored in one of the memory banks in the first bank group BG1. In the third data input/output mode, eight serial data signals transmitted from the external apparatus may be converted into 128 parallel data signals by the logic die 720. Because the first to eighth bonding wires 751-1, 752-1, 751-2, 752-2, 751-3, 752-3, 751-4, and 752-4 are each 128 in number, the 128 parallel data signals may be transmitted through any one of the first to eighth bonding wires 751-1, 752-1, 751-2, 752-2, 751-3, 752-3, 751-4, and 752-4. Accordingly, in the third data input/output mode, the logic die 720 may access one of the first to fourth cell dies 731, 732, 733, and 734 and may perform a data input/output operation with the accessed cell die. The logic die 720 may transmit the 128 parallel data signals through either the first data pads provided on the first side of the accessed cell die or the second data pads provided on the second side of the accessed cell die. For example, as schematically indicated by the area with horizontal lines in FIG. 8, the 128 parallel data signals may be stored in one of the memory banks in the first bank group BG1. In the first data input/output mode, sixteen serial data signals transmitted from the external apparatus may be converted into 256 parallel data signals by the logic die 720. Because the first to eighth bonding wires 751-1, 752-1, 751-2, 752-2, 751-3, 752-3, 751-4, and 752-4 are each 128 in number, 128 of the 256 parallel data signals may be transmitted through the first, third, fifth, and seventh bonding wires 751-1, 751-2, 751-3, and 751-4, and the remaining 128 parallel data signals may be transmitted through the second, fourth, sixth, and eighth bonding wires 752-1, 752-2, 752-3, and 752-4. Accordingly, in the first data input/output mode as well, the logic die 720 may access one of the first to fourth cell dies 731, 732, 733, and 734 and may perform a data input/output operation with the accessed cell die. The logic die may transmit the 256 parallel data signals through the first data pads provided on the first side of the accessed cell die and the second data pads provided on the second side of the accessed cell die. For example, the logic die 720 may transmit half of the 256 parallel data signals to the first data pads 731-1 provided on the first side of the first cell die 731 through the first bonding wires 751-1, and may transmit the remaining half of the parallel data signals to the second data pads 731-2 provided on the second side of the first cell die 731 through the second bonding wires 752-1. Likewise, in the first data input/output mode, the logic die 720 may perform a data input/output operation with the second cell die 732 through the third and fourth bonding wires 751-2 and 752-2, with the third cell die 733 through the fifth and sixth bonding wires 751-3 and 752-3, and with the fourth cell die 734 through the seventh and eighth bonding wires 751-4 and 752-4. For example, as schematically indicated by the area with diagonal lines in FIG. 8, half of the 256 parallel data signals may be stored in one of the memory banks in the first bank group BG1, and the remaining half of the parallel data signals may be stored in one of the memory banks in the fifth bank group BG5. A data transmission operation from the semiconductor apparatus 700 to the external apparatus may also be performed in a similar manner.

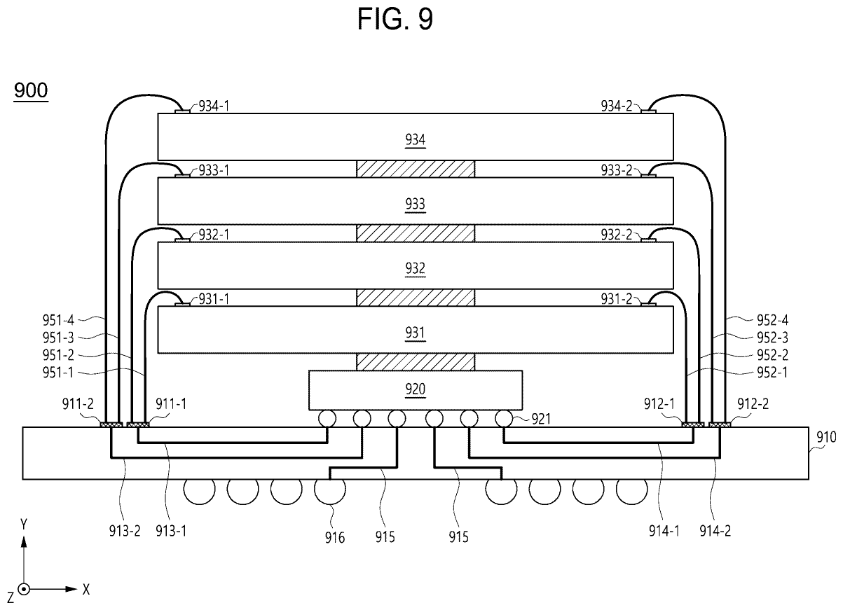

FIG. 9 is a diagram illustrating a configuration and connection relationship of a semiconductor apparatus 900 according to an embodiment of the present disclosure. Referring to FIG. 9, the semiconductor apparatus 900 may include a package substrate 910, a logic die 920, and a plurality of cell dies 931, 932, 933, and 934. The logic die 920 and the plurality of cell dies 931, 932, 933, and 934 may be disposed on the package substrate 910 and may be packaged into a single package. Without intending to be limiting, for example, the plurality of cell dies may include a first cell die 931, a second cell die 932, a third cell die 933, and a fourth cell die 934. The number of cell dies included in the semiconductor apparatus 900 may be any number that is a multiple of two. The logic die 920 may be disposed in a y-axis direction on the package substrate 910 and may be disposed at a central portion of the package substrate 910 in x-axis and z-axis directions. The logic die 920 may include bumps 921 and may be coupled to the package substrate 910 through the bumps 921. The first cell die 931 may be disposed on the logic die 920 in a y-axis direction and may be disposed to cover at least a part or all of the logic die 920. The first cell die 931 may be bonded onto the logic die 920 using an adhesive or a die attach film. The second cell die 932 may be disposed on the first cell die 931 in a y-axis direction and may be aligned with the first cell die 931 in x-axis and z-axis directions. The third cell die 933 may be disposed on the second cell die 932 in a y-axis direction and may be aligned with the first and second cell dies 931 and 932 in the x-axis and z-axis directions. The fourth cell die 934 may be disposed on the third cell die 933 in a y-axis direction and may be aligned with the first to third cell dies 931, 932, and 933 in the x-axis and z-axis directions. The second to fourth cell dies 932, 933, and 934 may be bonded onto the first to third cell dies 931, 932, and 933, respectively, using a die attach film. The first to fourth cell dies 931, 932, 933, and 934 may respectively include first data pads 931-1, 932-1, 933-1, and 934-1 on a first side. The first to fourth cell dies 931, 932, 933, and 934 may respectively include second data pads 931-2, 932-2, 933-2, and 934-2 on a second side facing the first side in an x-axis direction.

The package substrate 910 may include first pads 911-1, second pads 912-1, third pads 911-2, fourth pads 912-2, first signal transmission lines 913-1, second signal transmission lines 914-1, third signal transmission lines 913-2, fourth signal transmission lines 914-2, and fifth signal transmission lines 915. The first to fourth pads 911-1, 912-1, 911-2, and 912-2 may be provided on the package substrate 910, and the first to fifth signal transmission lines 913-1, 914-1, 913-2, 914-2, and 915 may be provided in the package substrate 910. For example, the first and third pads 911-1 and 911-2 may be provided on a first side (i.e., the left side of the package substrate 910 in FIG. 9) of the package substrate 910 in an x-axis direction, and the second and fourth pads 912-1 and 912-2 may be provided on a second side (i.e., the right side of the package substrate 910 in FIG. 9) of the package substrate 910 in an x-axis direction. The first pads 911-1 may be provided at a distance spaced in an x-axis direction from the first side of the first cell die 931. The third pads 911-2 may be provided at a distance spaced in an x-axis direction from the first pads 911-1. For example, the third pads 911-2 may be provided at a farther distance in an x-axis direction from the first cell die 931 than the first pads 911-1. The second pads 912-1 may be provided at a distance spaced in an x-axis direction from the second side of the first cell die 931. The fourth pads 912-2 may be provided at a distance spaced in an x-axis direction from the second pads 912-1. For example, the fourth pads 912-2 may be provided at a farther distance in an x-axis direction from the first cell die 931 than the second pads 912-1. The first cell die 931 may be coupled to the first pads 911-1 through first bonding wires 951-1 and to the second pads 912-1 through second bonding wires 952-1. The first data pads 931-1 provided on the first side of the first cell die 931 may be coupled to the first pads 911-1 through the first bonding wires 951-1. The second data pads 931-2 provided on the second side of the first cell die 931 may be coupled to the second pads 912-1 through the second bonding wires 952-1. The second cell die 932 may be coupled to the first pads 911-1 through third bonding wires 951-2 and to the second pads 912-1 through fourth bonding wires 952-2. The first data pads 932-1 provided on the first side of the second cell die 932 may be coupled to the first pads 911-1 through the third bonding wires 951-2. The second data pads 932-2 provided on the second side of the second cell die 932 may be coupled to the second pads 912-1 through the fourth bonding wires 952-2. The third cell die 933 may be coupled to the third pads 911-2 through fifth bonding wires 951-3 and to the fourth pads 912-2 through sixth bonding wires 952-3. The first data pads 933-1 provided on the first side of the third cell die 933 may be coupled to the third pads 911-2 through the fifth bonding wires 951-3. The second data pads 933-2 provided on the second side of the third cell die 933 may be coupled to the fourth pads 912-2 through the sixth bonding wires 952-3. The fourth cell die 934 may be coupled to the third pads 911-2 through seventh bonding wires 951-4 and to the fourth pads 912-2 through eighth bonding wires 952-4. The first data pads 934-1 provided on the first side of the fourth cell die 934 may be coupled to the third pads 911-2 through the seventh bonding wires 951-4. The second data pads 934-2 provided on the second side of the fourth cell die 934 may be coupled to the fourth pads 912-2 through the eighth bonding wires 952-4. The logic die 920 may be coupled to the first pads 911-1 through the first signal transmission lines 913-1 and to the second pads 912-1 through the second signal transmission lines 914-1. The logic die 920 may be coupled to the third pads 911-2 through the third signal transmission lines 913-2 and to the fourth pads 912-2 through the fourth signal transmission lines 914-2. The logic die 920 may be coupled to the first data pads 931-1 and 932-1, which are provided on the first sides of the first and second cell dies 931 and 932, through the first signal transmission lines 913-1, the first pads 911-1, and the first and third bonding wires 951-1 and 951-2, respectively. The logic die 920 may be coupled to the second data pads 931-2 and 932-2, which are provided on the second sides of the first and second cell dies 931 and 932, through the second signal transmission lines 914-1, the second pads 912-1, and the second and fourth bonding wires 952-1 and 952-2, respectively. The logic die 920 may be coupled to the first data pads 933-1 and 934-1, which are provided on the first sides of the third and fourth cell dies 933 and 934, respectively, through the third signal transmission lines 913-2, the third pads 911-2, and the fifth and seventh bonding wires 951-3 and 951-4. The logic die 920 may be coupled to the second data pads 933-2 and 934-2, which are provided on the second sides of the third and fourth cell dies 933 and 934, respectively, through the fourth signal transmission lines 914-2, the fourth pads 912-2, and the sixth and eighth bonding wires 952-3 and 952-4. The logic die 920 may be coupled to an external apparatus of the semiconductor apparatus 900 through the fifth signal transmission lines 915. The package substrate 910 may include package balls 916, and the fifth signal transmission lines 915 may be coupled to the external apparatus through the package balls 916. The logic die 920 may deserialize signals on the fifth signal transmission lines 915 into signals on the first to fourth signal transmission lines 913-1, 914-1, 913-2, and 914-2, and serialize the signals on the first to fourth signal transmission lines 913-1, 914-1, 913-2, and 914-2 into the signals on the fifth signal transmission lines 915. The logic die 920 may perform an error correction operation on the signals on the first to fourth signal transmission lines 913-1, 914-1, 913-2, and 914-2. Although not shown in FIG. 9, as illustrated in FIG. 7, the first to fourth cell dies 931, 932, 933, and 934 may include power pads on a third side and a fourth side facing the third side in a z-axis direction, and the package substrate 910 may also include pads for supplying a power voltage on a third side and a fourth side facing the third side in a z-axis direction. The power pads and the pads of the package substrate 910 may be coupled through bonding wires.

The first data pads 931-1 and 932-1 provided on the first side of the first and second cell dies 931 and 932 may be respectively coupled to the first pads 911-1 of the package substrate 910 through the first and third bonding wires 951-1 and 951-2, and the first pads 911-1 may be coupled to the logic die 920 through the first signal transmission lines 913-1. The number of the first and third bonding wires 951-1 and 951-2 may each be N*k/2, and the number of the first signal transmission lines 913-1 may also be N*k/2. The second data pads 931-2 and 932-2 provided on the second side of the first and second cell dies 931 and 932 may be respectively coupled to the second pads 912-1 of the package substrate 910 through the second and fourth bonding wires 952-1 and 952-2, and the second pads 912-1 may be coupled to the logic die 920 through the second signal transmission lines 914-1. The number of the second and fourth bonding wires 952-1 and 952-2 may each be N*k/2, and the number of the second signal transmission lines 914-1 may also be N*k/2. The first data pads 933-1 and 934-1 provided on the first side of the third and fourth cell dies 933 and 934 may be respectively coupled to the third pads 911-2 of the package substrate 910 through the fifth and seventh bonding wires 951-3 and 951-4, and the third pads 911-2 may be coupled to the logic die 920 through the third signal transmission lines 913-2. The number of the fifth and seventh bonding wires 951-3 and 951-4 may each be N*k/2, and the number of the third signal transmission lines 913-2 may also be N*k/2. The second data pads 933-2 and 934-2 provided on the second side of the third and fourth cell dies 933 and 934 may be respectively coupled to the fourth pads 912-2 of the package substrate 910 through the sixth and eighth bonding wires 952-3 and 952-4, and the fourth pads 912-2 may be coupled to the logic die 920 through the fourth signal transmission lines 914-2. The number of the sixth and eighth bonding wires 952-3 and 952-4 may each be N*k/2, and the number of the fourth signal transmission lines 914-2 may also be N*k/2. The number of the fifth signal transmission lines 915 may be N, 2N, or 4N.

The semiconductor apparatus 900 may support a plurality of data input/output modes. The plurality of data input/output modes may include a first data input/output mode, a second data input/output mode, and a third data input/output mode. When the semiconductor apparatus supports all of the first to third data input/output modes, for example, the number of the fifth signal transmission lines may be 16 (i.e., N is 16), and a burst length may be 16 or 32 (i.e., k is 16 or 32). The semiconductor apparatus 900 may operate with a larger burst length to increase bandwidth, and the burst length may be 32. For example, an operation in which data is transmitted from the external apparatus to the semiconductor apparatus 900 is described as follows. In the second data input/output mode, serial data signals received through the four external data pads of the logic die (not illustrated) and the fifth signal transmission lines 915 may be converted into 128 parallel data signals by the logic die 920. The 128 parallel data signals may be divided and transmitted to one of the first and second cell dies 931 and 932 and one of the third and fourth cell dies 933 and 934. The logic die 920 may access one of the first and second cell dies 931 and 932 and one of the third and fourth cell dies 933 and 934 at the same time. For example, the logic die 920 may simultaneously access the first and third cell dies 931 and 933. The logic die 920 may transmit 32 parallel data signals generated from the serial data signal received through a first external pad to the first cell die 931 through the first bonding wires 951-1, and may transmit 32 parallel data signals generated from the serial data signal received through a second external pad to the first cell die 931 through the second bonding wires 952-1. The logic die 920 may transmit 32 parallel data signals generated from the serial data signal received through a third external pad to the third cell die 933 through the fifth bonding wires 951-3, and may transmit 32 parallel data signals generated from the serial data signal received through a fourth external pad to the third cell die 933 through the sixth bonding wires 952-3.

In the third data input/output mode, the serial data signals received through the eight external data pads of the logic die (not illustrated) and the fifth signal transmission lines 915 may be converted into 256 parallel data signals by the logic die 920. The 256 parallel data signals may be divided and transmitted to one of the first and second cell dies 931 and 932 and one of the third and fourth cell dies 933 and 934. The logic die 920 may access one of the first and second cell dies 931 and 932 and one of the third and fourth cell dies 933 and 934 at the same time. For example, the logic die 920 may simultaneously access the first and third cell dies 931 and 933. The logic die 920 may transmit 32 parallel data signals generated from the serial data signal received through a first external pad and 32 parallel data signals generated from the serial data signal received through a fifth external pad to the first cell die 931 through the first bonding wires 951-1. The logic die 920 may transmit 32 parallel data signals generated from the serial data signal received through a second external pad and 32 parallel data signals generated from the serial data signal received through a sixth external pad to the first cell die 931 through the second bonding wires 952-1. The logic die 920 may transmit 32 parallel data signals generated from the serial data signal received through a third external pad and 32 parallel data signals generated from the serial data signal received through a seventh external pad to the third cell die 933 through the fifth bonding wires 951-3. The logic die 920 may transmit 32 parallel data signals generated from the serial data signal received through a fourth external pad and 32 parallel data signals generated from the serial data signal received through an eighth external pad to the third cell die 933 through the sixth bonding wires 952-3.

In the first data input/output mode, the serial data signals received through the sixteen external data pads of the logic die (not illustrated) may be converted into 512 parallel data signals by the logic die 920. The 512 parallel data signals may be divided and transmitted to one of the first and second cell dies 931 and 932 and one of the third and fourth cell dies 933 and 934. The logic die 920 may access one of the first and second cell dies 931 and 932 and one of the third and fourth cell dies 933 and 934 at the same time. For example, the logic die 920 may simultaneously access the first and third cell dies 931 and 933. The logic die 920 may transmit 32 parallel data signals generated from the serial data signal received through a first external pad, 32 parallel data signals generated from the serial data signal received through a fifth external pad, 32 parallel data signals generated from the serial data signal received through a ninth external pad, and 32 parallel data signals generated from the serial data signal received through a thirteenth external pad to the first cell die 931 through the first bonding wires 951-1. The logic die 920 may transmit 32 parallel data signals generated from the serial data signal received through a second external pad, 32 parallel data signals generated from the serial data signal received through a sixth external pad, 32 parallel data signals generated from the serial data signal received through a tenth external pad, and 32 parallel data signals generated from the serial data signal received through a fourteenth external pad to the first cell die 931 through the second bonding wires 952-1. The logic die 920 may transmit 32 parallel data signals generated from the serial data signal received through a third external pad, 32 parallel data signals generated from the serial data signal received through a seventh external pad, 32 parallel data signals generated from the serial data signal received through an eleventh external pad, and 32 parallel data signals generated from the serial data signal received through a fifteenth external pad to the third cell die 933 through the fifth bonding wires 951-3. The logic die 920 may transmit 32 parallel data signals generated from the serial data signal received through a fourth external pad, 32 parallel data signals generated from the serial data signal received through an eighth external pad, 32 parallel data signals generated from the serial data signal received through a twelfth external pad, and 32 parallel data signals generated from the serial data signal received through a sixteenth external pad to the third cell die 933 through the sixth bonding wires 952-3. A data transmission operation from the semiconductor apparatus 900 to the external apparatus may also be performed in a similar manner.

In the semiconductor apparatus 900, paths through which the parallel data signals are transmitted from the logic die 920 to the first to fourth cell dies 931, 932, 933, and 934 may be divided. Accordingly, the logic die 920 may access two cell dies simultaneously and perform data input/output operations with the two simultaneously accessed cell dies in all of the first to third data input/output modes. Because the semiconductor apparatus 900 has a structure in which two cell dies operate simultaneously regardless of the data input/output mode, it is possible to implement higher bandwidth without increasing the number of bonding wires, to distribute the power used in each of the cell dies, thereby improving power distribution characteristics, and to simplify control methods for data transmission in each of the data input/output modes.

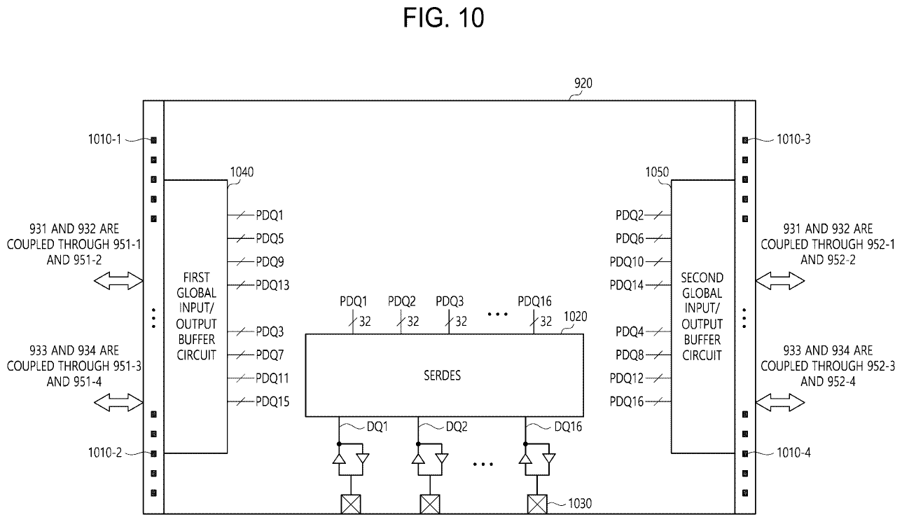

FIG. 10 is a diagram illustrating a configuration of the logic die 920 shown in FIG. 9. Referring to FIGS. 9 and 10, the logic die 920 may include a serializer/deserializer 1020, a first global input/output buffer circuit 1040, and a second global input/output buffer circuit 1050. The serializer/deserializer 1020 may be coupled between N data transmission lines and N*k data input/output lines. The first to N data transmission lines may be signal transmission lines through which the logic die 920 is coupled to an external apparatus. The N*k data input/output lines may be signal transmission lines through which the logic die 920 is coupled to a plurality of cell dies. For example, when N is 16 and k is 32, the serializer/deserializer 1020 may be coupled between 16 data transmission lines DQ1 to DQ16 and 512 data input/output lines. The 16 data transmission lines DQ1 to DQ16 may be coupled to external data pads 1030 of the logic die 920. The external data pads 1030 may be coupled to the external apparatus through the bumps 921 and the fifth signal transmission lines 915. For signal transmission between the serializer/deserializer 1020 and the external data pads 1030, each of the external data pads may be provided with a receiver and a transmitter. The serializer/deserializer 1020 may serialize data signals on the 512 data input/output lines into data signals on the 16 data transmission lines DQ1 to DQ16. The serializer/deserializer 1020 may deserialize data signals on the 16 data transmission lines DQ1 to DQ16 into data signals on the 512 data input/output lines. In FIG. 10, the serializer/deserializer 1020 is shown as being coupled to 16 data input/output line groups PDQ1 to PDQ16, each of which may include 32 data input/output lines.

The first global input/output buffer circuit 1040 may be coupled to half of the 512 data input/output lines, which are organized into numbered PDQ groups (e.g., PDQ1 to PDQ16). For example, the first global input/output buffer circuit 1040 may be coupled to PDQ data input/output line groups that are enumerated as 4 m+1 and 4 m+3 data input/output line groups, where m may be 0, 1, 2, or 3. Thus, the first global input/output buffer circuit 1040 may be coupled to the first, third, fifth, seventh, ninth, eleventh, thirteenth, and fifteenth data input/output line groups PDQ1, PDQ3, PDQ5, PDQ7, PDQ9, PDQ11, PDQ13, and PDQ15, which include first to 256th data input/output lines. The first global input/output buffer circuit 1040 may be coupled to the first, third, fifth, and seventh bonding wires 951-1, 951-2, 951-3, and 951-4. The logic die 920 includes first internal data pads 1010-1, and the first global input/output buffer circuit 1040 may be coupled to the first and third bonding wires 951-1 and 951-2 through the first internal data pads 1010-1, the bumps 921, and the first signal transmission lines 913-1. The logic die 920 includes second internal data pads 1010-2, and the first global input/output buffer circuit 1040 may be coupled to the fifth and seventh bonding wires 951-3 and 951-4 through the second internal data pads 1010-2, the bumps 921, and the third signal transmission lines 913-2. The first global input/output buffer circuit 1040 may be coupled to the first data pads 931-1 provided on the first side of the first cell die 931 through the first bonding wires 951-1, and may be coupled to the first data pads 932-1 provided on the first side of the second cell die 932 through the third bonding wires 951-2. The first global input/output buffer circuit 1040 may be coupled to the first data pads 933-1 provided on the first side of the third cell die 933 through the fifth bonding wires 951-3, and may be coupled to the first data pads 934-1 provided on the first side of the fourth cell die 934 through the seventh bonding wires 951-4. The first global input/output buffer circuit 1040 may respectively couple the 4 m+1 data input/output line groups to the first data pads 931-1 and 932-1 provided on the first sides of the first and second cell dies 931 and 932 through the first and third bonding wires 951-1 and 951-2. Therefore, the first global input/output buffer circuit 1040 may respectively couple the first, fifth, ninth, and thirteenth data input/output line groups PDQ1, PDQ5, PDQ9, and PDQ13 to the first and third bonding wires 951-1 and 951-2. The first global input/output buffer circuit 1040 may buffer data signals on the first, fifth, ninth, and thirteenth data input/output line groups PDQ1, PDQ5, PDQ9, and PDQ13, and may transmit the buffered data signals to the first and second cell dies 931 and 932 through the first and third bonding wires 951-1 and 951-2. The first global input/output buffer circuit 1040 may buffer data signals transmitted from the first and second cell dies 931 and 932 through the first and third bonding wires 951-1 and 951-2, and may output the buffered data signals to the first, fifth, ninth, and thirteenth data input/output line groups PDQ1, PDQ5, PDQ9, and PDQ13. The first global input/output buffer circuit 1040 may respectively couple the 4 m+3 data input/output line groups to the first data pads 933-1 and 934-1 provided on the first sides of the third and fourth cell dies 933 and 934 through the fifth and seventh bonding wires 951-3 and 951-4. The first global input/output buffer circuit 1040 may respectively couple the third, seventh, eleventh, and fifteenth data input/output line groups PDQ3, PDQ7, PDQ11, and PDQ15 to the fifth and seventh bonding wires 951-3 and 951-4. The first global input/output buffer circuit 1040 may buffer data signals on the third, seventh, eleventh, and fifteenth data input/output line groups PDQ3, PDQ7, PDQ11, and PDQ15, and may transmit the buffered data signals to the third and fourth cell dies 933 and 934 through the fifth and seventh bonding wires 951-3 and 951-4. The first global input/output buffer circuit 1040 may buffer data signals transmitted from the third and fourth cell dies 933 and 934 through the fifth and seventh bonding wires 951-3 and 951-4, and may output the buffered data signals to the third, seventh, eleventh, and fifteenth data input/output line groups PDQ3, PDQ7, PDQ11, and PDQ15. The first global input/output buffer circuit 1040 may be disposed on a first side of the logic die 920, and may be adjacent to the first side of the first to fourth cell dies 931, 932, 933, and 934 and the first side of the package substrate 910.

The second global input/output buffer circuit 1050 may be coupled to the remaining half of the 512 data input/output lines, which are also organized into numbered PDQ groups (e.g., PDQ1 to PDQ16). For example, the second global input/output buffer circuit 1050 may be coupled to PDQ data input/output line groups that are enumerated as 4 m+2 and 4 m+4 data input/output line groups. Thus, the second global input/output buffer circuit 1050 may be coupled to the second, fourth, sixth, eighth, tenth, twelfth, fourteenth, and sixteenth data input/output line groups PDQ2, PDQ4, PDQ6, PDQ8, PDQ10, PDQ12, PDQ14, and PDQ16, and may be coupled to the 257th to 512th data input/output lines. The second global input/output buffer circuit 1050 may be coupled to the second, fourth, sixth, and eighth bonding wires 952-1, 952-2, 952-3, and 952-4. The logic die 920 may include third internal data pads 1010-3, and the second global input/output buffer circuit 1050 may be coupled to the second and fourth bonding wires 952-1 and 952-2 through the third internal data pads 1010-3, the bumps 921, and the second signal transmission lines 914-1. The logic die 920 may include fourth internal data pads 1010-4, and the second global input/output buffer circuit 1050 may be coupled to the sixth and eighth bonding wires 952-3 and 952-4 through the fourth internal data pads 1010-4, the bumps 921, and the fourth signal transmission lines 914-2. The second global input/output buffer circuit 1050 may be coupled to the second data pads 931-2 provided on the second side of the first cell die 931 through the second bonding wires 952-1, and may be coupled to the second data pads 932-2 provided on the second side of the second cell die 932 through the fourth bonding wires 952-2. The second global input/output buffer circuit 1050 may be coupled to the second data pads 933-2 provided on the second side of the third cell die 933 through the sixth bonding wires 952-3, and may be coupled to the second data pads 934-2 provided on the second side of the fourth cell die 934 through the eighth bonding wires 952-4. The second global input/output buffer circuit 1050 may respectively couple the 4 m+2 data input/output line groups to the second data pads 931-2 and 932-2 provided on the second side of the first and second cell dies 931 and 932 through the second and fourth bonding wires 952-1 and 952-2. The second global input/output buffer circuit 1050 may be respectively coupled to the second, sixth, tenth, and fourteenth data input/output line groups PDQ2, PDQ6, PDQ10, and PDQ14 through the second and fourth bonding wires 952-1 and 952-2. The second global input/output buffer circuit 1050 may buffer data signals on the second, sixth, tenth, and fourteenth data input/output line groups PDQ2, PDQ6, PDQ10, and PDQ14 and may transmit the buffered data signals to the first and second cell dies 931 and 932 through the second and fourth bonding wires 952-1 and 952-2. The second global input/output buffer circuit 1050 may buffer data signals transmitted from the first and second cell dies 931 and 932 through the second and fourth bonding wires 952-1 and 952-2 and may output the buffered data signals to the second, sixth, tenth, and fourteenth data input/output line groups PDQ2, PDQ6, PDQ10, and PDQ14. The second global input/output buffer circuit 1050 may respectively couple the 4 m+4 data input/output line groups to the second data pads 933-2 and 934-2 provided on the second sides of the third and fourth cell dies 933 and 934 through the sixth and eighth bonding wires 952-3 and 952-4. The second global input/output buffer circuit 1050 may respectively couple the fourth, eighth, twelfth, and sixteenth data input/output line groups PDQ4, PDQ8, PDQ12, and PDQ16 to the sixth and eighth bonding wires 952-3 and 952-4. The second global input/output buffer circuit 1050 may buffer data signals on the fourth, eighth, twelfth, and sixteenth data input/output line groups PDQ4, PDQ8, PDQ12, and PDQ16 and may transmit the buffered data signals to the third and fourth cell dies 933 and 934 through the sixth and eighth bonding wires 952-3 and 952-4. The second global input/output buffer circuit 1050 may buffer data signals transmitted from the third and fourth cell dies 933 and 934 through the sixth and eighth bonding wires 952-3 and 952-4 and may output the buffered data signals to the fourth, eighth, twelfth, and sixteenth data input/output line groups PDQ4, PDQ8, PDQ12, and PDQ16. The second global input/output buffer circuit 1050 may be disposed on a second side of the logic die 920 and may be adjacent to the second side of the first to fourth cell dies 931, 932, 933, and 934 and the second side of the package substrate 910. Although not shown, the logic die 920 may further include an error correction circuit that performs an error correction operation on data signals on the first to sixteenth data input/output line groups PDQ1 to PDQ16.

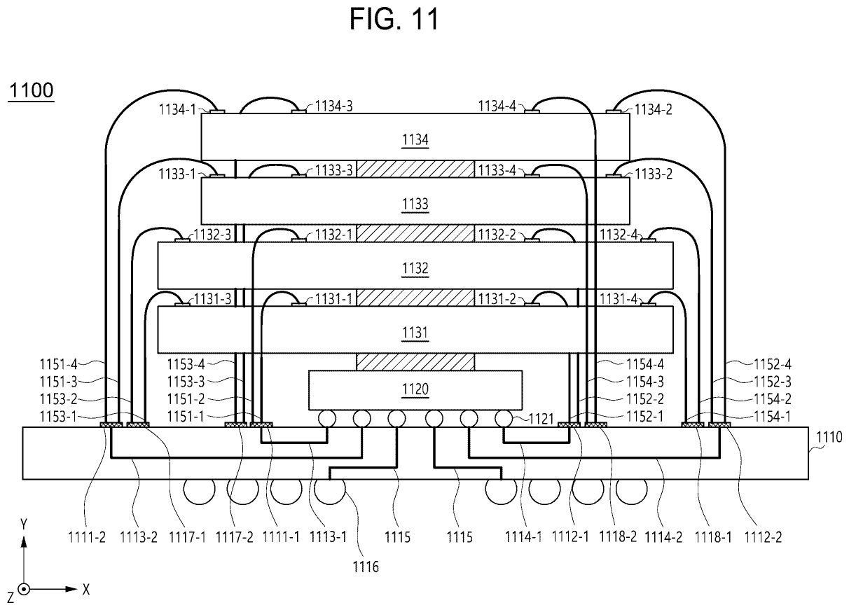

FIG. 11 is a diagram illustrating a configuration and connection relationship of a semiconductor apparatus 1100 according to an embodiment of the present disclosure. Referring to FIG. 11, the semiconductor apparatus 1100 may include a package substrate 1110, a logic die 1120, and a plurality of cell dies 1131, 1132, 1133, and 1134. The logic die 1120 and the plurality of cell dies 1131, 1132, 1133, and 1134 may be disposed on the package substrate 1110 and may be packaged into a single package. Although not intended to be limiting, for example, the plurality of cell dies may include a first cell die 1131, a second cell die 1132, a third cell die 1133, and a fourth cell die 1134. The number of cell dies included in the semiconductor apparatus 1100 may be a multiple of two. The logic die 1120 may be disposed on the package substrate 1110 in a y-axis direction. The logic die 1120 may be disposed at a center portion of the package substrate 1110 in x-axis and z-axis directions. The logic die 1120 may include bumps 1121 and may be coupled to the package substrate 1110 through the bumps 1121. The first cell die 1131 may be disposed on the logic die 1120 in a y-axis direction. The first cell die 1131 may be disposed to cover a part or all of the logic die 1120. The first cell die 1131 may be bonded to the logic die 1120 using an adhesive or a die attach film. Among four sides of the first cell die 1131, two longer sides may be aligned with and extend in an x-axis direction. Two shorter sides of the first cell die 1131 may be aligned with and extend in a z-axis direction. The second cell die 1132 may be disposed on the first cell die 1131 in a y-axis direction. The second cell die 1132 may be aligned with the first cell die 1131 in the x-axis and z-axis directions. The third cell die 1133 may be disposed on the second cell die 1132 in a y-axis direction. The third cell die 1133 may be rotated by 90 degrees with respect to the first and second cell dies 1131 and 1132 and may be disposed on the second cell die 1132. Among four sides of the third cell die 1133, two shorter sides may be aligned with and extend in an x-axis direction. Two longer sides of the third cell die 1133 may be aligned with and extend in a z-axis direction. The fourth cell die 1134 may be disposed on the third cell die 1133 in a y-axis direction. The fourth cell die 1134 may be rotated by 90 degrees with respect to the first and second cell dies 1131 and 1132 and may be disposed on the third cell die 1133. The fourth cell die 1134 may be aligned with the third cell die 1133 in the x-axis and z-axis directions. Among four sides of the fourth cell die 1134, two shorter sides may be aligned with and extend in an x-axis direction. Two longer sides of the fourth cell die 1134 may be aligned with and extend in a z-axis direction. The second to fourth cell dies 1132, 1133, and 1134 may be bonded to the first to third cell dies 1131, 1132, and 1133, respectively, using a die attach film. The first to fourth cell dies 1131, 1132, 1133, and 1134 may respectively include first data pads 1131-1, 1132-1, 1133-1, and 1134-1 on a first side. The first to fourth cell dies 1131, 1132, 1133, and 1134 may respectively include second data pads 1131-2, 1132-2, 1133-2, and 1134-2 on a second side facing the first side. The first side may be a region adjacent to one of the longer two sides of the first to fourth cell dies 1131, 1132, 1133, and 1134. The second side may be a region adjacent to the other one of the longer two sides. Accordingly, the first and second sides of the first and second cell dies 1131 and 1132 may extend in an x-axis direction, and the first and second sides of the third and fourth cell dies 1133 and 1134 may extend in a z-axis direction. A region adjacent to one of the shorter two sides of the first to fourth cell dies 1131, 1132, 1133, and 1134 may be defined as a third side, and a region adjacent to the other one of the shorter two sides may be defined as a fourth side of the first to fourth cell dies 1131, 1132, 1133, and 1134. Accordingly, the third and fourth sides of the first and second cell dies 1131 and 1132 may extend in a z-axis direction, and the third and fourth sides of the third and fourth cell dies 1133 and 1134 may extend in an x-axis direction. The first and second sides of the first and second cell dies 1131 and 1132 may be aligned with the first and second sides of the logic die 1120. The first and second sides of the third and fourth cell dies 1133 and 1134 may be aligned with the third and fourth sides of the logic die 1120.

The package substrate 1110 may include first pads 1111-1, second pads 1112-1, third pads 1111-2, fourth pads 1112-2, first signal transmission lines 1113-1, second signal transmission lines 1114-1, third signal transmission lines 1113-2, fourth signal transmission lines 1114-2, and fifth signal transmission lines 1115. The first to fourth pads 1111-1, 1112-1, 1111-2, and 1112-2 may be provided on package substrate 1110, and the first to fifth signal transmission lines 1113-1, 1114-1, 1113-2, 1114-2, and 1115 may be provided in the package substrate 1110. For example, the first pads 1111-1 may be provided on a first side (i.e., a front portion of the package substrate 1110 in a z-axis direction in FIG. 11) of the package substrate 1110, and the third pads 1111-2 may be provided on a third side (i.e., a left portion of package substrate 1110 in an x-axis direction in FIG. 11) of the package substrate 1110. The second pads 1112-1 may be provided on a second side (i.e., a rear portion of the package substrate 1110 in a z-axis direction) of the package substrate 1110. The fourth pads 1112-2 may be provided on a fourth side (i.e., a right portion of the package substrate 1110 in an x-axis direction) of the package substrate 1110. The first pads 1111-1 may be provided at a distance spaced apart in a z-axis direction from a first side of the logic die 1120. The third pads 1111-2 may be provided at a distance spaced apart in an x-axis direction from a third side of the first cell die 1131. The second pads 1112-1 may be provided at a distance spaced apart in a z-axis direction from a second side of the logic die 1120. The fourth pads 1112-2 may be provided at a distance spaced apart in an x-axis direction from a fourth side of the first cell die 1131. The first cell die 1131 may be coupled to the first pads 1111-1 through first bonding wires 1151-1, and may be coupled to the second pads 1112-1 through second bonding wires 1152-1. The first data pads 1131-1 provided on the first side of the first cell die 1131 may be coupled to the first pads 1111-1 through the first bonding wires 1151-1. The second data pads 1131-2 provided on the second side of the first cell die 1131 may be coupled to the second pads 1112-1 through the second bonding wires 1152-1. The second cell die 1132 may be coupled to the first pads 1111-1 through third bonding wires 1151-2, and may be coupled to the second pads 1112-1 through fourth bonding wires 1152-2. The first data pads 1132-1 provided on the first side of the second cell die 1132 may be coupled to the first pads 1111-1 through the third bonding wires 1151-2. The second data pads 1132-2 provided on the second side of the second cell die 1132 may be coupled to the second pads 1112-1 through the fourth bonding wires 1152-2. The third cell die 1133 may be coupled to the third pads 1111-2 through fifth bonding wires 1151-3, and may be coupled to the fourth pads 1112-2 through sixth bonding wires 1152-3. The first data pads 1133-1 provided on the first side of the third cell die 1133 may be coupled to the third pads 1111-2 through the fifth bonding wires 1151-3. The second data pads 1133-2 provided on the second side of the third cell die 1133 may be coupled to the fourth pads 1112-2 through the sixth bonding wires 1152-3. The fourth cell die 1134 may be coupled to the third pads 1111-2 through seventh bonding wires 1151-4, and may be coupled to the fourth pads 1112-2 through eighth bonding wires 1152-4. The first data pads 1134-1 provided on the first side of the fourth cell die 1134 may be coupled to the third pads 1111-2 through the seventh bonding wires 1151-4. The second data pads 1134-2 provided on the second side of the fourth cell die 1134 may be coupled to the fourth pads 1112-2 through the eighth bonding wires 1152-4. The logic die 1120 may be coupled to the first pads 1111-1 through the first signal transmission lines 1113-1, and may be coupled to the second pads 1112-1 through the second signal transmission lines 1114-1. The logic die 1120 may be coupled to the third pads 1111-2 through the third signal transmission lines 1113-2, and may be coupled to the fourth pads 1112-2 through the fourth signal transmission lines 1114-2. The logic die 1120 may be respectively coupled to the first data pads 1131-1 and 1132-1 provided on the first sides (i.e., front side in FIG. 11) of the first and second cell dies 1131 and 1132 through the first signal transmission lines 1113-1, the first pads 1111-1, and the first and third bonding wires 1151-1 and 1151-2. The logic die 1120 may be respectively coupled to the second data pads 1131-2 and 1132-2 provided on the second sides (i.e., opposite the front side in FIG. 11) of the first and second cell dies 1131 and 1132 through the second signal transmission lines 1114-1, the second pads 1112-1, and the second and fourth bonding wires 1152-1 and 1152-2. The logic die 1120 may be respectively coupled to the first data pads 1133-1 and 1134-1 provided on the first sides of the third and fourth cell dies 1133 and 1134 through the third signal transmission lines 1113-2, the third pads 1111-2, and the fifth and seventh bonding wires 1151-3 and 1151-4. The logic die 1120 may be respectively coupled to the second data pads 1133-2 and 1134-2 provided on the second sides of the third and fourth cell dies 1133 and 1134 through the fourth signal transmission lines 1114-2, the fourth pads 1112-2, and the sixth and eighth bonding wires 1152-3 and 1152-4. The logic die 1120 may be coupled to an external apparatus of the semiconductor apparatus 1100 through the fifth signal transmission lines 1115. The package substrate 1110 may include package balls 1116, and the fifth signal transmission lines 1115 may be coupled to the external apparatus through the package balls 1116. The logic die 1120 may deserialize signals on the fifth signal transmission lines 1115 into signals on the first to fourth signal transmission lines 1113-1, 1114-1, 1113-2, and 1114-2, and may serialize signals on the first to fourth signal transmission lines 1113-1, 1114-1, 1113-2, and 1114-2 into data signals on the fifth signal transmission lines 1115. The logic die 1120 may perform an error correction operation on signals on the first to fourth signal transmission lines 1113-1, 1114-1, 1113-2, and 1114-2.

The package substrate 1110 may further include a fifth pad 1117-1, a sixth pad 1118-1, a seventh pad 1117-2, and an eighth pad 1118-2. The fifth pad 1117-1 may be provided at a distance from the third side of the first cell die 1131 in an x-axis direction, and in the same direction may be provided at a position closer to the first cell die 1131 than the third pads 1111-2. The sixth pad 1118-1 may be provided at a distance from the fourth side of the first cell die 1131 in an x-axis direction, and in the same direction may be provided at a position closer to the first cell die 1131 than the fourth pads 1112-2. The seventh pad 1117-2 may be provided at a distance from the second side of the logic die 1120 in a z-axis direction and may be provided at a position between the first pads 1111-1 and the fifth pad 1117-1 in an x-axis direction. The eighth pad 1118-2 may be provided at a distance from the first side of the logic die 1120 in a z-axis direction and may be provided at a position between the second pads 1112-1 and the sixth pad 1118-1 in an x-axis direction. The first cell die 1131 may include power pads 1131-3 and 1131-4 on the third and fourth sides, respectively. The second cell die 1132 may include power pads 1132-3 and 1132-4 on the third and fourth sides, respectively. The third cell die 1133 may include power pads 1133-3 and 1133-4 on the third and fourth sides, respectively. The fourth cell die 1134 may include power pads 1134-3 and 1134-4 on the third and fourth sides, respectively. The first cell die 1131 may be coupled to the fifth pad 1117-1 through a ninth bonding wire 1153-1 and may be coupled to the sixth pad 1118-1 through a tenth bonding wire 1154-1. The second cell die 1132 may be coupled to the fifth pad 1117-1 through an eleventh bonding wire 1153-2 and may be coupled to the sixth pad 1118-1 through a twelfth bonding wire 1154-2. The third cell die 1133 may be coupled to the seventh pad 1117-2 through a thirteenth bonding wire 1153-3 and may be coupled to the eighth pad 1118-2 through a fourteenth bonding wire 1154-3. The fourth cell die 1134 may be coupled to the seventh pad 1117-2 through a fifteenth bonding wire 1153-4 and may be coupled to the eighth pad 1118-2 through a sixteenth bonding wire 1154-4. A power voltage may be supplied to the fifth to eighth pads 1117-1, 1118-1, 1117-2, and 1118-2. The power voltage may be supplied to the power pad 1131-3 disposed on the third side of the first cell die 1131 through the fifth pad 1117-1 and the ninth bonding wire 1153-1. The power voltage may be supplied to the power pad 1131-4 disposed on the fourth side of the first cell die 1131 through the sixth pad 1118-1 and the tenth bonding wire 1154-1. The power voltage may be supplied to the power pad 1132-3 disposed on the third side of the second cell die 1132 through the fifth pad 1117-1 and the eleventh bonding wire 1153-2. The power voltage may be supplied to the power pad 1132-4 disposed on the fourth side of the second cell die 1132 through the sixth pad 1118-1 and the twelfth bonding wire 1154-2. The power voltage may be supplied to the power pad 1133-3 disposed on the third side of the third cell die 1133 (e.g., a rear side in FIG. 11) through the seventh pad 1117-2 and the thirteenth bonding wire 1153-3. The power voltage may be supplied to the power pad 1133-4 disposed on the fourth side of the third cell die 1133 (e.g., a front side in FIG. 11) through the eighth pad 1118-2 and the fourteenth bonding wire 1154-4. The power voltage may be supplied to the power pad 1134-3 disposed on the third side of the fourth cell die 1134 through the seventh pad 1117-2 and the fifteenth bonding wire 1153-4. The power voltage may be supplied to the power pad 1134-4 disposed on the fourth side of the fourth cell die 1134 through the eighth pad 1118-2 and the sixteenth bonding wire 1154-4.

The first data pads 1131-1 and 1132-1 provided on the first sides of the first and second cell dies 1131 and 1132, respectively, may be coupled to the first pads 1111-1 of the package substrate 1110 through the first and third bonding wires 1151-1 and 1151-2, respectively, and the first pads 1111-1 may be coupled to the logic die 1120 through the first signal transmission lines 1113-1. The number of the first bonding wires 1151-1 and the number of the third bonding wires 1151-2 may each be N*k/2, and the number of the first signal transmission lines 1113-1 may also be N*k/2. The second data pads 1131-2 and 1132-2 provided on the second sides of the first and second cell dies 1131 and 1132, respectively, may be coupled to the second pads 1112-1 of the package substrate 1110 through the second and fourth bonding wires 1152-1 and 1152-2, respectively, and the second pads 1112-1 may be coupled to the logic die 1120 through the second signal transmission lines 1114-1. The number of the second bonding wires 1152-1 and the number of the fourth bonding wires 1152-2 may each be N*k/2, and the number of the second signal transmission lines 1114-2 may also be N*k/2. The first data pads 1133-1 and 1134-1 provided on the first sides of the third and fourth cell dies 1133 and 1134, respectively, may be coupled to the third pads 1111-2 of the package substrate 1110 through the fifth and seventh bonding wires 1151-3 and 1151-4, respectively, and the third pads 1111-2 may be coupled to the logic die 1120 through the third signal transmission lines 1113-2. The number of the fifth bonding wires 1151-3 and the number of the seventh bonding wires 1151-4 may each be N*k/2, and the number of the third signal transmission lines 1113-2 may also be N*k/2. The second data pads 1133-2 and 1134-2 provided on the second sides of the third and fourth cell dies 1133 and 1134, respectively, may be coupled to the fourth pads 1112-2 of the package substrate 1110 through the sixth and eighth bonding wires 1152-3 and 1152-4, respectively, and the fourth pads 1112-2 may be coupled to the logic die 1120 through the fourth signal transmission lines 1114-2. The number of the sixth bonding wires 1152-3 and the number of the eighth bonding wires 1152-4 may each be N*k/2, and the number of the fourth signal transmission lines 1114-2 may also be N*k/2. The number of the fifth signal transmission lines 1115 may be N, 2N, or 4N. When the semiconductor apparatus 1100 supports all of the first to third data input/output modes, for example, the number of the fifth signal transmission lines 1115 may be sixteen. The semiconductor apparatus 1100 may perform substantially the same operation as the semiconductor apparatus 900 shown in FIG. 9.

In the semiconductor apparatus 1100, the third and fourth cell dies 1133 and 1134 are substantially similar to the first and second cell dies 1131 and 1132, but rotated by 90 degrees with respect to the first and second cell dies 1131 and 1132. Therefore, the first and third bonding wires 1151-1 and 1151-2 connecting the first data pads 1131-1 and 1132-2 of the first and second cell dies 1131 and 1132 to the first pads 1111-1 may be located towards a first side of the first cell die 1131 in a z-axis direction with reference to the first cell die 1131. The second and fourth bonding wires 1152-1 and 1152-2 connecting the second data pads 1131-2 and 1132-2 of the first and second cell dies 1131 and 1132 to the second pads 1112-1 may be located towards a second side of the first cell die 1131 in a z-axis direction with reference to the first cell die 1131. The fifth and seventh bonding wires 1151-3 and 1151-4 connecting the first data pads 1133-1 and 1134-1 of the third and fourth cell dies 1133 and 1134 to the third pads 1111-2 may be located towards a third side of the first cell die 1131 in an x-axis direction with reference to the first cell die 1131. The sixth and eighth bonding wires 1152-3 and 1152-4 connecting the second data pads 1133-2 and 1134-2 of the third and fourth cell dies 1133 and 1134 to the fourth pads 1112-2 may be located towards a fourth side of the first cell die 1131 in an x-axis direction with reference to the first cell die 1131. In addition, the logic die 1120 may access the first and third cell dies 1131 and 1133 simultaneously to perform a data input/output operation, or may access the second and fourth cell dies 1132 and 1134 simultaneously to perform a data input/output operation. Because the bonding wires coupled to the data pads of the simultaneously accessed cell dies may be located in different directions, it is possible to prevent and reduce coupling between data signals transmitted through the bonding wires.

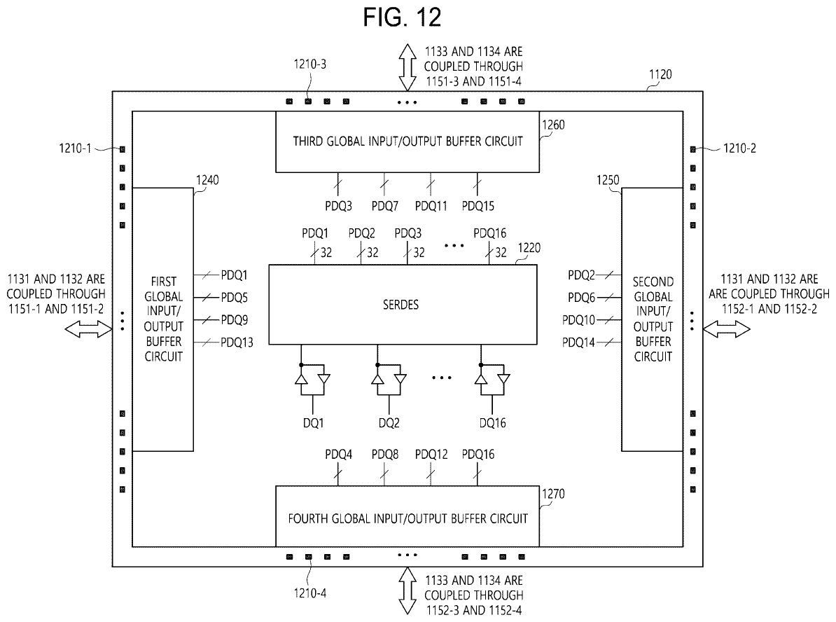

FIG. 12 is a diagram illustrating a configuration of the logic die 1120 shown in FIG. 11. Referring to FIGS. 11 and 12, the logic die 1120 may include a serializer/deserializer 1220, a first global input/output buffer circuit 1240, a second global input/output buffer circuit 1250, a third global input/output buffer circuit 1260, and a fourth global input/output buffer circuit 1270. The serializer/deserializer 1220 may be coupled between N data transmission lines and N*k data input/output lines. The N data transmission lines may be signal transmission lines through which the logic die 1120 is coupled to an external apparatus. The N*k data input/output lines may be signal transmission lines through which the logic die 1120 is coupled to a plurality of cell dies. For example, when N is 16 and k is 32, the serializer/deserializer 1220 may be coupled between 16 data transmission lines DQ1 to DQ16 and 512 data input/output lines. The 16 data transmission lines DQ1 to DQ16 may be coupled to external data pads (not illustrated) of the logic die 1120. A receiver and a transmitter (not illustrated) may be provided for each of the 16 data transmission lines DQ1 to DQ16 to transmit signals between the serializer/deserializer 1220 and the external data pads. The serializer/deserializer 1220 may serialize data signals on the 512 data input/output lines into data signals on the 16 data transmission lines DQ1 to DQ16. The serializer/deserializer 1220 may deserialize data signals on the 16 data transmission lines DQ1 to DQ16 into data signals on the 512 data input/output lines. In FIG. 12, the serializer/deserializer 1220 is illustrated as being coupled to 16 data input/output line groups, which are organized into numbered PDQ groups (e.g., PDQ1 to PDQ16), and the 16 data input/output line groups PDQ1 to PDQ16 may each include 32 data input/output lines.

The first global input/output buffer circuit 1240 may be coupled to 128 data input/output lines among the 512 data input/output lines. For example, the first global input/output buffer circuit 1240 may be coupled to PDQ data input/output line groups that are enumerated as 4 m+1 data input/output line groups, where m may be 0, 1, 2, or 3. Thus, the first global input/output buffer circuit 1240 may be coupled to first, fifth, ninth, and thirteenth data input/output line groups PDQ1, PDQ5, PDQ9, and PDQ13, which include first to 128th data input/output lines. The first global input/output buffer circuit 1240 may be coupled to the first and third bonding wires 1151-1 and 1151-2. The logic die 1120 may include first internal data pads 1210-1, and the first global input/output buffer circuit 1240 may be coupled to the first and third bonding wires 1151-1 and 1151-2 through the first internal data pads 1210-1, the bumps 1121, and the first signal transmission lines 1113-1. The first global input/output buffer circuit 1240 may be coupled to the first data pads 1131-1 disposed on the first side of the first cell die 1131 through the first bonding wires 1151-1, and may be coupled to the first data pads 1132-1 disposed on the first side of the second cell die 1132 through the third bonding wires 1151-2. The first global input/output buffer circuit 1240 may couple 4 m+1 data input/output line groups to the first data pads 1131-1 and 1132-1 of the first and second cell dies 1131 and 1132, respectively, through the first and third bonding wires 1151-1 and 1151-2. The first global input/output buffer circuit 1240 may respectively couple the first, fifth, ninth, and thirteenth data input/output line groups PDQ1, PDQ5, PDQ9, and PDQ13 to the first and third bonding wires 1151-1 and 1151-2. The first global input/output buffer circuit 1240 may buffer data signals on the first, fifth, ninth, and thirteenth data input/output line groups PDQ1, PDQ5, PDQ9, and PDQ13 and transmit the buffered data signals to the first and second cell dies 1131 and 1132 through the first and third bonding wires 1151-1 and 1151-2. The first global input/output buffer circuit 1240 may buffer data signals transmitted from the first and second cell dies 1131 and 1132 through the first and third bonding wires 1151-1 and 1151-2 and output the buffered data signals to the first, fifth, ninth, and thirteenth data input/output line groups PDQ1, PDQ5, PDQ9, and PDQ13. The first global input/output buffer circuit 1240 may be disposed on a first side of the logic die 1120, which parallels the first side of the first and second cell dies 1131 and 1132 and the first side of the package substrate 1110.

The second global input/output buffer circuit 1250 may be coupled to another 128 data input/output lines, which are also organized into numbered PDQ groups (e.g., PDQ1 to PDQ16), from among the 512 data input/output lines. For example, the second global input/output buffer circuit 1250 may be coupled to PDQ data input/output line groups that are enumerated as 4 m+2 data input/output line groups. Thus, the second global input/output buffer circuit may be coupled to second, sixth, tenth, and fourteenth data input/output line groups PDQ2, PDQ6, PDQ10, and PDQ14, and may be coupled to 129th to 256th data input/output lines. The second global input/output buffer circuit 1250 may be coupled to the second and fourth bonding wires 1152-1 and 1152-2. The logic die 1120 may include second internal data pads 1210-2, and the second global input/output buffer circuit 1250 may be coupled to the second and fourth bonding wires 1152-1 and 1152-2 through the second internal data pads 1210-2, the bumps 1121, and the second signal transmission lines 1114-1. The second global input/output buffer circuit 1250 may be coupled to the second data pads 1131-2 disposed on the second side of the first cell die 1131 through the second bonding wires 1152-1, and may be coupled to the second data pads 1132-2 disposed on the second side of the second cell die 1132 through the fourth bonding wires 1152-2. The second global input/output buffer circuit 1250 may couple the 4 m+2 data input/output line groups to the second data pads 1131-2 and 1132-2 of the first and second cell dies 1131 and 1132, respectively, through the second and fourth bonding wires 1152-1 and 1152-2. The second global input/output buffer circuit 1250 may respectively couple the second, sixth, tenth, and fourteenth data input/output line groups PDQ2, PDQ6, PDQ10, and PDQ14 to the second and fourth bonding wires 1152-1 and 1152-2. The second global input/output buffer circuit 1250 may buffer data signals on the second, sixth, tenth, and fourteenth data input/output line groups PDQ2, PDQ6, PDQ10, and PDQ14 and transmit the buffered data signals to the first and second cell dies 1131 and 1132 through the second and fourth bonding wires 1152-1 and 1152-2. The second global input/output buffer circuit 1250 may buffer data signals transmitted from the first and second cell dies 1131 and 1132 through the second and fourth bonding wires 1152-1 and 1152-2 and output the buffered data signals to the second, sixth, tenth, and fourteenth data input/output line groups PDQ2, PDQ6, PDQ10, and PDQ14. The second global input/output buffer circuit 1250 may be disposed on a second side of the logic die 1120, which parallels the second side of the first and second cell dies 1131 and 1132 and the second side of the package substrate 1110.

The third global input/output buffer circuit 1260 may be coupled to yet another 128 data input/output lines among the 512 data input/output lines. For example, the third global input/output buffer circuit 1260 may be coupled to PDQ data input/output line groups that are enumerated as 4 m+3 data input/output line groups. Thus, the third global input/output buffer circuit 1260 may be coupled to third, seventh, eleventh, and fifteenth data input/output line groups PDQ3, PDQ7, PDQ11, and PDQ15, which include 257th to 384th data input/output lines. The third global input/output buffer circuit 1260 may be coupled to the fifth and seventh bonding wires 1151-3 and 1151-4. The logic die 1120 may include third internal data pads 1210-3, and the third global input/output buffer circuit 1260 may be coupled to the fifth and seventh bonding wires 1151-3 and 1151-4 through the third internal data pads 1210-3, the bumps 1121, and the third signal transmission lines 1113-2. The third global input/output buffer circuit 1260 may be coupled to the first data pads 1133-1 disposed on the first side of the third cell die 1133 through the fifth bonding wires 1151-3, and may be coupled to the first data pads 1134-1 disposed on the first side of the fourth cell die 1134 through the seventh bonding wires 1151-4. The third global input/output buffer circuit 1260 may couple the 4 m+3 data input/output line groups to the first data pads 1133-1 and 1134-1 of the third and fourth cell dies 1133 and 1134, respectively, through the fifth and seventh bonding wires 1151-3 and 1151-4. The third global input/output buffer circuit 1260 may respectively couple the third, seventh, eleventh, and fifteenth data input/output line groups PDQ3, PDQ7, PDQ11, and PDQ15 to the fifth and seventh bonding wires 1151-3 and 1151-4. The third global input/output buffer circuit 1260 may buffer data signals on the third, seventh, eleventh, and fifteenth data input/output line groups PDQ3, PDQ7, PDQ11, and PDQ15 and transmit the buffered data signals to the third and fourth cell dies 1133 and 1134 through the fifth and seventh bonding wires 1151-3 and 1151-4. The third global input/output buffer circuit 1260 may buffer data signals transmitted from the third and fourth cell dies 1133 and 1134 through the fifth and seventh bonding wires 1151-3 and 1151-4 and output the buffered data signals to the third, seventh, eleventh, and fifteenth data input/output line groups PDQ3, PDQ7, PDQ11, and PDQ15. The third global input/output buffer circuit 1260 may be disposed on a third side of the logic die 1120, which parallels the third side of the first and second cell dies 1131 and 1132 and the third side of the package substrate 1110.

The fourth global input/output buffer circuit 1270 may be coupled to still another 128 data input/output lines, which are also organized into numbered PDQ groups (e.g., PDQ1 to PDQ16), from among the 512 data input/output lines. For example, the fourth global input/output buffer circuit 1270 may be coupled to PDQ data input/output line groups that are enumerated as 4 m+4 data input/output line groups. Thus, the fourth global input/output buffer circuit 1270 may be coupled to fourth, eighth, twelfth, and sixteenth data input/output line groups PDQ4, PDQ8, PDQ12, and PDQ16 and may be coupled to 385th to 512th data input/output lines. The fourth global input/output buffer circuit 1270 may be coupled to the sixth and eighth bonding wires 1152-3 and 1152-4. The logic die 1120 may include fourth internal data pads 1210-4, and the fourth global input/output buffer circuit 1270 may be coupled to the sixth and eighth bonding wires 1152-3 and 1152-4 through the fourth internal data pads 1210-4, the bumps 1121, and the fourth signal transmission lines 1114-2. The fourth global input/output buffer circuit 1270 may be coupled to the second data pads 1133-2 disposed on the second side of the third cell die 1133 through the sixth bonding wires 1152-3 and may be coupled to the second data pads 1134-2 disposed on the second side of the fourth cell die 1134 through the eighth bonding wires 1152-4. The fourth global input/output buffer circuit 1270 may couple the 4 m+4 data input/output line groups to the second data pads 1133-2 and 1134-2 of the third and fourth cell dies 1133 and 1134, respectively, through the sixth and eighth bonding wires 1152-3 and 1152-4. The fourth global input/output buffer circuit 1270 may respectively couple the fourth, eighth, twelfth, and sixteenth data input/output line groups PDQ4, PDQ8, PDQ12, and PDQ16 to the sixth and eighth bonding wires 1152-3 and 1152-4. The fourth global input/output buffer circuit 1270 may buffer data signals on the fourth, eighth, twelfth, and sixteenth data input/output line groups PDQ4, PDQ8, PDQ12, and PDQ16 and transmit the buffered data signals to the third and fourth cell dies 1133 and 1134 through the sixth and eighth bonding wires 1152-3 and 1152-4. The fourth global input/output buffer circuit 1270 may buffer data signals transmitted from the third and fourth cell dies 1133 and 1134 through the sixth and eighth bonding wires 1152-3 and 1152-4 and output the buffered data signals to the fourth, eighth, twelfth, and sixteenth data input/output line groups PDQ4, PDQ8, PDQ12, and PDQ16. Although not illustrated, the logic die 1120 may further include an error correction circuit configured to perform an error correction operation on data signals on the first to sixteenth data input/output line groups PDQ1 to PDQ16. The fourth global input/output buffer circuit 1270 may be disposed on a fourth side of the logic die 1120, which parallels the fourth side of the first and second cell dies 1131 and 1132 and the fourth side of the package substrate 1110.

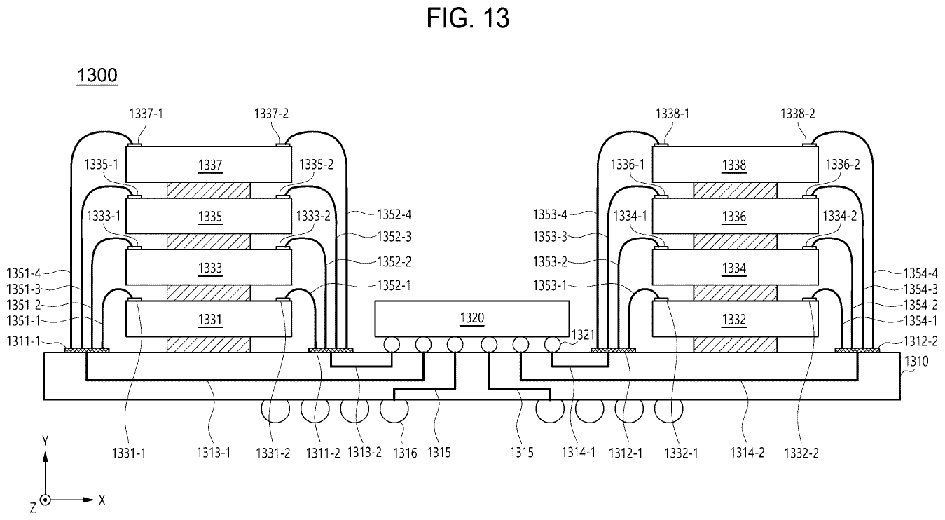

FIG. 13 is a diagram illustrating a configuration of a semiconductor apparatus 1300 according to an embodiment of the present disclosure. Referring to FIG. 13, the semiconductor apparatus 1300 may include a package substrate 1310, a logic die 1320, and a plurality of cell dies 1331, 1332, 1333, 1334, 1335, 1336, 1337, and 1338. The logic die 1320 and the plurality of cell dies 1331, 1332, 1333, 1334, 1335, 1336, 1337, and 1338 may be disposed on the package substrate 1310 and may be packaged as a single package. The logic die 1320 may be disposed on the package substrate 1310. For example, the logic die 1320 may be disposed at a central portion of the package substrate 1310 in the x-axis and z-axis directions so that the plurality of cell dies 1331, 1332, 1333, 1334, 1335, 1336, 1337, and 1338 are disposed on both sides of the logic die 1320 in an x-axis direction. The logic die 1320 may include a first side and a second side facing the first side in an x-axis direction. The plurality of cell dies may include first to eighth cell dies 1331, 1332, 1333, 1334, 1335, 1336, 1337, and 1338. Although eight cell dies are illustrated in FIG. 13, the number of cell dies included in a semiconductor apparatus may be a multiple of two. The first cell die 1331 may be disposed on the package substrate 1310 adjacent to the first side of the logic die 1320 in an x-axis direction. The second cell die 1332 may be disposed on the package substrate 1310 adjacent to the second side of the logic die 1320 in an x-axis direction. The first and second cell dies 1331 and 1332 may be attached to the package substrate 1310 in a y-axis direction using an adhesive or a die attach film (DAF). The third cell die 1333 may be disposed on the first cell die 1331 in a y-axis direction, and aligned with the first cell die 1331 in the x-axis and z-axis directions. The fourth cell die 1334 may be disposed on the second cell die 1332 in a y-axis direction, and aligned with the second cell die 1332 in the x-axis and z-axis directions. The third and fourth cell dies 1333 and 1334 may be attached to the first and second cell dies 1331 and 1332, respectively, using die attach film. The fifth cell die 1335 may be disposed on the third cell die 1333 in a y-axis direction, and aligned with the first and third cell dies 1331 and 1333 in the x-axis and z-axis directions. The sixth cell die 1336 may be disposed on the fourth cell die 1334 in a y-axis direction, and aligned with the second and fourth cell dies 1332 and 1334 in the x-axis and z-axis directions. The fifth and sixth cell dies 1335 and 1336 may be attached to the third and fourth cell dies 1333 and 1334, respectively, using die attach film. The seventh cell die 1337 may be disposed on the fifth cell die 1335 in a y-axis direction, and aligned with the first, third, and fifth cell dies 1331, 1333, and 1335 in the x-axis and z-axis directions. The eighth cell die 1338 may be disposed on the sixth cell die 1336 in a y-axis direction, and aligned with the second, fourth, and sixth cell dies 1332, 1334, and 1336 in the x-axis and z-axis directions. The seventh and eighth cell dies 1337 and 1338 may be attached to the fifth and sixth cell dies 1335 and 1336, respectively, using die attach film. The first, third, fifth, and seventh cell dies 1331, 1333, 1335, and 1337 may include first data pads 1331-1, 1333-1, 1335-1, and 1337-1 on a first side of the respective cell dies in the x-axis direction, and may include second data pads 1331-2, 1333-2, 1335-2, and 1337-2 on a second side facing the first side in the x-axis direction. In first, third, fifth, and seventh cell dies 1331, 1333, 1335, and 1337, the second side is closer to the logic die 1320 than the first side. The second, fourth, sixth, and eighth cell dies 1332, 1334, 1336, and 1338 may include first data pads 1332-1, 1334-1, 1336-1, and 1338-1 on a first side of the respective cell dies in the x-axis direction, and may include second data pads 1332-2, 1334-2, 1336-2, and 1338-2 on a second side facing the first side in the x-axis direction. In second, fourth, sixth, and eighth cell dies 1332, 1334, 1336, and 1338, the first side is closer to the logic die 1320 than the second side.

The package substrate 1310 may include first pads 1311-1, second pads 1311-2, third pads 1312-1, fourth pads 1312-2, first signal transmission lines 1313-1, second signal transmission lines 1313-2, third signal transmission lines 1314-1, fourth signal transmission lines 1314-2, and fifth signal transmission lines 1315. The first to fourth pads 1311-1, 1311-2, 1312-1, and 1312-2 may be provided on the package substrate 1310, and the first to fifth signal transmission lines 1313-1, 1313-2, 1314-1, 1314-2, and 1315 may be provided in the package substrate 1310. For example, the first pads 1311-1 may be provided at a distance in an x-axis direction away from the first side of the first cell die 1331 and away from the first side of the logic die 1320. The second pads 1311-2 may be provided at a distance in an x-axis direction, away from the second side of the first cell die 1331 and towards the first side of the logic die 1320. The third pads 1312-1 may be provided at a distance in an x-axis direction away from the first side of the second cell die 1332 and towards the second side of the logic die 1320. The fourth pads 1312-2 may be provided at a distance in an x-axis direction away from the second side of the second cell die 1332 and away from the second side of the logic die 1320. The first cell die 1331 may be coupled to the first pads 1311-1 through first bonding wires 1351-1, and may be coupled to the second pads 1311-2 through second bonding wires 1352-1. The first data pads 1331-1 provided on the first side of the first cell die 1331 may be coupled to the first pads 1311-1 through the first bonding wires 1351-1. The second data pads 1331-2 provided on the second side of the first cell die 1331 may be coupled to the second pads 1311-2 through the second bonding wires 1352-1. The second cell die 1332 may be coupled to the third pads 1312-1 through third bonding wires 1353-1 and may be coupled to the fourth pads 1312-2 through fourth bonding wires 1354-1. The first data pads 1332-1 provided on the first side of the second cell die 1332 may be coupled to the third pads 1312-1 through the third bonding wires 1353-1. The second data pads 1332-2 provided on the second side of the second cell die 1332 may be coupled to the fourth pads 1312-2 through the fourth bonding wires 1354-1. The third, fifth, and seventh cell dies 1333, 1335, and 1337 may be respectively coupled to the first pads 1311-1 through fifth, ninth, and thirteenth bonding wires 1351-2, 1351-3, and 1351-4. The third, fifth, and seventh cell dies 1333, 1335, and 1337 may be respectively coupled to the second pads 1311-2 through sixth, tenth, and fourteenth bonding wires 1352-2, 1352-3, and 1352-4. The first data pads 1333-1, 1335-1, and 1337-1 provided on the first sides of the third, fifth, and seventh cell dies 1333, 1335, and 1337 may be coupled to the first pads 1311-1 through the fifth, ninth, and thirteenth bonding wires 1351-2, 1351-3, and 1351-4. The second data pads 1333-2, 1335-2, and 1337-2 provided on the second sides of the third, fifth, and seventh cell dies 1333, 1335, and 1337 may be coupled to the second pads 1311-2 through the sixth, tenth, and fourteenth bonding wires 1352-2, 1352-3, and 1352-4. The fourth, sixth, and eighth cell dies 1334, 1336, and 1338 may be respectively coupled to the third pads 1312-1 through seventh, eleventh, and fifteenth bonding wires 1353-2, 1353-3, and 1353-4. The fourth, sixth, and eighth cell dies 1334, 1336, and 1338 may be respectively coupled to the fourth pads 1312-2 through eighth, twelfth, and sixteenth bonding wires 1354-2, 1354-3, and 1354-4. The first data pads 1334-1, 1336-1, and 1338-1 provided on the first sides of the fourth, sixth, and eighth cell dies 1334, 1336, and 1338 may be coupled to the third pads 1312-1 through the seventh, eleventh, and fifteenth bonding wires 1353-2, 1353-3, and 1353-4. The second data pads 1334-2, 1336-2, and 1338-2 provided on the second sides of the fourth, sixth, and eighth cell dies 1334, 1336, and 1338 may be coupled to the fourth pads 1312-2 through the eighth, twelfth, and sixteenth bonding wires 1354-2, 1354-3, and 1354-4.

The logic die 1320 may be coupled to the first pads 1311-1 through the first signal transmission lines 1313-1, and may be coupled to the second pads 1311-2 through the second signal transmission lines 1313-2. The logic die 1320 may be coupled to the third pads 1312-1 through the third signal transmission lines 1314-1, and may be coupled to the fourth pads 1312-2 through the fourth signal transmission lines 1314-2. The logic die 1320 may be respectively coupled to first data pads 1331-1, 1333-1, 1335-1, and 1337-1 of the first, third, fifth, and seventh cell dies 1331, 1333, 1335, and 1337 through the first signal transmission lines 1313-1, the first pads 1311-1, and the first, fifth, ninth, and thirteenth bonding wires 1351-1, 1351-2, 1351-3, and 1351-4. The logic die 1320 may be respectively coupled to the second data pads 1331-2, 1333-2, 1335-2, and 1337-2 of the first, third, fifth, and seventh cell dies 1331, 1333, 1335, and 1337 through the second signal transmission lines 1313-2, the second pads 1311-2, and the second, sixth, tenth, and fourteenth bonding wires 1352-1, 1352-2, 1352-3, and 1352-4. The logic die 1320 may be respectively coupled to the first data pads 1332-1, 1334-1, 1336-1, and 1338-1 of the second, fourth, sixth, and eighth cell dies 1332, 1334, 1336, and 1338 through the third signal transmission lines 1314-1, the third pads 1312-1, and the third, seventh, eleventh, and fifteenth bonding wires 1353-1, 1353-2, 1353-3, and 1353-4. The logic die 1320 may be respectively coupled to the second data pads 1332-2, 1334-2, 1336-2, and 1338-2, which are provided on the second sides of the second, fourth, sixth, and eighth cell dies 1332, 1334, 1336, and 1338, through the fourth signal transmission lines 1314-2, the fourth pads 1312-2, and the fourth, eighth, twelfth, and sixteenth bonding wires 1354-1, 1354-2, 1354-3, and 1354-4. The logic die 1320 may be coupled to an external apparatus of the semiconductor apparatus 1300 through the fifth signal transmission lines 1315. The package substrate 1310 may include package balls 1316, and the fifth signal transmission lines 1315 may be coupled to the external apparatus through the package balls 1316. The logic die 1350 may deserialize signals on the fifth signal transmission lines 1315 into signals on the first to fourth signal transmission lines 1313-1, 1313-2, 1314-1, and 1314-2, and may serialize signals on the first to fourth signal transmission lines 1313-1, 1313-2, 1314-1, and 1314-2 into signals on the fifth signal transmission lines 1315. The logic die 1350 may perform an error correction operation on signals on the first to fourth signal transmission lines 1313-1, 1313-2, 1314-1, and 1314-2.

Although not illustrated, as shown in FIG. 7, the package substrate 1310 may additionally include pads that supply a power voltage. One of the pads that supply the power voltage may be provided at a distance from a third side of the first cell die 1331 in a z-axis direction, and another one of the pads may be provided at a distance from a third side of the second cell die 1332 in a z-axis direction. In an embodiment, one of the pads that supply the power voltage may be provided at a distance from a fourth side facing the third side of the first cell die 1331 in a z-axis direction, and another one of the pads may be provided at a distance from a fourth side facing the third side of the second cell die 1332 in a z-axis direction. In an embodiment, the package substrate 1310 may include pads that supply the power voltage at respective distances from the third and fourth sides of the first cell die 1331 in a z-axis direction. The package substrate 1310 may include the pads that supply the power voltage at respective distances from the third and fourth sides of the second cell die 1332 in a z-axis direction. The first, third, fifth, and seventh cell dies 1331, 1333, 1335, and 1337 may respectively include power pads on a third side or a fourth side. The second, fourth, sixth, and eighth cell dies 1332, 1334, 1336, and 1338 may respectively include power pads on a third side or a fourth side. The power pads of the first, third, fifth, and seventh cell dies 1331, 1333, 1335, and 1337 may be coupled to the pad and/or pads that supply the power voltage through bonding wires. The power pads of the second, fourth, sixth, and eighth cell dies 1332, 1334, 1336, and 1338 may be coupled to the pad and/or pads that supply the power voltage through bonding wires.

The first data pads 1331-1, 1333-1, 1335-1, and 1337-1, which are disposed on the first sides of the first, third, fifth, and seventh cell dies 1331, 1333, 1335, and 1337, may be respectively coupled to the first pads 1311-1 of the package substrate 1310 through the first, fifth, ninth, and thirteenth bonding wires 1351-1, 1351-2, 1351-3, and 1351-4, and the first pads 1311-1 may be coupled to the logic die 1320 through the first signal transmission lines 1313-1. The number of the first, fifth, ninth, and thirteenth bonding wires 1351-1, 1351-2, 1351-3, and 1351-4 may each be N*k/2, and the number of the first signal transmission lines 1313-1 may also be N*k/2. The second data pads 1331-2, 1333-2, 1335-2, and 1337-2, which are disposed on the second sides of the first, third, fifth, and seventh cell dies 1331, 1333, 1335, and 1337, may be respectively coupled to the second pads 1311-2 of the package substrate 1310 through the second, sixth, tenth, and fourteenth bonding wires 1352-1, 1352-2, 1352-3, and 1352-4, and the second pads 1311-2 may be coupled to the logic die 1320 through the second signal transmission lines 1313-2. The number of the second, sixth, tenth, and fourteenth bonding wires 1352-1, 1352-2, 1352-3, and 1352-4 may each be N*k/2, and the number of the second signal transmission lines 1313-2 may also be N*k/2. The first data pads 1332-1, 1334-1, 1336-1, and 1338-1, which are disposed on the first sides of the second, fourth, sixth, and eighth cell dies 1332, 1334, 1336, and 1338, may be respectively coupled to the third pads 1312-1 of the package substrate 1310 through the third, seventh, eleventh, and fifteenth bonding wires 1353-1, 1353-2, 1353-3, and 1353-4, and the third pads 1312-1 may be coupled to the logic die 1320 through the third signal transmission lines 1314-1. The number of the third, seventh, eleventh, and fifteenth bonding wires 1353-1, 1353-2, 1353-3, and 1353-4 may each be N*k/2, and the number of the third signal transmission lines 1314-1 may also be N*k/2. The second data pads 1332-2, 1334-2, 1336-2, and 1338-2, which are disposed on the second sides of the second, fourth, sixth, and eighth cell dies 1332, 1334, 1336, and 1338, may be respectively coupled to the fourth pads 1312-2 of the package substrate 1310 through the fourth, eighth, twelfth, and sixteenth bonding wires 1354-1, 1354-2, 1354-3, and 1354-4, and the fourth pads 1312-2 may be coupled to the logic die 1320 through the fourth signal transmission lines 1314-2. The number of the fourth, eighth, twelfth, and sixteenth bonding wires 1354-1, 1354-2, 1354-3, and 1354-4 may each be N*k/2, and the number of the fourth signal transmission lines 1314-2 may also be N*k/2. The number of the fifth signal transmission lines 1315 may be N, 2N, or 4N.

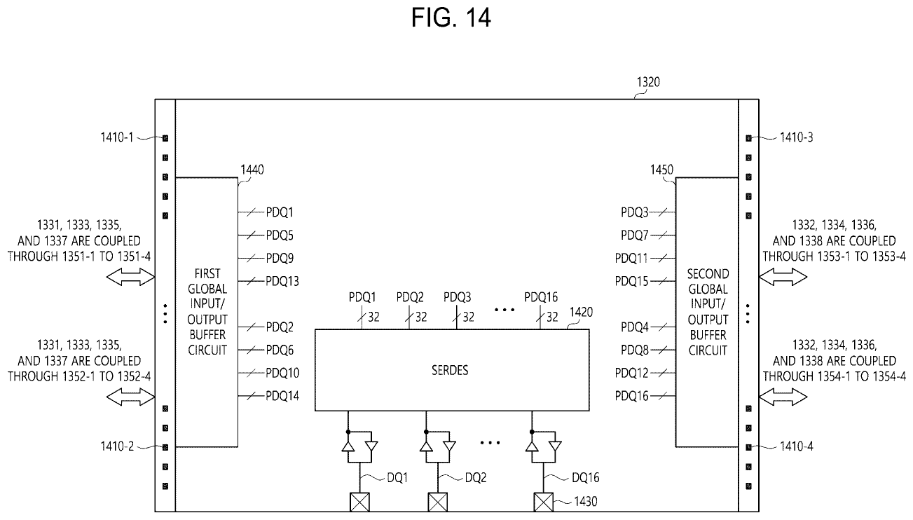

FIG. 14 is a diagram illustrating a configuration of the logic die 1320 shown in FIG. 13. Referring to FIGS. 13 and 14, the logic die 1320 may include a serializer/deserializer 1420, a first global input/output buffer circuit 1440, and a second global input/output buffer circuit 1450. The serializer/deserializer 1420 may be coupled between N data transmission lines and N*k data input/output lines. The N data transmission lines may be signal transmission lines through which the logic die 1320 is coupled to an external device. The N*k data input/output lines may be signal transmission lines through which the logic die 1320 is coupled to a plurality of cell dies. For example, when N is 16 and k is 32, the serializer/deserializer 1420 may be coupled between 16 data transmission lines DQ1-DQ16 and 512 data input/output lines. The 16 data transmission lines DQ1-DQ16 may be coupled to external data pads 1430 of the logic die 1320. The external data pads 1430 may be coupled to the external apparatus through the bumps 1321 and the fifth signal transmission lines 1315. For signal transmission between the serializer/deserializer 1420 and the external data pads 1430, a receiver and a transmitter may be provided for each of the data transmission lines DQ1-DQ16. The serializer/deserializer 1420 may serialize data signals on the 512 data input/output lines into data signals on the 16 data transmission lines DQ1-DQ16. The serializer/deserializer 1420 may deserialize the data signals on the 16 data transmission lines DQ1-DQ16 into data signals on the 512 data input/output lines. In FIG. 14, the serializer/deserializer 1420 is illustrated as being coupled to 16 data input/output line groups PDQ1-PDQ16, each of which may include 32 data input/output lines.

The first global input/output buffer circuit 1440 may be coupled to half of the 512 data input/output lines, which are organized into numbered PDQ groups (e.g., PDQ1 to PDQ16). For example, the first global input/output buffer circuit 1440 may be coupled to PDQ data input/output line groups that are enumerated as 4 m+1 and 4 m+2 data input/output line groups, where m may be 0, 1, 2, or 3. Thus, the first global input/output buffer circuit 1440 may be coupled to first, second, fifth, sixth, ninth, tenth, thirteenth, and fourteenth data input/output line groups PDQ1, PDQ2, PDQ5, PDQ6, PDQ9, PDQ10, PDQ13, and PDQ14, which include first to 256th data input/output lines. The first global input/output buffer circuit 1440 may be coupled to the first, second, fifth, sixth, ninth, tenth, thirteenth, and fourteenth bonding wires 1351-1, 1352-1, 1351-2, 1352-2, 1351-3, 1352-3, 1351-4, and 1352-4. The logic die 1320 includes first internal data pads 1410-1, and the first global input/output buffer circuit 1440 may be coupled to the first, fifth, ninth, and thirteenth bonding wires 1351-1, 1351-2, 1351-3, and 1351-4 through the first internal data pads 1410-1, the bumps 1321, and the first signal transmission lines 1313-1. The logic die 1320 includes second internal data pads 1410-2, and the first global input/output buffer circuit 1440 may be coupled to the second, sixth, tenth, and fourteenth bonding wires 1352-1, 1352-2, 1352-3, and 1352-4 through the second internal data pads 1410-2, the bumps 1321, and the second signal transmission lines 1313-2. The first global input/output buffer circuit 1440 may be coupled to the first data pads 1331-1, 1333-1, 1335-1, and 1337-1, which are provided on the first sides of the first, third, fifth, and seventh cell dies 1331, 1333, 1335, and 1337, through the first, fifth, ninth, and thirteenth bonding wires 1351-1, 1351-2, 1351-3, and 1351-4. The first global input/output buffer circuit 1440 may couple the 4 m+1 data input/output line groups to the first data pads 1331-1, 1333-1, 1335-1, and 1337-1 of the first, third, fifth, and seventh cell dies 1331, 1333, 1335, and 1337 through the first, fifth, ninth, and thirteenth bonding wires 1351-1, 1351-2, 1351-3, and 1351-4, respectively. Therefore, the first global input/output buffer circuit 1440 may couple the first, fifth, ninth, and thirteenth data input/output line groups PDQ1, PDQ5, PDQ9, and PDQ13 to the first, fifth, ninth, and thirteenth bonding wires 1351-1, 1351-2, 1351-3, and 1351-4, respectively. The first global input/output buffer circuit 1440 may buffer data signals on the first, fifth, ninth, and thirteenth data input/output line groups PDQ1, PDQ5, PDQ9, and PDQ13, and may transmit the buffered data signals to the first, third, fifth, and seventh cell dies 1331, 1333, 1335, and 1337 through the first, fifth, ninth, and thirteenth bonding wires 1351-1, 1351-2, 1351-3, and 1351-4. The first global input/output buffer circuit 1440 may buffer data signals transmitted from the first, third, fifth, and seventh cell dies 1331, 1333, 1335, and 1337 through the first, fifth, ninth, and thirteenth bonding wires 1351-1, 1351-2, 1351-3, and 1351-4, and may output the buffered data signals to the first, fifth, ninth, and thirteenth data input/output line groups PDQ1, PDQ5, PDQ9, and PDQ13. The first global input/output buffer circuit 1440 may be coupled to the second data pads 1331-2, 1333-2, 1335-2, and 1337-2 provided on the second sides of the first, third, fifth, and seventh cell dies 1331, 1333, 1335, and 1337 through the second, sixth, tenth, and fourteenth bonding wires 1352-1, 1352-2, 1352-3, and 1352-4, respectively. The first global input/output buffer circuit 1440 may couple the second, sixth, tenth, and fourteenth data input/output line groups PDQ2, PDQ6, PDQ10, and PDQ14 to the second, sixth, tenth, and fourteenth bonding wires 1352-1, 1352-2, 1352-3, and 1352-4, respectively. The first global input/output buffer circuit 1440 may buffer data signals on the second, sixth, tenth, and fourteenth data input/output line groups PDQ2, PDQ6, PDQ10, and PDQ14, and may transmit the buffered data signals to the first, third, fifth, and seventh cell dies 1331, 1333, 1335, and 1337 through the second, sixth, tenth, and fourteenth bonding wires 1352-1, 1352-2, 1352-3, and 1352-4. The first global input/output buffer circuit 1440 may buffer data signals transmitted from the first, third, fifth, and seventh cell dies 1331, 1333, 1335, and 1337 through the second, sixth, tenth, and fourteenth bonding wires 1352-1, 1352-2, 1352-3, and 1352-4, and may output the buffered data signals to the second, sixth, tenth, and fourteenth data input/output line groups PDQ2, PDQ6, PDQ10, and PDQ14. The first global input/output buffer circuit 1440 may be disposed on the first side of the logic die 1320 and may be adjacent to the second sides of the first, third, fifth, and seventh cell dies 1331, 1333, 1335, and 1337.

The second global input/output buffer circuit 1450 may be coupled to the remaining half of the 512 data input/output lines, which are also organized into numbered PDQ groups (e.g., PDQ1 to PDQ16). For example, the second global input/output buffer circuit 1450 may be coupled to PDQ data input/output line groups that are enumerated as 4 m+3 and 4 m+4 data input/output line groups. Thus, the second global input/output buffer circuit 1450 may be coupled to the third, fourth, seventh, eighth, eleventh, twelfth, fifteenth, and sixteenth data input/output line groups PDQ3, PDQ4, PDQ7, PDQ8, PDQ11, PDQ12, PDQ15, and PDQ16, and may be coupled to 257th to 512th data input/output lines. The second global input/output buffer circuit 1450 may be coupled to the third, fourth, seventh, eighth, eleventh, twelfth, fifteenth, and sixteenth bonding wires 1353-1, 1354-1, 1353-2, 1354-2, 1353-3, 1354-3, 1353-4, and 1354-4. The logic die 1320 may include third internal data pads 1410-3, and the second global input/output buffer circuit 1450 may be coupled to the third, seventh, eleventh, and fifteenth bonding wires 1353-1, 1353-2, 1353-3, and 1353-4 through the third internal data pads 1410-3, the bumps 1321, and the third signal transmission lines 1314-1. The logic die 1320 may include fourth internal data pads 1410-4, and the second global input/output buffer circuit 1450 may be coupled to the fourth, eighth, twelfth, and sixteenth bonding wires 1354-1, 1354-2, 1354-3, and 1354-4 through the fourth internal data pads 1410-4, the bumps 1321, and the fourth signal transmission lines 1314-2. The second global input/output buffer circuit 1450 may be coupled to the first data pads 1332-1, 1334-1, 1336-1, and 1338-1 provided on the first sides of the second, fourth, sixth, and eighth cell dies 1332, 1334, 1336, and 1338 through the third, seventh, eleventh, and fifteenth bonding wires 1353-1, 1353-2, 1353-3, and 1353-4. The second global input/output buffer circuit 1450 may couple the 4 m+3 data input/output line groups to the first data pads 1332-1, 1334-1, 1336-1, and 1338-1 of the second, fourth, sixth, and eighth cell dies 1332, 1334, 1336, and 1338 through the third, seventh, eleventh, and fifteenth bonding wires 1353-1, 1353-2, 1353-3, and 1353-4, respectively. The second global input/output buffer circuit 1450 may couple the third, seventh, eleventh, and fifteenth data input/output line groups PDQ3, PDQ7, PDQ11, and PDQ15 to the third, seventh, eleventh, and fifteenth bonding wires 1353-1, 1353-2, 1353-3, and 1353-4, respectively. The second global input/output buffer circuit 1450 may buffer data signals on the third, seventh, eleventh, and fifteenth data input/output line groups PDQ3, PDQ7, PDQ11, and PDQ15, and may transmit the buffered data signals to the second, fourth, sixth, and eighth cell dies 1332, 1334, 1336, and 1338 through the third, seventh, eleventh, and fifteenth bonding wires 1353-1, 1353-2, 1353-3, and 1353-4. The second global input/output buffer circuit 1450 may buffer data signals transmitted from the second, fourth, sixth, and eighth cell dies 1332, 1334, 1336, and 1338 through the third, seventh, eleventh, and fifteenth bonding wires 1353-1, 1353-2, 1353-3, and 1353-4, and may output the buffered data signals to the third, seventh, eleventh, and fifteenth data input/output line groups PDQ3, PDQ7, PDQ11, and PDQ15. The second global input/output buffer circuit 1450 may couple the 4 m+4 data input/output line groups to the second data pads 1332-2, 1334-2, 1336-2, and 1338-2, which are provided on the second sides of the second, fourth, sixth, and eighth cell dies 1332, 1334, 1336, and 1338, respectively, through the fourth, eighth, twelfth, and sixteenth bonding wires 1354-1, 1354-2, 1354-3, and 1354-4. Therefore, the second global input/output buffer circuit 1450 may couple the fourth, eighth, twelfth, and sixteenth data input/output line groups PDQ4, PDQ8, PDQ12, and PDQ16 to the fourth, eighth, twelfth, and sixteenth bonding wires 1354-1, 1354-2, 1354-3, and 1354-4, respectively. The second global input/output buffer circuit 1450 may buffer data signals on the fourth, eighth, twelfth, and sixteenth data input/output line groups PDQ4, PDQ8, PDQ12, and PDQ16, and may transmit the buffered data signals to the second, fourth, sixth, and eighth cell dies 1332, 1334, 1336, and 1338 through the fourth, eighth, twelfth, and sixteenth bonding wires 1354-1, 1354-2, 1354-3, and 1354-4. The second global input/output buffer circuit 1450 may buffer data signals transmitted from the second, fourth, sixth, and eighth cell dies 1332, 1334, 1336, and 1338 through the fourth, eighth, twelfth, and sixteenth bonding wires 1354-1, 1354-2, 1354-3, and 1354-4, and may output the buffered data signals to the fourth, eighth, twelfth, and sixteenth data input/output line groups PDQ4, PDQ8, PDQ12, and PDQ16. Although not shown, the logic die 1320 may further include an error correction circuit configured to perform error correction operations on data signals on the first to sixteenth data input/output line groups PDQ1 through PDQ16. The second global input/output buffer circuit 1450 may be disposed on the second side of the logic die 1320 and may be adjacent to the second sides of the second, fourth, sixth, and eighth cell dies 1332, 1334, 1336, and 1338.

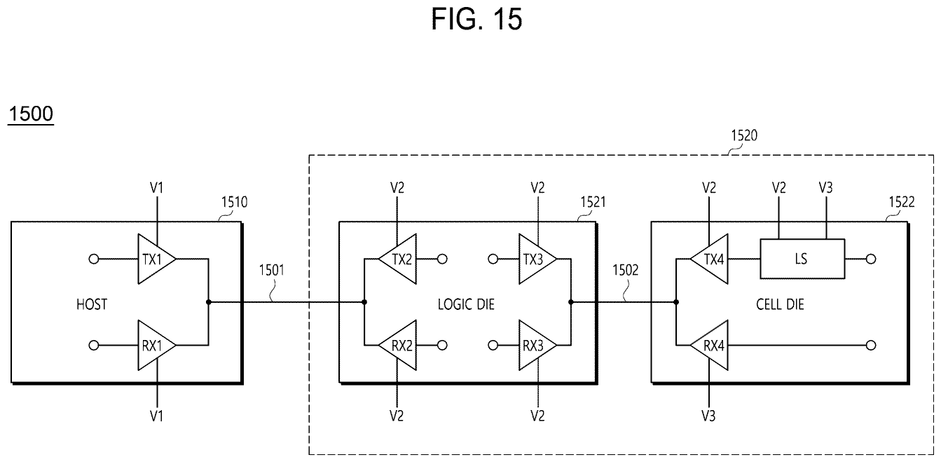

FIG. 15 is a diagram illustrating a configuration of a semiconductor system 1500 according to an embodiment of the present disclosure. Referring to FIG. 15, the semiconductor system 1500 may include a host 1510 and a semiconductor apparatus 1520. The host 1510 may be an external apparatus of the semiconductor apparatus 1520 and may be a master apparatus capable of controlling the semiconductor apparatus 1520. The semiconductor apparatus 1520 may be a slave apparatus that is controlled by the host 1510 and may perform a data input/output operation. The semiconductor apparatus 1520 may include a logic die 1521 and a cell die 1522. Although the semiconductor apparatus 1520 may include a plurality of cell dies, only one cell die is shown in FIG. 15 for convenience of explanation. The cell die 1522 may be manufactured through a first-type process technology. The logic die 1521 may be manufactured through a second-type process technology. The host 1510 may be manufactured through a third-type process technology. The logic die 1521 and the cell die 1522 may be packaged into a single package. The second-type process technology may be finer than the first-type process technology. The third-type process technology may be the same as or finer than the second-type process technology. The host 1510 may operate by receiving a first power voltage V1. The logic die 1521 may operate by receiving a second power voltage. The cell die 1522 may operate by receiving the second power voltage V2 and a third power voltage V3. The first power voltage V1 may have a voltage level that is equal to or lower than the second power voltage V2. The second power voltage V2 may have a voltage level lower than the third power voltage V3. The host 1510 may be coupled to the logic die 1521 through a first signal transmission line 1501. A signal transmitted between the host 1510 and the logic die 1521 through the first signal transmission line 1501 may swing within a range between a voltage level of the first power voltage V1 and a ground voltage. The logic die 1521 may be coupled to the cell die 1522 through a second signal transmission line 1502. A signal transmitted between the logic die 1521 and the cell die 1522 through the second signal transmission line may swing within a range between a voltage level of the second power voltage V2 and the ground voltage.

The host 1510 may include a first transmitter TX1 and a first receiver RX1. The first transmitter TX1 may operate by receiving the first power voltage V1. Based on an internal data signal of the host 1510, the first transmitter TX1 may drive the first signal transmission line 1501 with the first power voltage V1 and the ground voltage, and may transmit a data signal to the logic die 1521 through the first signal transmission line 1501. The first receiver RX1 may operate by receiving the first power voltage V1. The first receiver RX1 may receive a data signal transmitted from the logic die 1521 through the first signal transmission line 1501 and may drive the data signal with the first power voltage V1 and the ground voltage to generate an internal data signal of the host 1510.

The logic die 1521 may include a second transmitter TX2, a second receiver RX2, a third transmitter TX3, and a third receiver RX3. The second transmitter TX2 may operate by receiving the second power voltage V2. Based on an internal data signal of the logic die 1521, the second transmitter TX2 may drive the first signal transmission line 1501 with the second power voltage V2 and the ground voltage, and may transmit a data signal to the host 1510 through the first signal transmission line 1501. The second receiver RX2 may operate by receiving the second power voltage V2. The second receiver RX2 may receive a data signal transmitted from the host 1510 through the first signal transmission line 1501 and may drive the data signal with the second power voltage V2 and the ground voltage to generate an internal data signal of the logic die 1521. In an embodiment, when the first power voltage V1 has a voltage level lower than the second power voltage V2, the second transmitter TX2 may operate by receiving the first and second power voltages V1 and V2. The second transmitter TX2 may further include a level shifter for changing a swing range of the internal data signal of the logic die 1521. The second transmitter TX2 may convert the internal data signal swinging between the second power voltage V2 and the ground voltage into a signal swinging between the first power voltage V1 and the ground voltage, and may drive the first signal transmission line 1501 with the first power voltage V1 and the ground voltage. The third transmitter TX3 may operate by receiving the second power voltage V2. Based on an internal data signal of the logic die 1521, the third transmitter TX3 may drive the second signal transmission line 1502 with the second power voltage V2 and the ground voltage, and may transmit a data signal to the cell die 1522 through the second signal transmission line 1502. The third receiver RX3 may operate by receiving the second power voltage V2. The third receiver RX3 may receive a data signal transmitted from the cell die 1522 through the second signal transmission line 1502 and may drive the data signal with the second power voltage V2 and the ground voltage to generate an internal data signal of the logic die 1521.

The cell die 1522 may include a level shifter LS, a fourth transmitter TX4, and a fourth receiver RX4. The level shifter LS may operate by receiving the second and third power voltages V2 and V3. The level shifter LS may convert a swing range of an internal data signal of the cell die 1522. The internal data signal of the cell die 1522 may swing within a range between a voltage level of the third power voltage V3 and the ground voltage, and a data signal output from the level shifter LS may swing within a range between a voltage level of the second power voltage V2 and the ground voltage. The fourth transmitter TX4 may operate by receiving the second power voltage V2. Based on the data signal output from the level shifter LS, the fourth transmitter TX4 may drive the second signal transmission line 1502 with the second power voltage V2 and the ground voltage and may transmit a data signal to the logic die 1521 through the second signal transmission line 1502. The fourth receiver RX4 may operate by receiving the third power voltage V3. The fourth receiver RX4 may receive a data signal transmitted from the logic die 1521 through the second signal transmission line 1502 and may drive the data signal with the third power voltage V3 and the ground voltage. As swing ranges of signals transmitted between the host 1510 and the logic die 1521 and between the logic die 1521 and the cell die 1522 are reduced, power consumption of the semiconductor system 1500 may be reduced.

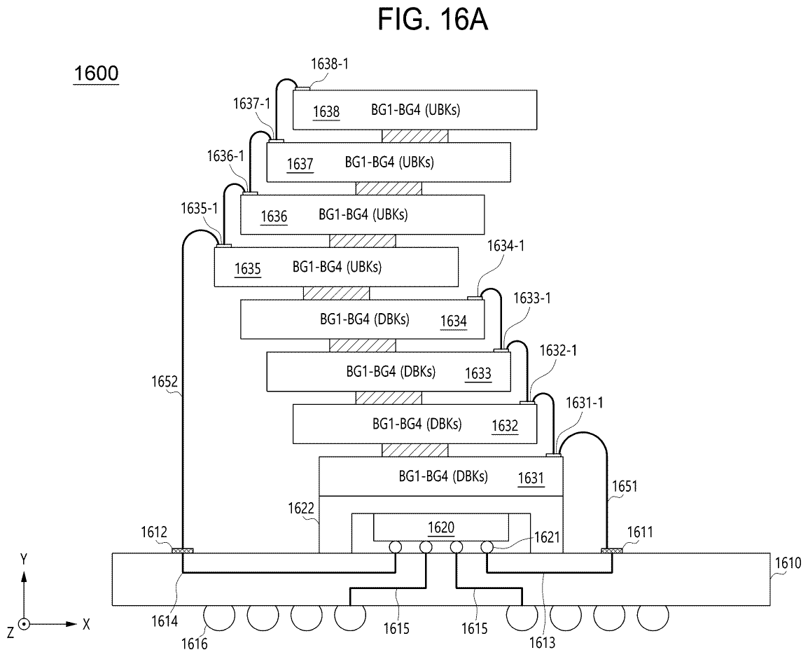

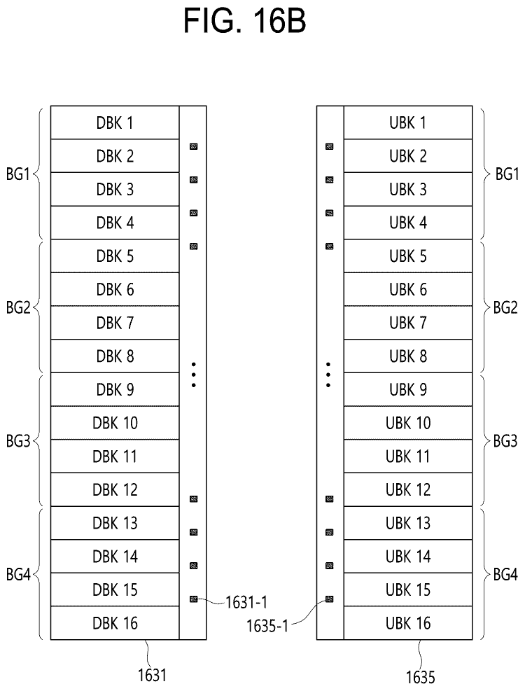

FIG. 16 is a diagram illustrating a configuration and connection relationship of a semiconductor apparatus 1600 according to an embodiment of the present disclosure. Referring to FIG. 16, the semiconductor apparatus 1600 may include a package substrate 1610, a logic die 1620, and a plurality of cell dies. The logic die 1620 and the plurality of cell dies may be disposed on the package substrate 1610 and may be packaged as a single package. For example, the semiconductor apparatus 1600 may include first to eighth cell dies 1631, 1632, 1633, 1634, 1635, 1636, 1637, and 1638. The logic die 1620 may be disposed on the package substrate 1610 in a y-axis direction. The logic die 1620 may be disposed at a central portion of the package substrate 1610 in the x-axis and z-axis directions. The logic die 1620 may include a plurality of bumps 1621 and may be coupled to the package substrate 1610 through the plurality of bumps 1621. The first cell die 1631 may be disposed on the logic die 1620 in a y-axis direction. The first cell die 1631 may be disposed to cover a part or all of the logic die 1620. The first cell die 1631 may be bonded to the logic die 1620 using an adhesive or a die attach film. The semiconductor apparatus 1600 may further include a molding structure 1622 surrounding the logic die 1620 and configured to support the first cell die 1631. The second cell die 1632 may be disposed on the first cell die 1631 in the y-axis direction. The third cell die 1633 may be disposed on the second cell die 1632 in the y-axis direction. The fourth cell die 1634 may be disposed on the third cell die 1633 in the y-axis direction. The second to fourth cell dies 1632, 1633, and 1634 may be respectively attached to the first to third cell dies 1631, 1632, and 1633 using a die attach film. The first to eighth cell dies 1631, 1632, 1633, 1634, 1635, 1636, 1637, and 1638 may each include data pads 1631-1, 1632-1, 1633-1, 1634-1, 1635-1, 1636-1, 1637-1, and 1638-1, respectively, on a first side of each respective cell dies. The first to fourth cell dies 1631, 1632, 1633, and 1634 may be disposed in a stepwise structure such that the first side of each of the first to fourth cell dies 1631, 1632, 1633, and 1634 and/or the data pads 1631-1, 1632-1, 1633-1, and 1634-1 are respectively exposed. The second cell die 1632 may be disposed on the first cell die 1631 by being shifted or offset in a second direction of an x-axis such that the first side of the first cell die 1631 and/or the data pads 1631-1 are exposed in a first direction of the x-axis. The third cell die 1633 may be disposed on the second cell die 1632 by being shifted in the second direction of the x-axis such that the first side of the second cell die 1632 and/or the data pads 1632-1 are exposed in the first direction of the x-axis. The fourth cell die 1634 may be disposed on the third cell die 1633 by being shifted in the second direction of the x-axis such that the first side of the third cell die 1633 and/or the data pads 1633-1 are exposed in the first direction of the x-axis. The fifth cell die 1635 may be disposed on the fourth cell die 1634 in a y-axis direction. The sixth cell die 1636 may be disposed on the fifth cell die 1635 in the y-axis direction. The seventh cell die 1637 may be disposed on the sixth cell die 1636 in the y-axis direction. The eighth cell die 1638 may be disposed on the seventh cell die 1637 in the y-axis direction. The fifth to eighth cell dies 1635, 1636, 1637, and 1638 may be respectively attached to the fourth to seventh cell dies 1634, 1635, 1636, and 1637 using a die attach film. The fifth to eighth cell dies 1635, 1636, 1637, and 1638 may be rotated by 180 degrees with respect to the first to fourth cell dies 1631, 1632, 1633, and 1634 and may be sequentially disposed on the fourth cell die 1634. The fifth to eighth cell dies 1635, 1636, 1637, and 1638 may be disposed in a stepwise structure such that the first side of each of the fifth to eighth cell dies 1635, 1636, 1637, and 1638 and/or the data pads 1635-1, 1636-1, 1637-1, and 1638-1 are respectively exposed. The fifth cell die 1635 may be disposed on the fourth cell die 1634 by being shifted in the second direction of an x-axis such that the first side of the fourth cell die 1634 and/or the data pads 1634-1 are exposed in the first direction of the x-axis. The sixth cell die 1636 may be disposed on the fifth cell die 1635 by being shifted in the first direction of the x-axis such that the first side of the fifth cell die 1635 and/or the data pads 1635-1 are exposed in the second direction of the x-axis. The seventh cell die 1637 may be disposed on the sixth cell die 1636 by being shifted in the first direction of the x-axis such that the first side of the sixth cell die 1636 and/or the data pads 1636-1 are exposed in the second direction of the x-axis. The eighth cell die 1638 may be disposed on the seventh cell die 1637 by being shifted in the first direction of the x-axis such that the first side of the seventh cell die 1637 and/or the data pads 1637-1 are exposed in the second direction of the x-axis.

The package substrate 1610 may include first pads 1611, second pads 1612, first signal transmission lines 1613, second signal transmission lines 1614, and third signal transmission lines 1615. The first pads 1611 and the second pads 1612 may be provided on the package substrate 1610, and the first to third signal transmission lines 1613, 1614, and 1615 may be provided in the package substrate 1610. For example, the first pads 1611 may be provided on the package substrate 1610 at a distance spaced apart from a first side of the first cell die 1631 in an x-axis direction, and the second pads 1612 may be provided on the package substrate 1610 at a distance spaced apart from the fifth cell die 1635 in the x-axis direction. The first cell die 1631 may be coupled to the first pads 1611 through first bonding wires 1651. The data pads 1631-1 of the first cell die 1631 may be coupled to the first pads 1611 through the first bonding wires 1651. The second to fourth cell dies 1632, 1633, and 1634 may be coupled to the first pads 1611 through the first bonding wires 1651. The data pads 1632-1, 1633-1, and 1634-1 of the second to fourth cell dies 1632, 1633, and 1634 may be coupled to the first pads 1611 through the first bonding wires 1651. The data pads 1631-1, 1632-1, 1633-1, and 1634-1 of the first to fourth cell dies 1631, 1632, 1633, and 1634 may be coupled in common through the first bonding wires 1651. The fifth cell die 1635 may be coupled to the second pads 1612 through second bonding wires 1652. The data pads 1635-1 of the fifth cell die 1635 may be coupled to the second pads 1612 through the second bonding wires 1652. The sixth to eighth cell dies 1636, 1637, and 1638 may be coupled to the second pads 1612 through the second bonding wires 1652. The data pads 1636-1, 1637-1, and 1638-1 of the sixth to eighth cell dies 1636, 1637, and 1638 may be coupled to the second pads 1612 through the second bonding wires 1652. The data pads 1635-1, 1636-1, 1637-1, and 1638-1 of the fifth to eighth cell dies 1635, 1636, 1637, and 1638 may be coupled in common through the second bonding wires 1652. The logic die 1620 may be coupled to the first pads 1611 through the first signal transmission lines 1613. The logic die 1620 may be coupled to the first to fourth cell dies 1631, 1632, 1633, and 1634 through the first signal transmission lines 1613, the first pads 1611, and the first bonding wires 1651. The logic die 1620 may be coupled to the second pads 1612 through the second signal transmission lines 1614. The logic die 1620 may be coupled to the fifth to eighth cell dies 1635, 1636, 1637, and 1638 through the second signal transmission lines 1614, the second pads 1612, and the second bonding wires 1652. The logic die 1620 may be coupled to an external apparatus of the semiconductor apparatus 1600 through the third signal transmission lines 1615. The logic die 1620 may be coupled to a plurality of pads formed on the package substrate 1610 through the plurality of bumps 1621. The logic die 1620 may be coupled to the first to third signal transmission lines 1613, 1614, and 1615 through the plurality of bumps 1621. The package substrate 1610 may include package balls 1616, and the third signal transmission lines 1615 may be coupled to the external apparatus through the package balls 1616. The logic die 1620 may deserialize signals on the third signal transmission lines 1615 into signals on the first and second signal transmission lines 1613 and 1614, and may serialize signals on the first and second signal transmission lines 1613 and 1614 into signals on the third signal transmission lines 1615. The logic die 1620 may perform an error correction operation on signals on the first and second signal transmission lines 1613 and 1614. A ratio of the number of the first and second signal transmission lines to the number of the third signal transmission lines may be k to 1, for example, 8 to 1 or 16 to 1.

Although not illustrated, the first to eighth cell dies 1631, 1632, 1633, 1634, 1635, 1636, 1637, and 1638 may each include power pads on a second side opposite to the first side. The package substrate 1610 may further include a third pad and a fourth pad. The third pad may be provided on the package substrate 1610 at a distance spaced apart from the first pads 1611. The fourth pad may be provided on the package substrate 1610 at a distance spaced apart from the second pads 1612. A power supply voltage may be supplied to the third pad and the fourth pad. Power pads of the first to fourth cell dies 1631, 1632, 1633, and 1634 may be respectively coupled to the third pad through bonding wires. Power pads of the fifth to eighth cell dies 1635, 1636, 1637, and 1638 may be respectively coupled to the fourth pad through bonding wires.

The first cell die 1631 may include down memory banks of bank groups accessed based on a first address group, and the fifth cell die 1635 may include up memory banks of the bank groups accessed based on the first address group. The second cell die 1632 may include down memory banks of bank groups accessed based on a second address group, and the sixth cell die 1636 may include up memory banks of the bank groups accessed based on the second address group. The third cell die 1633 may include down memory banks of bank groups accessed based on a third address group, and the seventh cell die 1637 may include up memory banks of the bank groups accessed based on the third address group. The fourth cell die 1634 may include down memory banks of bank groups accessed based on a fourth address group, and the eighth cell die 1638 may include up memory banks of the bank groups accessed based on the fourth address group. For example, the first cell die 1631 may include down memory banks DBKs of first to fourth bank groups BG1 to BG4 accessed based on the first address group. The second cell die 1632 may include down memory banks DBKs of first to fourth bank groups BG1 to BG4 accessed based on the second address group. The third cell die 1633 may include down memory banks DBKs of first to fourth bank groups BG1 to BG4 accessed based on the third address group. The fourth cell die 1634 may include down memory banks DBKs of first to fourth bank groups BG1 to BG4 accessed based on the fourth address group. The fifth cell die 1635 may include up memory banks UBKs of the first to fourth bank groups BG1 to BG4 accessed based on the first address group. The sixth cell die 1636 may include up memory banks UBKs of the first to fourth bank groups BG1 to BG4 accessed based on the second address group. The seventh cell die 1637 may include up memory banks UBKs of the first to fourth bank groups BG1 to BG4 accessed based on the third address group. The eighth cell die 1638 may include up memory banks UBKs of the first to fourth bank groups BG1 to BG4 accessed based on the fourth address group. Accordingly, the first and fifth cell dies 1631 and 1635 may operate as one independent rank, die, or slice, and the second and sixth cell dies 1632 and 1636 may also operate as one independent rank, die, or slice. The third and seventh cell dies 1633 and 1637 may operate as one independent rank, die, or slice, and the fourth and eighth cell dies 1634 and 1638 may also operate as one independent rank, die, or slice. The semiconductor apparatus 1600 may reduce a package size of the semiconductor apparatus 1600 by stacking the cell dies on the logic die 1620 and disposing the cell dies in a stepwise structure such that data pads of the cell dies are exposed.

FIG. 16B is a diagram illustrating configurations of a first cell die 1631 and a fifth cell die 1635 illustrated in FIG. 16A. Referring to FIG. 16B, the first cell die 1631 may include the first bank group BG1, the second bank group BG2, the third bank group BG3, and the fourth bank group BG4. The first bank group BG1 may include a first down memory bank DBK1, a second down memory bank DBK2, a third down memory bank DBK3, and a fourth down memory bank DBK4. The second bank group BG2 may include a fifth down memory bank DBK5, a sixth down memory bank DBK6, a seventh down memory bank DBK7, and an eighth down memory bank DBK8. The third bank group BG3 may include a ninth down memory bank DBK9, a tenth down memory bank DBK10, an eleventh down memory bank DBK11, and a twelfth down memory bank DBK12. The fourth bank group BG4 may include a thirteenth down memory bank DBK13, a fourteenth down memory bank DBK14, a fifteenth down memory bank DBK15, and a sixteenth down memory bank DBK16. The fifth cell die 1635 may include the first bank group BG1, the second bank group BG2, the third bank group BG3, and the fourth bank group BG4 accessed based on the same address group as the first to fourth bank groups BG1, BG2, BG3, and BG4 of the first cell die 1631. The first bank group BG1 may include a first up memory bank UBK1, a second up memory bank UBK2, a third up memory bank UBK3, and a fourth up memory bank UBK4. The second bank group BG2 may include a fifth up memory bank UBK5, a sixth up memory bank UBK6, a seventh up memory bank UBK7, and an eighth up memory bank UBK8. The third bank group BG3 may include a ninth up memory bank UBK9, a tenth up memory bank UBK10, an eleventh up memory bank UBK11, and a twelfth up memory bank UBK12. The fourth bank group BG4 may include a thirteenth up memory bank UBK13, a fourteenth up memory bank UBK14, a fifteenth up memory bank UBK15, and a sixteenth up memory bank UBK16. In FIG. 16B, orders of the memory banks included in each bank group are illustrated by way of example and are not intended to be limiting, and orders of the memory banks included in each bank group may be variously changed. The first cell die 1631 may include the data pads 1631-1 on a first side, and the fifth cell die 1635 may include the data pads 1635-1 on a first side. The first side may be a portion adjacent to one of two longer sides among four sides of the first cell die 1631 and the fifth cell die 1635.

Referring to FIG. 16A, the data pads 1631-1, 1632-1, 1633-1, and 1634-1 of the first to fourth cell dies 1631, 1632, 1633, and 1634 may be coupled to the first pads 1611 of the package substrate 1610 through the first bonding wires 1651, and the first pads 1611 may be coupled to the logic die 1620 through the first signal transmission lines 1613. The data pads 1635-1, 1636-1, 1637-1, and 1638-1 of the fifth to eighth cell dies 1635, 1636, 1637, and 1638 may be coupled to the second pads 1612 of the package substrate 1610 through the second bonding wires 1652, and the second pads 1612 may be coupled to the logic die 1620 through the second signal transmission lines 1614. The number of the data pads 1631-1, 1632-1, 1633-1, 1634-1, 1635-1, 1636-1, 1637-1, and 1638-1 of the first to eighth cell dies 1631, 1632, 1633, 1634, 1635, 1636, 1637, and 1638 may each be N*k/2. The number of the first bonding wires 1651 may be N*k/2, and the number of the first signal transmission lines 1613 may also be N*k/2. The number of the second bonding wires 1652 may be N*k/2, and the number of the second signal transmission lines 1614 may also be N*k/2. The number of the third signal transmission lines 1615 may be N, 2N, or 4N. The logic die 1620 may be implemented as a logic die 520 described above and illustrated in FIG. 5.

The semiconductor apparatus 1600 may support a plurality of data input/output modes. The plurality of data input/output modes may include a first data input/output mode, a second data input/output mode, and a third data input/output mode. For example, the first data input/output mode may be x16 and may be an operation mode in which a data input/output operation is performed by transmitting 16 serial data signals. The second data input/output mode may be x4 and may be an operation mode in which a data input/output operation is performed by transmitting four serial data signals. The third data input/output mode may be x8 and may be an operation mode in which a data input/output operation is performed by transmitting eight serial data signals. When the semiconductor apparatus 1600 supports all of the first to third data input/output modes, the number of the third signal transmission lines may be 16, and a burst length may be 16 or 32. For example, when N is 16 and k is 16, an operation in which data are transmitted from the external apparatus to the semiconductor apparatus 1600 will be described as follows. In the second data input/output mode, four serial data signals transmitted from the external apparatus may be deserialized by the logic die 1620 into 64 parallel data signals. The 64 parallel data signals may be divided and transmitted to one of the first to fourth cell dies 1631, 1632, 1633, and 1634 and one of the fifth to eighth cell dies 1635, 1636, 1637, and 1638. In the second data input/output mode, the logic die 1620 may simultaneously access one of the first to fourth cell dies 1631, 1632, 1633, and 1634 and one of the fifth to eighth cell dies 1635, 1636, 1637, and 1638, and may perform a data input/output operation with two accessed cell dies. For example, the logic die 1620 may access the first and fifth cell dies 1631 and 1635 in conjunction, based on the first address group, or may access the second and sixth cell dies 1632 and 1636 in conjunction, based on the second address group. In addition, the logic die may access the third and seventh cell dies 1633 and 1637 in conjunction, based on the third address group, or may access the fourth and eighth cell dies 1634 and 1638 in conjunction, based on the fourth address group. For example, when the logic die 1620 accesses the first and fifth cell dies 1631 and 1635 based on the first address group, the logic die 1620 may transmit first to thirty-second parallel data signals from among the 64 parallel data signals to the first cell die 1631 through the first bonding wires 1651, and may transmit thirty-third to sixty-fourth parallel data signals to the fifth cell die 1635 through the second bonding wires 1652.

In the third data input/output mode, eight serial data signals transmitted from the external apparatus may be deserialized by the logic die 1620 into 128 parallel data signals. The 128 parallel data signals may be divided and transmitted to one of the first to fourth cell dies 1631, 1632, 1633, and 1634 and one of the fifth to eighth cell dies 1635, 1636, 1637, and 1638. In the third data input/output mode, the logic die 1620 may simultaneously access one of the first to fourth cell dies 1631, 1632, 1633, and 1634 and one of the fifth to eighth cell dies 1635, 1636, 1637, and 1638, and may perform a data input/output operation with two accessed cell dies. For example, the logic die 1620 may access the first and fifth cell dies 1631 and 1635 in conjunction, based on the first address group, or may access the second and sixth cell dies 1632 and 1636 in conjunction, based on the second address group. In addition, the logic die may access the third and seventh cell dies 1633 and 1637 in conjunction, based on the third address group, or may access the fourth and eighth cell dies 1634 and 1638 in conjunction, based on the fourth address group. For example, when the logic die 1620 accesses the first and fifth cell dies 1631 and 1635 based on the first address group, the logic die 1620 may transmit first to sixty-fourth parallel data signals from among the 128 parallel data signals to the first cell die 1631 through the first bonding wires 1651, and may transmit sixty-fifth to one hundred twenty-eighth parallel data signals to the fifth cell die 1635 through the second bonding wires 1652.

In the first data input/output mode, 16 serial data signals transmitted from the external apparatus may be deserialized by the logic die 1620 into 256 parallel data signals. The 256 parallel data signals may be divided and transmitted to one of the first to fourth cell dies 1631, 1632, 1633, and 1634 and one of the fifth to eighth cell dies 1635, 1636, 1637, and 1638. In the first data input/output mode, the logic die 1620 may simultaneously access one of the first to fourth cell dies 1631, 1632, 1633, and 1634 and one of the fifth to eighth cell dies 1635, 1636, 1637, and 1638, and may perform a data input/output operation with two accessed cell dies. For example, the logic die 1620 may access the first and fifth cell dies 1631 and 1635 in conjunction, based on the first address group, or may access the second and sixth cell dies 1632 and 1636 in conjunction, based on the second address group. In addition, the logic die may access the third and seventh cell dies 1633 and 1637 in conjunction, based on the third address group, or may access the fourth and eighth cell dies 1634 and 1638 in conjunction, based on the fourth address group. For example, when the logic die 1620 accesses the first and fifth cell dies 1631 and 1635 based on the first address group, the logic die 1620 may transmit first to one hundred twenty-eighth parallel data signals from among the 256 parallel data signals to the first cell die 1631 through the first bonding wires 1651, and may transmit one hundred twenty-ninth to two hundred fifty-sixth parallel data signals to the fifth cell die 1635 through the second bonding wires 1652. An operation in which data are transmitted from the semiconductor apparatus 1600 to the external apparatus may also be performed in a similar manner.

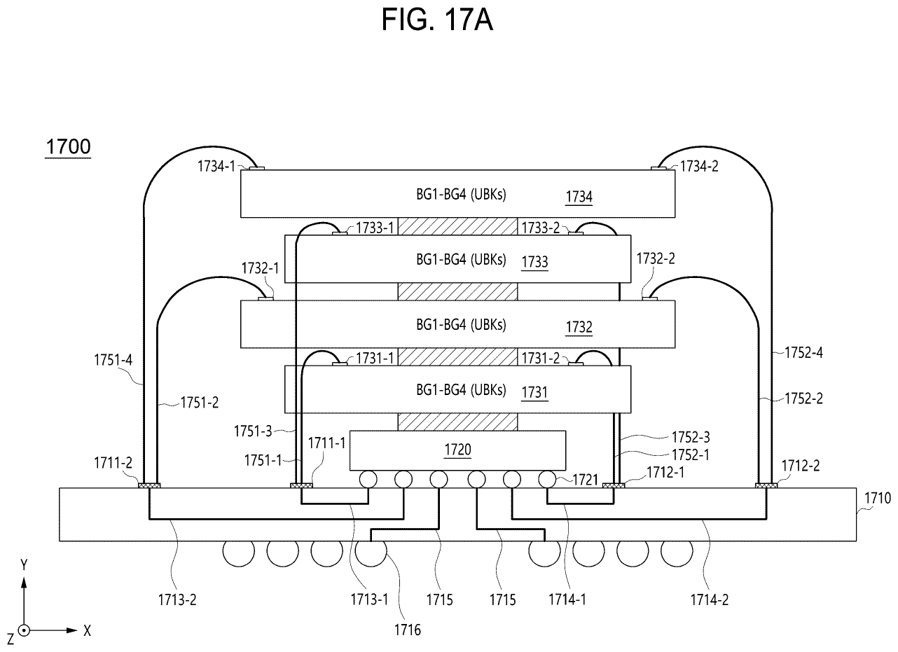

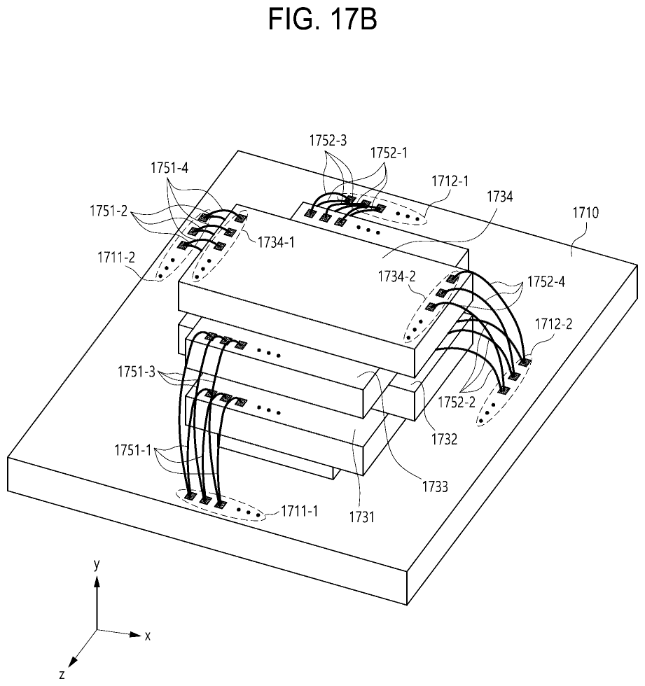

FIGS. 17A and 17B are diagrams illustrating a configuration and connection relationship of a semiconductor apparatus according to an embodiment of the present disclosure. Referring to FIGS. 17A and 17B, a semiconductor apparatus 1700 may include a package substrate 1710, a logic die 1720, and a plurality of cell dies. The logic die 1720 and the plurality of cell dies may be disposed on the package substrate 1710 and may be packaged as a single package. The plurality of cell dies may include a first cell die 1731, a second cell die 1732, a third cell die 1733, and a fourth cell die 1734. The number of cell dies included in the semiconductor apparatus 1700 may be any even number. The logic die 1720 may be disposed on the package substrate 1710 in a y-axis direction. The logic die 1720 may be disposed at a central portion of the package substrate 1710 in x-axis and z-axis directions. The logic die 1720 may include a plurality of bumps 1721 and may be coupled to the package substrate 1710 through the plurality of bumps 1721. The first cell die 1731 may be disposed on the logic die 1720 in a y-axis direction. The first cell die 1731 may be disposed to cover a part or all of the logic die 1720. The first cell die 1731 may be bonded onto the logic die 1720 using an adhesive or a die attach film. In an embodiment, the semiconductor apparatus 1700 may further include a molding structure illustrated in FIG. 16, and the first cell die 1731 may be bonded onto the molding structure. Among four sides of the first cell die 1731, two shorter sides may be aligned in an x-axis direction. Two longer sides of the first cell die 1731 may be aligned in a z-axis direction. The second cell die 1732 may be disposed on the first cell die 1731 in a y-axis direction. The second cell die 1732 may be disposed on the first cell die by being rotated by 90 degrees with respect to the first cell die 1731. Among four sides of the second cell die 1732, two longer sides may be aligned in an x-axis direction. Two shorter sides of the second cell die 1732 may be aligned in a z-axis direction. The third cell die 1733 may be disposed on the second cell die 1732 in a y-axis direction. The third cell die 1733 may be aligned with the first cell die 1731 in x-axis and z-axis directions. Among four sides of the third cell die 1733, two shorter sides may be aligned in an x-axis direction. Two longer sides of the third cell die 1733 may be aligned in a z-axis direction. The fourth cell die 1734 may be disposed on the third cell die 1733 in a y-axis direction. The fourth cell die 1734 may be aligned with the second cell die 1732 in x-axis and z-axis directions. Among four sides of the fourth cell die 1734, two longer sides may be aligned in an x-axis direction. Two shorter sides of the fourth cell die 1734 may be aligned in a z-axis direction. The second to fourth cell dies 1732, 1733, and 1734 may be respectively bonded to the first to third cell dies 1731, 1732, and 1733 using a die attach film. The first cell die 1731 may include first data pads 1731-1, the second cell die 1732 may include first data pads 1732-1, the third cell die 1733 may include first data pads 1733-1, and the fourth cell die 1734 may include first data pads 1734-1 on a first side of each of the first to fourth cell dies 1731, 1732, 1733, and 1734. The first cell die 1731 may include second data pads 1731-2, the second cell die 1732 may include second data pads 1732-2, the third cell die 1733 may include second data pads 1733-2, and the fourth cell die 1734 may include second data pads 1734-2 on a second side opposite to the first side of each of the first to fourth cell dies 1731, 1732, 1733, and 1734. A first side of a cell die may be a region adjacent to one of two shorter sides among the first to fourth cell dies 1731, 1732, 1733, and 1734. The second side may be a region adjacent to the other one of the two shorter sides. Accordingly, the first and second sides of the first and third cell dies 1731 and 1733 may extend in a z-axis direction, and the first and second sides of the second and fourth cell dies 1732 and 1734 may extend in an x-axis direction. A region adjacent to one of the two longer sides of the first to fourth cell dies 1731, 1732, 1733, and 1734 may be a third side of the first to fourth cell dies 1731, 1732, 1733, and 1734, and a region adjacent to the other one of the two longer sides may be a fourth side of the first to fourth cell dies 1731, 1732, 1733, and 1734. The third and fourth sides of the first and third cell dies 1731 and 1733 may extend in an x-axis direction, and the third and fourth sides of the second and fourth cell dies 1732 and 1734 may extend in a z-axis direction. The first and second sides of the first and third cell dies 1731 and 1733 may be disposed to be aligned with first and second sides of the logic die 1720. The first and second sides of the second and fourth cell dies 1732 and 1734 may be disposed to be aligned with third and fourth sides of the logic die 1720.

The package substrate 1710 may include first pads 1711-1, second pads 1712-1, third pads 1711-2, fourth pads 1712-2, first signal transmission lines 1713-1, second signal transmission lines 1714-1, third signal transmission lines 1713-2, fourth signal transmission lines 1714-2, and fifth signal transmission lines 1715. The first to fourth pads 1711-1, 1712-1, 1711-2, and 1712-2 may be formed on the package substrate 1710, and the first to fifth signal transmission lines 1713-1, 1714-1, 1713-2, 1714-2, and 1715 may be formed in the package substrate 1710. For example, the first pads 1711-1 may be formed on a first side of the package substrate 1710, that is, a front portion of the package substrate 1710 in a z-axis direction in FIGS. 17A and 17B, and the third pads 1711-2 may be formed on a third side of the package substrate 1710, that is, a left portion of the package substrate 1710 in an x-axis direction in FIGS. 17A and 17B. The second pads 1712-1 may be formed on a second side of the package substrate 1710, that is, a rear portion of the package substrate 1710 in the z-axis direction in FIGS. 17A and 17B. The fourth pads 1712-2 may be formed on a fourth side of the package substrate 1710, that is, a right portion of the package substrate 1710 in the x-axis direction in FIGS. 17A and 17B. The first pads 1711-1 may be provided on the package substrate 1710 at a distance spaced apart from the first side of the first cell die 1731 in the z-axis direction. The third pads 1711-2 may be provided on the package substrate 1710 at a distance spaced apart from the first side of the second cell die 1732 in the x-axis direction. The second pads 1712-1 may be provided on the package substrate 1710 at a distance spaced apart from the second side of the first cell die 1731 in the z-axis direction. The fourth pads 1712-2 may be provided on the package substrate 1710 at a distance spaced apart from the second side of the second cell die 1732 in the x-axis direction. The first cell die 1731 may be coupled to the first pads 1711-1 through first bonding wires 1751-1 and may be coupled to the second pads 1712-1 through second bonding wires 1752-1. The first data pads 1731-1 provided on the first side of the first cell die 1731 may be coupled to the first pads 1711-1 through the first bonding wires 1751-1. The second data pads 1731-2 provided on the second side of the first cell die 1731 may be coupled to the second pads 1712-1 through the second bonding wires 1752-1. The second cell die 1732 may be coupled to the third pads 1711-2 through third bonding wires 1751-2 and may be coupled to the fourth pads 1712-2 through fourth bonding wires 1752-2. The first data pads 1732-1 provided on the first side of the second cell die 1732 may be coupled to the third pads 1711-2 through the third bonding wires 1751-2. The second data pads 1732-2 provided on the second side of the second cell die 1732 may be coupled to the fourth pads 1712-2 through the fourth bonding wires 1752-2. The third cell die 1733 may be coupled to the first pads 1711-1 through fifth bonding wires 1751-3 and may be coupled to the second pads 1712-1 through sixth bonding wires 1752-3. The first data pads 1733-1 provided on the first side of the third cell die 1733 may be coupled to the first pads 1711-1 through the fifth bonding wires 1751-3. The second data pads 1733-2 provided on the second side of the third cell die 1733 may be coupled to the second pads 1712-1 through the sixth bonding wires 1752-3. The fourth cell die 1734 may be coupled to the third pads 1711-2 through seventh bonding wires 1751-4 and may be coupled to the fourth pads 1712-2 through eighth bonding wires 1752-4. The first data pads 1734-1 provided on the first side of the fourth cell die 1734 may be coupled to the third pads 1711-2 through the seventh bonding wires 1751-4. The second data pads 1734-2 provided on the second side of the fourth cell die 1734 may be coupled to the fourth pads 1712-2 through the eighth bonding wires 1752-4. The logic die 1720 may be coupled to the first pads 1711-1 through the first signal transmission lines 1713-1 and may be coupled to the second pads 1712-1 through the second signal transmission lines 1714-1. The logic die 1720 may be coupled to the third pads 1711-2 through the third signal transmission lines 1713-2 and may be coupled to the fourth pads 1712-2 through the fourth signal transmission lines 1714-2. The logic die 1720 may be respectively coupled to the first data pads 1731-1 and 1733-1 provided on the first sides of the first and third cell dies 1731 and 1733 through the first signal transmission lines 1713-1, the first pads 1711-1, and the first and fifth bonding wires 1751-1 and 1751-3. The logic die 1720 may be respectively coupled to the second data pads 1731-2 and 1733-2 provided on the second sides of the first and third cell dies 1731 and 1733 through the second signal transmission lines 1714-1, the second pads 1712-1, and the second and sixth bonding wires 1752-1 and 1752-3. The logic die 1720 may be respectively coupled to the first data pads 1732-1 and 1734-1 provided on the first sides of the second and fourth cell dies 1732 and 1734 through the third signal transmission lines 1713-2, the third pads 1711-2, and the third and seventh bonding wires 1751-2 and 1751-4. The logic die 1720 may be respectively coupled to the second data pads 1732-2 and 1734-2 provided on the second sides of the second and fourth cell dies 1732 and 1734 through the fourth signal transmission lines 1714-2, the fourth pads 1712-2, and the fourth and eighth bonding wires 1752-2 and 1752-4. The logic die 1720 may be coupled to the external apparatus of the semiconductor apparatus 1700 through the fifth signal transmission lines 1715. The package substrate 1710 may include package balls 1716, and the fifth signal transmission lines 1715 may be coupled to the external apparatus through the package balls 1716. The logic die 1720 may deserialize signals transmitted through the fifth signal transmission lines 1715 and may transmit deserialized signals through the first to fourth signal transmission lines 1713-1, 1714-1, 1713-2, and 1714-2. The logic die 1720 may serialize signals transmitted through the first to fourth signal transmission lines 1713-1, 1714-1, 1713-2, and 1714-2 and may transmit serialized signals through the fifth signal transmission lines 1715. The logic die 1720 may perform an error correction operation on signals transmitted through the first to fourth signal transmission lines 1713-1, 1714-1, 1713-2, and 1714-2.

Although not illustrated, the package substrate 1710 may further include fifth pads, sixth pads, seventh pads, and eighth pads. The fifth pads may be provided on the package substrate 1710 at a distance spaced apart from the third pads 1711-2 in an x-axis direction, and the sixth pads may be provided on the package substrate 1710 at a distance spaced apart from the fourth pads 1712-2 in the x-axis direction. The seventh pads may be provided on the package substrate 1710 at a distance spaced apart from the second pads 1712-1 in a z-axis direction, and the eighth pads may be provided on the package substrate 1710 at a distance spaced apart from the first pads 1711-1 in the z-axis direction. The first to fourth cell dies 1731, 1732, 1733, and 1734 may each include power pads on the third side and the fourth side. A power voltage may be supplied to the fifth to eighth pads. The power pads on the third side of the first and third cell dies 1731 and 1733 may be respectively coupled to the fifth pads through bonding wires. The power pads on the fourth side of the first and third cell dies 1731 and 1733 may be respectively coupled to the sixth pads through bonding wires. The power pads on the third side of the second and fourth cell dies 1732 and 1734 may be respectively coupled to the seventh pads through bonding wires. The power pads on the fourth side of the second and fourth cell dies 1732 and 1734 may be respectively coupled to the eighth pads through bonding wires.

The first to fourth cell dies 1731, 1732, 1733, and 1734 may each include a plurality of bank groups. For example, the first to fourth cell dies 1731, 1732, 1733, and 1734 may each include first to fourth bank groups BG1 to BG4. The first cell die 1731 may include first to fourth bank groups BG1 to BG4 accessed based on a first address group. The first to fourth bank groups BG1 to BG4 of the first cell die 1731 may each include a plurality of up memory banks UBKs and a plurality of down memory banks DBKs. The second cell die 1732 may include first to fourth bank groups BG1 to BG4 accessed based on the first address group. The first to fourth bank groups BG1 to BG4 of the second cell die 1732 may each include a plurality of up memory banks UBKs and a plurality of down memory banks DBKs. The third cell die 1733 may include first to fourth bank groups BG1 to BG4 accessed based on a second address group. The first to fourth bank groups BG1 to BG4 of the third cell die 1733 may each include a plurality of up memory banks UBKs and a plurality of down memory banks DBKs. The fourth cell die 1734 may include first to fourth bank groups BG1 to BG4 accessed based on the second address group. The first to fourth bank groups BG1 to BG4 of the fourth cell die 1734 may each include a plurality of up memory banks UBKs and a plurality of down memory banks DBKs. The down memory banks DBKs of the first to fourth bank groups BG1 to BG4 may each be coupled to the logic die 1720 through the first data pads 1731-1, 1732-1, 1733-1, and 1734-1 provided on the first sides of the first to fourth cell dies 1731, 1732, 1733, and 1734, respectively. The up memory banks UBKs of the first to fourth bank groups BG1 to BG4 may each be coupled to the logic die 1720 through the second data pads 1731-2, 1732-2, 1733-2, and 1734-2 provided on the second sides of the first to fourth cell dies 1731, 1732, 1733, and 1734, respectively.

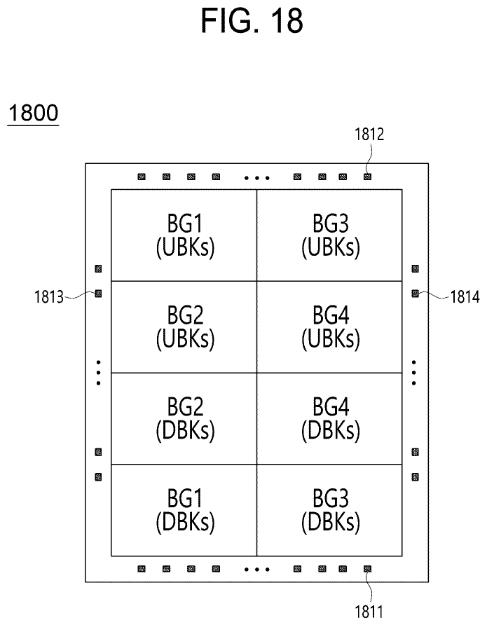

FIG. 18 is a diagram illustrating a configuration of a cell die 1800 according to an embodiment of the present disclosure. The first to fourth cell dies 1731, 1732, 1733, and 1734 illustrated in FIG. 17 may each have a structure substantially identical to the cell die 1800. Referring to FIG. 18, the cell die 1800 may include first data pads 1811 on a first side. The cell die 1800 may include second data pads 1812 on a second side opposite to the first side. The first side and the second side may be regions adjacent to two shorter sides among four sides of the cell die 1800. A plurality of bank groups accessed based on one address group may be disposed in a central region of the cell die 1800. For example, the cell die 1800 may include first to fourth bank groups BG1 to BG4. The first to fourth bank groups BG1 to BG4 may each include up memory banks UBKs and down memory banks DBKs. The first to fourth bank groups BG1 to BG4 including the down memory banks DBKs may be disposed adjacent to the first side and may be coupled to the first data pads 1811 provided on the first side. The first to fourth bank groups BG1 to BG4 including the up memory banks UBKs may be disposed adjacent to the second side and may be coupled to the second data pads 1812 provided on the second side. The cell die 1800 may include power pads 1813 on a third side between the first side and the second side. The third side may be a region adjacent to one of two longer sides among the four sides of the cell die 1800. The cell die 1800 may include power pads 1814 on a fourth side opposite to the third side. The fourth side may be a region adjacent to the other one of the two longer sides. The cell die 1800 may receive a power voltage through the power pads 1813 and 1814.

Referring to FIGS. 17A and 17B together, the first data pads 1731-1 and 1733-1 provided on the first sides of the first and third cell dies 1731 and 1733 are respectively coupled to the first pads 1711-1 of the package substrate 1710 through the first and fifth bonding wires 1751-1 and 1751-3, and the first pads 1711-1 may be coupled to the logic die 1720 through the first signal transmission lines 1713-1. The numbers of the first and fifth bonding wires 1751-1 and 1751-3 may each be N*k/4, and the number of the first signal transmission lines 1713-1 may also be N*k/4. The second data pads 1731-2 and 1733-2 provided on the second sides of the first and third cell dies 1731 and 1733 are respectively coupled to the second pads 1712-1 of the package substrate 1710 through the second and sixth bonding wires 1752-1 and 1752-3, and the second pads 1712-1 may be coupled to the logic die 1720 through the second signal transmission lines 1714-1. The numbers of the second and sixth bonding wires 1752-1 and 1752-3 may each be N*k/4, and the number of the second signal transmission lines 1714-1 may also be N*k/4. The first data pads 1732-1 and 1734-1 provided on the first sides of the second and fourth cell dies 1732 and 1734 are respectively coupled to the third pads 1711-2 of the package substrate 1710 through the third and seventh bonding wires 1751-2 and 1751-4, and the third pads 1711-2 may be coupled to the logic die 1720 through the third signal transmission lines 1713-2. The numbers of the third and seventh bonding wires 1751-2 and 1751-4 may each be N*k/4, and the number of the third signal transmission lines 1713-2 may also be N*k/4. The second data pads 1732-2 and 1734-2 provided on the second sides of the second and fourth cell dies 1732 and 1734 are respectively coupled to the fourth pads 1712-2 of the package substrate 1710 through the fourth and eighth bonding wires 1752-2 and 1752-4, and the fourth pads 1712-2 may be coupled to the logic die 1720 through the fourth signal transmission lines 1714-2. The numbers of the fourth and eighth bonding wires 1752-2 and 1752-4 may each be N*k/4, and the number of the fourth signal transmission lines 1714-2 may also be N*k/4. The number of the fifth signal transmission lines 1715 may be N, 2N, or 4N. The logic die 1720 may be implemented as the logic die 1120 illustrated in FIG. 12.

The semiconductor apparatus 1700 may support a plurality of data input/output modes. The plurality of data input/output modes may include a first data input/output mode, a second data input/output mode, and a third data input/output mode. When the semiconductor apparatus 1700 supports all of the first to third data input/output modes, for example, the number of the fifth signal transmission lines 1715 may be 16, and a burst length may be 16 or 32. The semiconductor apparatus 1700 may operate with a larger burst length to increase bandwidth, and the burst length may be 32. For example, when Nis 16 and k is 32, an operation in which data are transmitted from the external apparatus to the semiconductor apparatus 1700 will be described as follows. In the second data input/output mode, serial data signals received through the fifth signal transmission lines 1715 may be converted into 128 parallel data signals by the logic die 1720. The 128 parallel data signals may be divided and transmitted to one of the first and third cell dies 1731 and 1733 and one of the second and fourth cell dies 1732 and 1734. The logic die 1720 may access the first and second cell dies 1731 and 1732 in conjunction, based on the first address group, or may access the third and fourth cell dies 1733 and 1734 in conjunction, based on the second address group. When the logic die 1720 accesses the first and second cell dies 1731 and 1732 based on the first address group, the logic die 1720 may transmit first to thirty-second parallel data signals from among the 128 parallel data signals to the first cell die 1731 through the first bonding wires 1751-1, and may transmit thirty-third to sixty-fourth parallel data signals to the first cell die 1731 through the second bonding wires 1752-1. The logic die 1720 may transmit sixty-fifth to ninety-sixth parallel data signals to the second cell die 1732 through the third bonding wires 1751-2, and may transmit ninety-seventh to one hundred twenty-eighth parallel data signals to the second cell die 1732 through the fourth bonding wires 1752-2.

In the third data input/output mode, serial data signals received through the fifth signal transmission lines 1715 may be converted into 256 parallel data signals by the logic die 1720. The 256 parallel data signals may be divided and transmitted to one of the first and third cell dies 1731 and 1733 and one of the second and fourth cell dies 1732 and 1734. The logic die 1720 may access the first and second cell dies 1731 and 1732 in conjunction, based on the first address group, or may access the third and fourth cell dies 1733 and 1734 in conjunction, based on the second address group. For example, when the logic die 1720 accesses the first and second cell dies 1731 and 1732 based on the first address group, the logic die 1720 may transmit first to sixty-fourth parallel data signals from among the 256 parallel data signals to the first cell die 1731 through the first bonding wires 1751-1. The logic die 1720 may transmit sixty-fifth to one hundred twenty-eighth parallel data signals to the first cell die 1731 through the second bonding wires 1752-1. The logic die 1720 may transmit one hundred twenty-ninth to one hundred ninety-second parallel data signals to the second cell die 1732 through the third bonding wires 1751-2. The logic die 1720 may transmit one hundred ninety-third to two hundred fifty-sixth parallel data signals to the second cell die 1732 through the fourth bonding wires 1752-2.

In the first data input/output mode, serial data signals received through the fifth signal transmission lines 1715 may be converted into 512 parallel data signals by the logic die 1720. The 512 parallel data signals may be divided and transmitted to one of the first and third cell dies 1731 and 1733 and one of the second and fourth cell dies 1732 and 1734. The logic die 1720 may access the first and second cell dies 1731 and 1732 in conjunction, based on the first address group, or may access the third and fourth cell dies 1733 and 1734 in conjunction, based on the second address group. For example, when the logic die 1720 accesses the first and second cell dies 1731 and 1732 based on the first address group, the logic die 1720 may transmit first to one hundred twenty-eighth parallel data signals from among the 512 parallel data signals to the first cell die 1731 through the first bonding wires 1751-1. The logic die 1720 may transmit one hundred twenty-ninth to two hundred fifty-sixth parallel data signals to the first cell die 1731 through the second bonding wires 1752-1. The logic die 1720 may transmit two hundred fifty-seventh to three hundred eighty-fourth parallel data signals to the second cell die 1732 through the third bonding wires 1751-2. The logic die 1720 may transmit three hundred eighty-fifth to five hundred twelfth parallel data signals to the second cell die 1732 through the fourth bonding wires 1752-2. An operation in which data are transmitted from the semiconductor apparatus 1700 to the external apparatus may also be performed in a similar manner.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of

What is claimed is:

1. A semiconductor apparatus comprising:
a package substrate;
a logic die disposed on the package substrate; and
first to fourth cell dies disposed on the logic die and each having data pads on a first side,
wherein the second cell die is offset from the first cell die in a second direction opposite to a first direction to expose the first side of the first cell die in the first direction,
wherein the third and fourth cell dies are disposed on the second cell die and rotated by 180 degrees with respect to the first and second cell dies,
wherein the third cell die is offset from the second cell die in the second direction to expose the first side of the second cell die in the first direction,
wherein the fourth cell die is offset from the third cell die in the first direction to expose the first side of the third cell die in the second direction,
wherein the data pads of the first and second cell dies are coupled to first pads of the package substrate through first bonding wires, and the data pads of the third and fourth cell dies are coupled to second pads of the package substrate through second bonding wires, and
wherein the logic die is coupled to the first pads through first signal transmission lines provided in the package substrate, coupled to the second pads through second signal transmission lines provided in the package substrate, and coupled to an external apparatus through third signal transmission lines provided in the package substrate.

2. The semiconductor apparatus of claim 1, wherein a ratio of the number of each of the first and second signal transmission lines to the number of the third signal transmission lines is 8:1 or 16:1.

3. The semiconductor apparatus of claim 1, wherein the logic die includes a serializer/deserializer configured to serialize signals on the first and second signal transmission lines into signals on the third signal transmission lines and configured to deserialize signals on the third signal transmission lines into signals on the first and second signal transmission lines.

4. The semiconductor apparatus of claim 1, wherein the first cell die includes down memory banks of a bank group accessed based on a first address group, the second cell die includes down memory banks of a bank group accessed based on a second address group, the third cell die includes up memory banks of the bank group accessed based on the first address group, and the fourth cell die includes up memory banks of the bank group accessed based on the second address group.

5. The semiconductor apparatus of claim 1, wherein the logic die is configured to access the first and third cell dies in conjunction or to access the second and fourth cell dies in conjunction, in a first data input/output mode.

6. The semiconductor apparatus of claim 5, wherein the logic die is configured to access the first and third cell dies in conjunction or to access the second and fourth cell dies in conjunction, in a second data input/output mode and a third data input/output mode.

7. A semiconductor apparatus comprising:
a package substrate;
a logic die disposed on the package substrate;
a first cell die disposed on the logic die;
a second cell die disposed on the first cell die and rotated by 90 degrees with respect to the first cell die;
a third cell die disposed on the second cell die to be aligned with the first cell die; and
a fourth cell die disposed on the third cell die to be aligned with the second cell die,
wherein the first to fourth cell dies each include first data pads on a first side and second data pads on a second side opposite to the first side,
wherein the first data pads of the first cell die are coupled to first pads of the package substrate through first bonding wires, and the second data pads of the first cell die are coupled to second pads of the package substrate through second bonding wires,
wherein the first data pads of the second cell die are coupled to third pads of the package substrate through third bonding wires, and the second data pads of the second cell die are coupled to fourth pads of the package substrate through fourth bonding wires,
wherein the first data pads of the third cell die are coupled to the first pads of the package substrate through fifth bonding wires, and the second data pads of the third cell die are coupled to the second pads of the package substrate through sixth bonding wires,
wherein the first data pads of the fourth cell die are coupled to the third pads of the package substrate through seventh bonding wires, and the second data pads of the fourth cell die are coupled to the fourth pads of the package substrate through eighth bonding wires, and
wherein the logic die is coupled to the first pads through first signal transmission lines provided in the package substrate, coupled to the second pads through second signal transmission lines provided in the package substrate, coupled to the third pads through third signal transmission lines provided in the package substrate, coupled to the fourth pads through fourth signal transmission lines provided in the package substrate, and coupled to an external apparatus through fifth signal transmission lines provided in the package substrate.

8. The semiconductor apparatus of claim 7, wherein down memory banks of the first cell die are coupled to the first data pads of the first cell die, and up memory banks of the first cell die are coupled to the second data pads of the first cell die.

9. The semiconductor apparatus of claim 8, wherein down memory banks of the second cell die are coupled to the first data pads of the second cell die, and up memory banks of the second cell die are coupled to the second data pads of the second cell die.

10. The semiconductor apparatus of claim 9, wherein down memory banks of the third cell die are coupled to the first data pads of the third cell die, and up memory banks of the third cell die are coupled to the second data pads of the third cell die.

11. The semiconductor apparatus of claim 10, wherein down memory banks of the fourth cell die are coupled to the first data pads of the fourth cell die, and up memory banks of the fourth cell die are coupled to the second data pads of the fourth cell die.

12. The semiconductor apparatus of claim 7, wherein the logic die is configured to access the first cell die and the second cell die in conjunction, based on a first address group and to access the third cell die and the fourth cell die in conjunction, based on a second address group.

13. The semiconductor apparatus of claim 7, wherein the logic die is configured to access the first cell die and the second cell die in conjunction or to access the third cell die and the fourth cell die in conjunction, in a first data input/output mode.

14. The semiconductor apparatus of claim 12, wherein the logic die is configured to access the first cell die and the second cell die in conjunction or to access the third cell die and the fourth cell die in conjunction, in a second data input/output mode and a third data input/output mode.

15. The semiconductor apparatus of claim 7, wherein the logic die generates 4n parallel data signals from serial data signals received through the fifth signal transmission lines,
wherein when the logic die accesses the first cell die and the second cell die, the logic die transmits first to nth parallel data signals to the first data pads of the first cell die through the first pads, transmits n+1th to 2nth parallel data signals to the second data pads of the first cell die through the second pads, transmits 2n+1th to 3nth parallel data signals to the first data pads of the second cell die through the third pads, and transmits 3n+1th to 4nth parallel data signals to the second data pads of the second cell die through the fourth pads, and
wherein n is an integer equal to or greater than 4.

16. A semiconductor apparatus comprising:
a package substrate;
a logic die disposed on the package substrate; and
first to fourth cell dies disposed on the logic die and each having data pads on a first side,
wherein the second cell die is disposed on the first cell die by being shifted in a second direction opposite to a first direction to expose the first side of the first cell die in the first direction,
wherein the third and fourth cell dies are disposed on the second cell die and rotated by 180 degrees with respect to the first and second cell dies,
wherein the third cell die is disposed on the second cell die by being shifted in the second direction to expose the first side of the second cell die in the first direction,
wherein the fourth cell die is disposed on the third cell die by being shifted in the first direction to expose the first side of the third cell die in the second direction,
wherein the first cell die includes down memory banks of a bank group accessed based on a first address group, the second cell die includes down memory banks of a bank group accessed based on a second address group, the third cell die includes up memory banks of the bank group accessed based on the first address group, and the fourth cell die includes up memory banks of the bank group accessed based on the second address group, and
wherein the logic die is configured to access the first and third cell dies in conjunction or to access the second and fourth cell dies in conjunction, in a plurality of data input/output modes.

17. The semiconductor apparatus of claim 16, wherein the first to fourth cell dies each have data pads on the first side, and
wherein the data pads of the first and second cell dies are coupled to first pads of the package substrate through first bonding wires, and the data pads of the third and fourth cell dies are coupled to second pads of the package substrate through second bonding wires.

18. A semiconductor apparatus comprising:
a package substrate;
a logic die disposed on the package substrate;
a first cell die disposed on the logic die;
a second cell die disposed on the first cell die and rotated by 90 degrees with respect to the first cell die;
a third cell die disposed on the second cell die to be aligned with the first cell die; and
a fourth cell die disposed on the third cell die to be aligned with the second cell die,
wherein the first to fourth cell dies each have first data pads on a first side and second data pads on a second side opposite to the first side,
wherein down memory banks of the first cell die are coupled to the first data pads of the first cell die, and up memory banks of the first cell die are coupled to the second data pads of the first cell die,
wherein down memory banks of the second cell die are coupled to the first data pads of the second cell die, and up memory banks of the second cell die are coupled to the second data pads of the second cell die,
wherein down memory banks of the third cell die are coupled to the first data pads of the third cell die, and up memory banks of the third cell die are coupled to the second data pads of the third cell die,
wherein down memory banks of the fourth cell die are coupled to the first data pads of the fourth cell die, and up memory banks of the fourth cell die are coupled to the second data pads of the fourth cell die, and
wherein the logic die is configured to access the first and second cell dies in conjunction or to access the third and fourth cell dies in conjunction, in a plurality of data input/output modes.

19. The semiconductor apparatus of claim 18, wherein the logic die is configured to access the first and second cell dies in conjunction, based on a first address group and to access the third and fourth cell dies in conjunction, based on a second address group.

20. The semiconductor apparatus of claim 18, wherein the first data pads of the first cell die are coupled to first pads of the package substrate through first bonding wires, and the second data pads of the first cell die are coupled to second pads of the package substrate through second bonding wires,
wherein the first data pads of the second cell die are coupled to third pads of the package substrate through third bonding wires, and the second data pads of the second cell die are coupled to fourth pads of the package substrate through fourth bonding wires,
wherein the first data pads of the third cell die are coupled to the first pads of the package substrate through fifth bonding wires, and the second data pads of the third cell die are coupled to the second pads of the package substrate through sixth bonding wires, and
wherein the first data pads of the fourth cell die are coupled to the third pads of the package substrate through seventh bonding wires, and the second data pads of the fourth cell die are coupled to the fourth pads of the package substrate through eighth bonding wires.

21. The semiconductor apparatus of claim 20, wherein the logic die is coupled to:
the first pads through first signal transmission lines of the package substrate;
the second pads through second signal transmission lines of the package substrate;
the third pads through third signal transmission lines of the package substrate;
the fourth pads through fourth signal transmission lines of the package substrate; and
an external apparatus through fifth signal transmission lines of the package substrate.
